(19) United States
(12) Patent Application Publication
(10) Pub. No.: US 2014/0323723 A1
(43) Pub. Date: Oct. 30, 2014

(54) NOVEL ORGANIC ELECTROLUMINESCENT COMPOUNDS AND AN ORGANIC ELECTROLUMINESCENT DEVICE USINC THE SAME

(71) Applicant: Rohm and Haas Electronic Materials Korea Ltd., Chungcheongnam-do (KR)

(72) Inventors: Hee-Choon Ahn, Gyeonggi-do (KR); Seok-Keun Yoon, Gyeonggi-do (KR); Nam-Kyun Kim, Gyeonggi-do (KR); Seung-Ae Kim, Gyeonggi-do (KR); Jong-Seok Ku, Gyeonggi-do (KR); Hyuck-Joo Kwon, Seoul (KR); Kyung-Joo Lee, Seoul (KR); Bong-Ok Kim, Seoul (KR)

(21) Appl. No.: 14/359,299

(22) PCT Filed: Nov. 15, 2012
(86) PCT No.: PCT/KR2012/009686

§ 371 Date: May 19, 2014

(30) Foreign Application Priority Data
Nov. 18, 2011 (KR) 10-2011-0120827

(51) Int. Cl. H01L 51/00

(52) U.S. Cl. CPC H01L 51/0067; H01L 51/0072
USPC 544/212

(57) ABSTRACT

The present invention relates to a novel organic electroluminescent compound and an organic electroluminescent device containing the same. The organic electroluminescent compound according to the present invention has an advantage of manufacturing an OLED device having long operating lifespan due to its excellent lifespan characteristics, lower driving voltages, high luminous efficiency, and reduced power consumption induced by improved power efficiency.

### TECHNICAL FIELD

The present invention relates to novel organic electroluminescent compounds and an organic electroluminescent device using the same.

### BACKGROUND ART

An electroluminescent (EL) device is a self-light-emitting device which has advantages over other types of display devices in that it provides a wider viewing angle, a greater contrast ratio, and a faster response time. An organic EL device was first developed by Eastman Kodak, by using small aromatic diamine molecules, and aluminum complexes as materials for forming a light-emitting layer [Appl. Phys. Lett. 51, 913, 1987].

The most important factor determining luminous efficiency in an organic EL device is the light-emitting material. Until now, fluorescent materials have been widely used as a light-emitting material. However, in view of electroluminescent mechanisms, since phosphorescent light-emitting materials theoretically enhance the luminous efficiency by four (4) times compared to fluorescent light-emitting materials, development of phosphorescent light-emitting materials are widely being researched. Iridium(III) complexes have been widely known as phosphorescent materials, including bis(2-(2′-benzothienyl)-pyridinato-N,C-3′)iridium(acetylacetonate) ((acac)Ir(btp)₂), tris(2-phenylpyridine)iridium (Ir(ppy)₃) and bis(4,6-difluorophenylpyridinato-N,C2)picolinate iridium (Firpic) as red, green and blue materials, respectively.

Until now, 4,4′-N,N′-dicarbazol-biphenyl (CBP) was the most widely known host material for phosphorescent substances. Further, an organic EL device using bathocuproine (BCP) and aluminum(III)bis(2-methyl-8-quinolinate)(4-phenylphenolate) (BAIq) for a hole blocking layer is also known, and Pioneer (Japan) et al. developed a high performance organic EL device employing a derivative of BAIq as a host material.

Though these materials provide good light-emitting characteristics, they have the following disadvantages. Due to their low glass transition temperature and poor thermal stability, degradation may occur during a high-temperature deposition process in a vacuum. The power efficiency of an organic EL device is given by [(π/voltage)×current efficiency], and power efficiency is inversely proportional to voltage, and thus in order to lower power consumption, power efficiency should be raised. Although an organic EL device comprising phosphorescent materials provides a much higher current efficiency (cd/A) than one comprising fluorescent materials, an organic EL device using conventional phosphorescent materials such as BAIq or CBP has a higher driving voltage than those using fluorescent materials. Thus, the EL device using conventional phosphorescent materials has less advantage in terms of power efficiency (Im/W). Further, the operating lifespan of the organic EL device is short.

International Patent Publication No. WO 2006/049013 discloses compounds for organic electroluminescent device having a carbazole backbone structure wherein the nitrogen atom of the carbazole is bonded to a heteroaryl group containing nitrogen through an aryl group, etc.

However, it does not disclose a compound having a benzocarbazole backbone structure wherein the nitrogen atom of the benzocarbazole is bonded, directly or through an aryl group, to a heteroaryl group substituted with an aryl group, etc.

### DISCLOSURE OF INVENTION

### Technical Problem

The objective of the present invention is to provide an organic electroluminescent compound imparting high luminous efficiency and a long operating lifespan to a device, and having proper color coordination; and an organic electroluminescent device having high efficiency and a long lifespan, using the compound as a light-emitting material.

### Solution to Problem

The present inventors found that the objective above is achievable by a compound represented by the following formula 1:

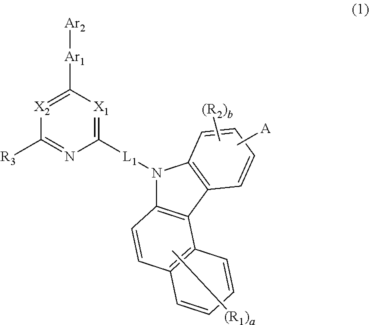

wherein

A represents

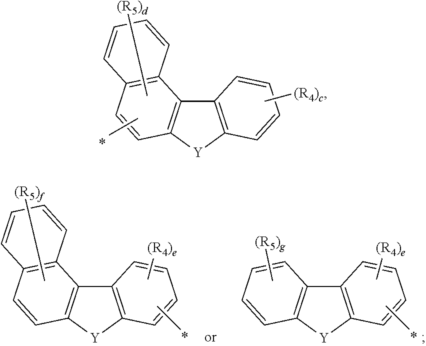

L₁ represents a single bond, a substituted or unsubstituted 3- to 30-membered heteroarylene group, a substituted or unsubstituted (C6-C30)arylene group, or a substituted or unsubstituted (C3-C30)cycloalkylene group;

X₁ and X₂ each independently represent CR₆ or N;

Y represents —O—, —S—, —CR₁₁R₁₂—, —SiR₁₁R₁₂—, or —NR₁₃—;

Ar₁ represents a single bond, a substituted or unsubstituted 3- to 30-membered heteroarylene group, a substituted or unsubstituted (C6-C30)arylene group, or a substituted or unsubstituted (C1-C30)alkylene group;

Ar₂ represents hydrogen, deuterium, a substituted or unsubstituted (C1-C30)alkyl group, a substituted or unsubstituted (C6-C30)aryl group, or a substituted or unsubstituted 3- to 30-membered heteroaryl group;

R₁ to R₆ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, a substituted or unsubstituted (C6-C30)aryl(C1-C30)alkyl group, a substituted or unsubstituted (C6-C30)aryl group fused with at least one substituted or unsubstituted (C3-C30)cycloalkyl, a substituted or unsubstituted 5- to 7-membered heterocycloalkyl group fused with at least one substituted or unsubstituted aromatic ring, a substituted or unsubstituted (C3-C30)cycloalkyl group fused with at least one substituted or unsubstituted aromatic ring, —NR₁₄R₁₅, —SiR₁₆R₁₇R₁₈, —SR₁₉, —OR₂₀, a (C2-C30)alkenyl group, a (C2-C30)alkynyl group, a cyano group or a nitro group;

R₁₁ to R₁₃ each independently represent a substituted or unsubstituted (C1-C30)alkyl group, a substituted or unsubstituted (C6-C30)aryl group, or a substituted or unsubstituted 3- to 30-membered heteroaryl group;

R₁₄ to R₂₀ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; or are linked to an adjacent substituent(s) to form a 3- to 30-membered mono- or polycyclic, alicyclic or aromatic ring whose carbon atom(s) may be replaced with at least one hetero atom selected from nitrogen, oxygen and sulfur;

a and f each independently represent an integer of 1 to 6; where a or f is an integer of 2 or more, each of R₁, or each of R₅ is the same or different;

b and e each independently represent an integer of 1 to 3; where b or e is an integer of 2 or more, each of R₂, or each of R₄ is the same or different;

c and g each independently represent an integer of 1 to 4; where c or g is an integer of 2 or more, each of R₄, or each of R₅ is the same or different;

d represents an integer of 1 to 5; where d is an integer of 2 or more, each of R₅ is the same or different; and

the heterocycloalkyl group and the heteroaryl(ene) group contain at least one hetero atom selected from B, N, O, S, P(═O), Si and P.

### Advantageous Effects of Invention

The present invention makes it possible to manufacture a device free from crystallization since the compounds used in the organic electronic material are highly efficient in transporting electrons. Further, the compounds have good layer formability and improve the current characteristic of the device. Therefore, they can produce an organic electroluminescent device having lowered driving voltages and enhanced power efficiency.

### MODE FOR THE INVENTION

Hereinafter, the present invention will be described in detail. However, the following description is intended to explain the invention, and is not meant in any way to restrict the scope of the invention.

The present invention relates to an organic electroluminescent compound represented by formula 1, above, an organic electroluminescent material comprising the compound, and an organic electroluminescent device comprising the material.

Hereinafter, the organic electroluminescent compound represented by the above formula 1 will be described in detail.

Herein, “(C1-C30)alkyl(ene)” is meant to be a linear or branched alkyl(ene) having 1 to 30 carbon atoms, in which the number of carbon atoms is preferably 1 to 10; more preferably 1 to 6; and includes methyl, ethyl, n-propyl, isopropyl, n-butyl, isobutyl and tert-butyl, etc.; “(C2-C30)alkenyl” is meant to be a linear or branched alkenyl having 2 to 30 carbon atoms, in which the number of carbon atoms is preferably 2 to 20; more preferably 2 to 10; and includes vinyl, 1-propenyl, 2-propenyl, 1-butenyl, 2-butenyl, 3-butenyl and 2-methylbut-2-enyl, etc.; “(C2-C30)alkynyl” is a linear or branched alkynyl having 2 to 30 carbon atoms, in which the number of carbon atoms is preferably 2 to 20; more preferably 2 to 10; and includes ethynyl, 1-propynyl, 2-propynyl, 1-butynyl, 2-butynyl, 3-butynyl, 1-methylpent-2-ynyl, etc.; “(C3-C30)cycloalkyl” is a mono- or polycyclic hydrocarbon having 3 to 30 carbon atoms, in which the number of carbon atoms is preferably 3 to 20; more preferably 3 to 7; and includes cyclopropyl, cyclobutyl, cyclopentyl, cyclohexyl, etc.; “5- to 7-membered heterocycloalkyl” is a cycloalkyl having at least one heteroatom selected from B, N, O, S, P(═O), Si and P; preferably O, S and N, and 5 to 7 ring backbone atoms; and includes tetrahydrofurane, pyrrolidine, thiolan, tetrahydropyran, etc.; “(C6-C30)aryl(ene)” is a monocyclic or fused ring derived from an aromatic hydrocarbon having 6 to 30 carbon atoms, in which the number of carbon atoms is preferably 6 to 20; more preferably 6 to 12; and includes phenyl, biphenyl, terphenyl, naphthyl, binaphtyl, phenylnaphtyl, naphtylphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, dihydroacenaphthyl, etc.; “3- to 30-membered heteroaryl(ene)” is an aryl group having at least one, preferably 1 to 4 heteroatom selected from the group consisting of B, N, O, S, P(═O), Si and P, and 3 to 30 ring backbone atoms; is a monocyclic ring, or a fused ring condensed with at least one benzene ring; has preferably 3 to 20; more preferably 3 to 12 ring backbone atoms; may be partially saturated; may be one formed by linking at least one heteroaryl or aryl group to a heteroaryl group via a single bond(s); and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, benzocarbazolyl, dibenzocarbazolyl, phenoxazinyl, phenanthridinyl, benzodioxolyl, etc. Further, “Halogen” includes F, Cl, Br and I.

Herein, “substituted” in the expression “substituted or unsubstituted” means that a hydrogen atom in a certain functional group is replaced with another atom or group, i.e., a substituent.

Substituents of the substituted alkyl(ene) group, the substituted aryl(ene) group, the substituted heteroaryl(ene) group, the substituted cycloalkyl(ene) group and the substituted heterocycloalkyl group in L₁, Ar₁, Ar₂, R₁ to R₆ and R₁₁ to R₂₀ groups of formula 1, each independently are at least one selected from the group consisting of deuterium; a halogen; a (C1-C30)alkyl group substituted or unsubstituted with a halogen; a (C6-C30)aryl group; a 3- to 30-membered heteroaryl group substituted or unsubstituted with a (C6-C30)aryl; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; an N-carbazolyl group; a di(C1-C30)alkylamino group; a di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group, preferably each independently are at least one selected from the group consisting of deuterium, a halogen, a (C1-C6)alkyl group, a (C6-C12)aryl group, a di(C1-C6)alkyl(C6-C12)arylsilyl group and a (C1-C6)alkyldi(C6-C12)arylsilyl group.

More specifically,

L₁ represents a single bond, a 3- to 30-membered heteroarylene group or a (C6-C30)arylene group;

X₁ and X₂ each independently represent CR₆ or N;

Y represents —O—, —S—, —CR₁₁R₁₂—, —SiR₁₁R₁₂— or —NR₁₃—;

Ar₁ represents a single bond or a (C6-C30)arylene group;

Ar₂ represents hydrogen, deuterium, a substituted or unsubstituted (C1-C30)alkyl group, a substituted or unsubstituted (C6-C30)aryl group, or a substituted or unsubstituted 3- to 30-membered heteroaryl group, 1,2-dihydroacenaphtyl group, a substituted or unsubstituted N-carbazolyl group, a substituted or unsubstituted N-benzocarbazolyl group, or a substituted or unsubstituted N-dibenzocarbazolyl group;

R₁ to R₆ each independently represent hydrogen, deuterium, a halogen, a (C1-C30)alkyl group, a (C6-C30)aryl group, a 3- to 30-membered heteroaryl group, or an N-carbazolyl group;

R₁₁ to R₁₃ each independently represent a (C1-C30)alkyl group, a (C6-C30)aryl group, or a 3- to 30-membered heteroaryl group; and

the heteroarylene and arylene groups in L₁, the arylene group in Ar₁, the alkyl, aryl, heteroaryl, N-carbazolyl, N-benzocarbazolyl and N-dibenzocarbazolyl groups in Ar₂, the alkyl, aryl, heteroaryl and N-carbazolyl groups in R₁ to R₆, and the alkyl, aryl and heteroaryl groups in R₁₁ to R₁₃ each independently can be substituted with at least one selected from the group consisting of deuterium; a halogen; a (C1-C30)alkyl group substituted or unsubstituted with a halogen; a (C6-C30)aryl group; a 3- to 30-membered heteroaryl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a cyano group; an N-carbazolyl group; a (C6-C30)aryl(C1-C30)alkyl group; a (C1-C30)alkyl(C6-C30)aryl group; a carboxyl group; a nitro group; and a hydroxyl group.

In formula 1, above, L₁ is preferably selected from the group consisting of a single bond, phenylene, naphtylene, biphenylene, terphenylene, anthrylene, andenylene, fluorenylene, phenantrylene, triphenylenylene, pyrenylene, perylenylene, crysenylene, naphthacenylene, fluoranthenylene, phenylene-naphthylene, furylene, thiophenylene, pyrrolylene, imidazolylene, pyrazolylene, thiazolylene, thiadiazolylene, isothiazolylene, isoxazolylene, oxazolylene, oxadiazolylene, triazinylene, tetrazinylene, triazolylene, furazanylene, pyridylene, pyrazinylene, pyrimidinylene, pyridazinylene, benzofuranylene, benzothiophenylene, isobenzofuranylene, benzoimidazolylene, benzothiazolylene, benzoisothiazolylene, benzoisoxazolylene, benzoxazolylene, isoindolylene, indolylene, indazolylene, benzothiadiazolylene, quinolylene, isoquinolylene, cinnolinylene, quinazolinylene, quinoxalinylene, carbazolylene, phenanthridinylene, benzodioxolylene, dibenzofuranylene, and dibenzothiophenylene.

In formula 1, above, the moiety, Ar₂—Ar₁-* is selected from the following structures:

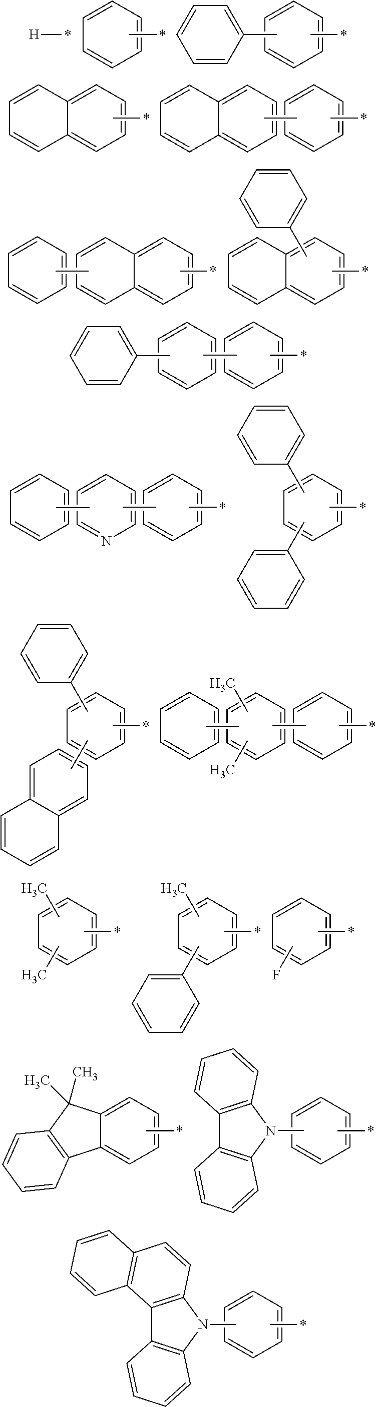

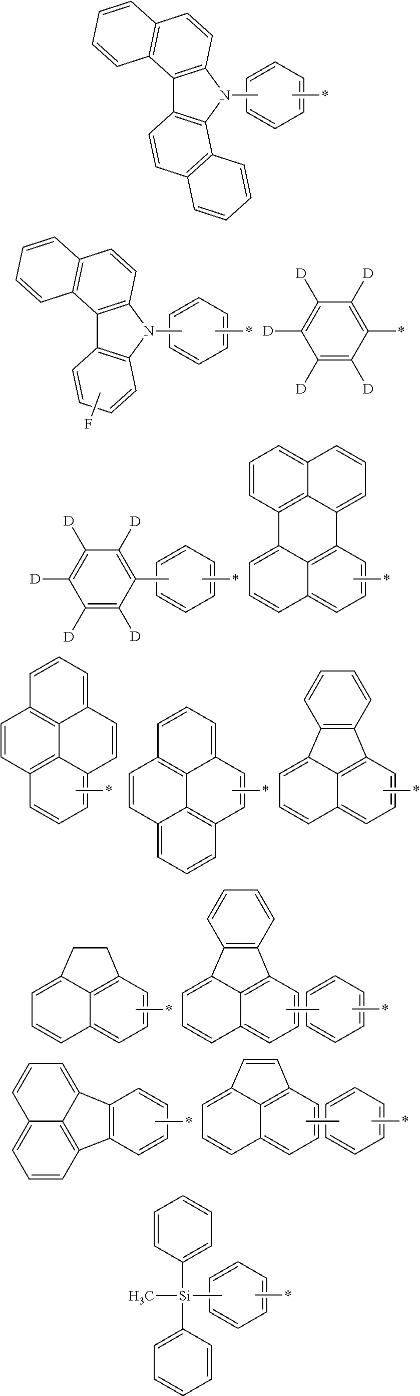

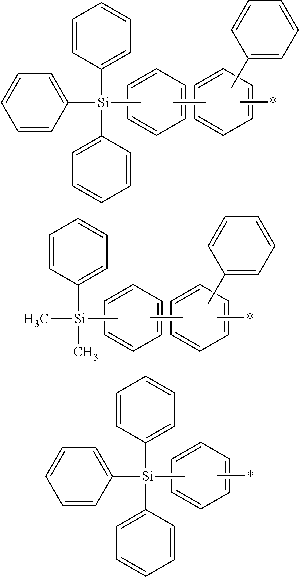

In formula 1, above, L₁ is a single bond, a substituted or unsubstituted 3- to 30-membered heteroarylene group, a substituted or unsubstituted (C6-C30)arylene group, or a substituted or unsubstituted (C3-C30)cycloalkylene group, preferably a single bond or a substituted or unsubstituted (C6-C30)arylene group, more preferably a single bond, or a (C6-C20)arylene group substituted or unsubstituted with a (C1-C6)alkyl group.

X₁ and X₂ are each independently CR₆ or N.

Y represents —O—, —S—, —CR₁₁R₁₂—, —SiR₁₁R₁₂— or —NR₁₃—.

Ar₁ is a single bond, a substituted or unsubstituted 3- to 30-membered heteroarylene group, a substituted or unsubstituted (C6-C30)arylene group, or a substituted or unsubstituted (C1-C30)alkylene group, preferably a single bond or a substituted or unsubstituted (C6-C20)arylene group, more preferably a single bond or (C6-C12)arylene group substituted or unsubstituted with a (C6-C12)aryl group.

Ar₂ is hydrogen, deuterium, a substituted or unsubstituted (C1-C30)alkyl group, a substituted or unsubstituted (C6-C30)aryl group, or a substituted or unsubstituted 3- to 30-membered heteroaryl group, preferably hydrogen, a substituted or unsubstituted (C6-C30)aryl group, or a substituted or unsubstituted 3- to 30-membered heteroaryl group, more preferably hydrogen, a (C6-C20)aryl group substituted or unsubstituted with deuterium, a halogen, a (C1-C6)alkyl group, di(C1-C6)alkyl(C6-C12)arylsilyl group, or (C1-C6)alkyldi(C6-C12)arylsilyl group, or a 3- to 30-membered heteroaryl group substituted or unsubstituted with a halogen.

R₁ to R₆ each independently are hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, a substituted or unsubstituted (C6-C30)aryl(C1-C30)alkyl group, a substituted or unsubstituted (C6-C30)aryl group fused with at least one substituted or unsubstituted (C3-C30)cycloalkyl, a substituted or unsubstituted 5- to 7-membered heterocycloalkyl group fused with at least one substituted or unsubstituted aromatic ring, a substituted or unsubstituted (C3-C30)cycloalkyl group fused with at least one substituted or unsubstituted aromatic ring, —NR₁₄R₁₅, —SiR₁₆R₁₇R₁₈, —SR₁₉, —OR₂₀, a (C2-C30)alkenyl group, a (C2-C30)alkynyl group, a cyano group or a nitro group, preferably hydrogen or a substituted or unsubstituted (C6-C30)aryl group, more preferably hydrogen or a (C6-C12)aryl group substituted or unsubstituted with a (C1-C6)alkyl group or a tri(C6-C12)arylsilyl group.

R₁₁ to R₁₃ each independently are a substituted or unsubstituted (C1-C30)alkyl group, a substituted or unsubstituted (C6-C30)aryl group, or a substituted or unsubstituted 3- to 30-membered heteroaryl group, preferably an unsubstituted (C1-C10)alkyl group, or a substituted or unsubstituted (C6-C30)aryl group, more preferably an unsubstituted (C1-C6)alkyl group, or a (C6-C20)aryl group substituted or unsubstituted with a (C1-C6)alkyl group.

According to an embodiment of the present invention, in formula 1, above, L₁ is a single bond or a substituted or unsubstituted (C6-C30)arylene group; X₁ and X₂ are each independently CR₆ or N; Y represents —O—, —S—, —CR₁₁R₁₂—, —SiR₁₁R₁₂— or —NR₁₃—; Ar₁ is a single bond or a substituted or unsubstituted (C6-C20)arylene group; Ar₂ is a hydrogen, a substituted or unsubstituted (C6-C30)aryl group, or a substituted or unsubstituted 3- to 30-membered heteroaryl group; R₁ to R₆ each independently are hydrogen or a substituted or unsubstituted (C6-C30)aryl group; R₁₁ to R₁₃ each independently are an unsubstituted (C1-C10)alkyl group, or a substituted or unsubstituted (C6-C30)aryl group.

According to another embodiment of the present invention, in formula 1, above, L₁ is a single bond, or a (C6-C20)arylene group substituted or unsubstituted with a (C1-C6)alkyl group; X₁ and X₂ are each independently CR₆ or N; Y represents —O—, —S—, —CR₁₁R₁₂—, —SiR₁₁R₁₂— or —NR₁₃—; Ar₁ is a single bond or (C6-C12)arylene group substituted or unsubstituted with a (C6-C12)aryl group; Ar₂ is hydrogen, a (C6-C20)aryl group substituted or unsubstituted with deuterium, a halogen, a (C1-C6)alkyl group, di(C1-C6)alkyl(C6-C12)arylsilyl group, or (C1-C6)alkyldi(C6-C12)arylsilyl group, or a 3- to 20-membered heteroaryl group substituted or unsubstituted with a halogen; R₁ to R₆ each independently are hydrogen or a (C6-C12)aryl group substituted or unsubstituted with a (C1-C6)alkyl group or a tri(C6-C12)arylsilyl group; R₁₁ to R₁₃ each independently are an unsubstituted (C1-C6)alkyl group, or a (C6-C20)aryl group substituted or unsubstituted with a (C1-C6)alkyl group.

The representative compounds of the present invention include the following compounds:

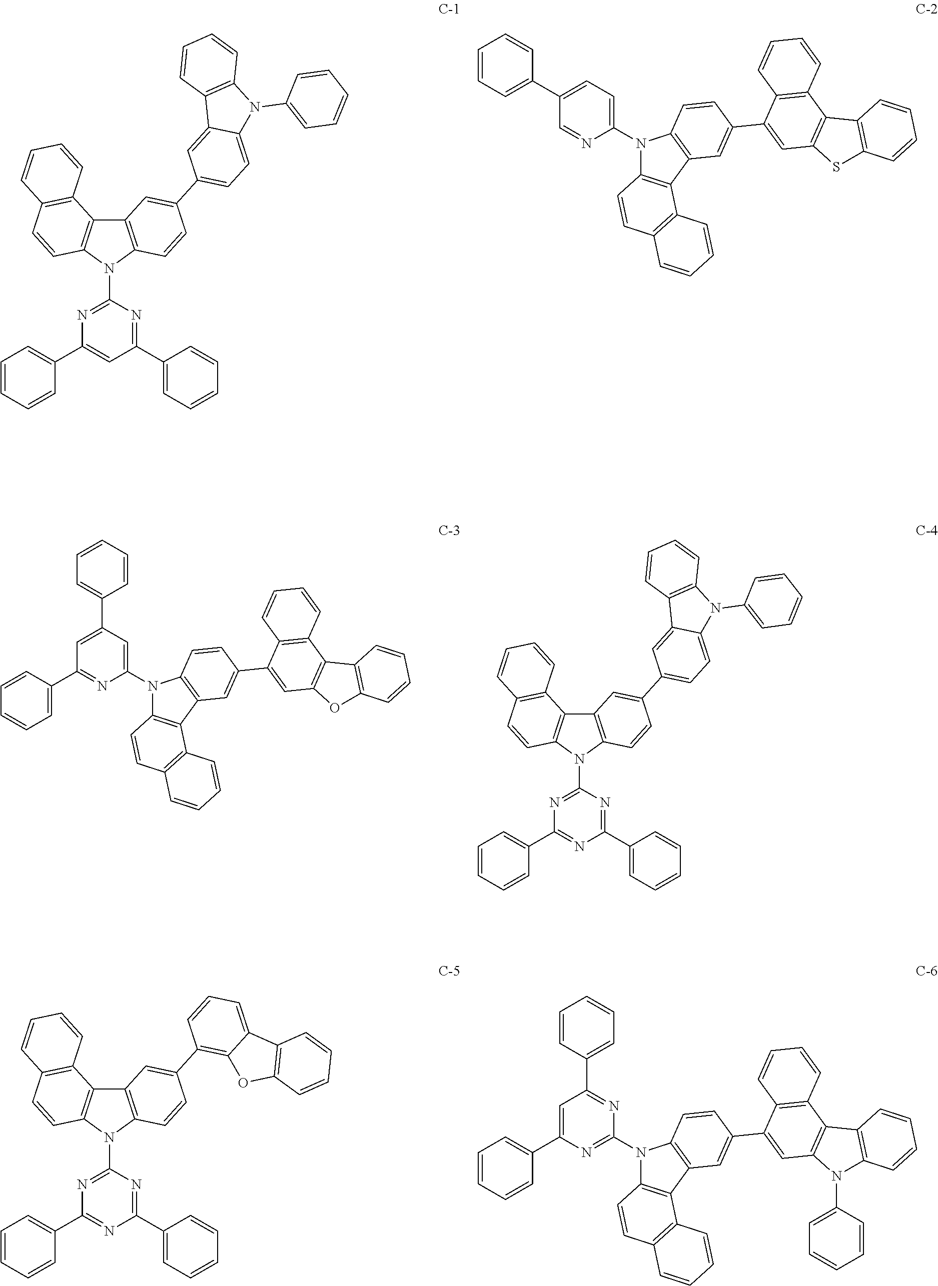

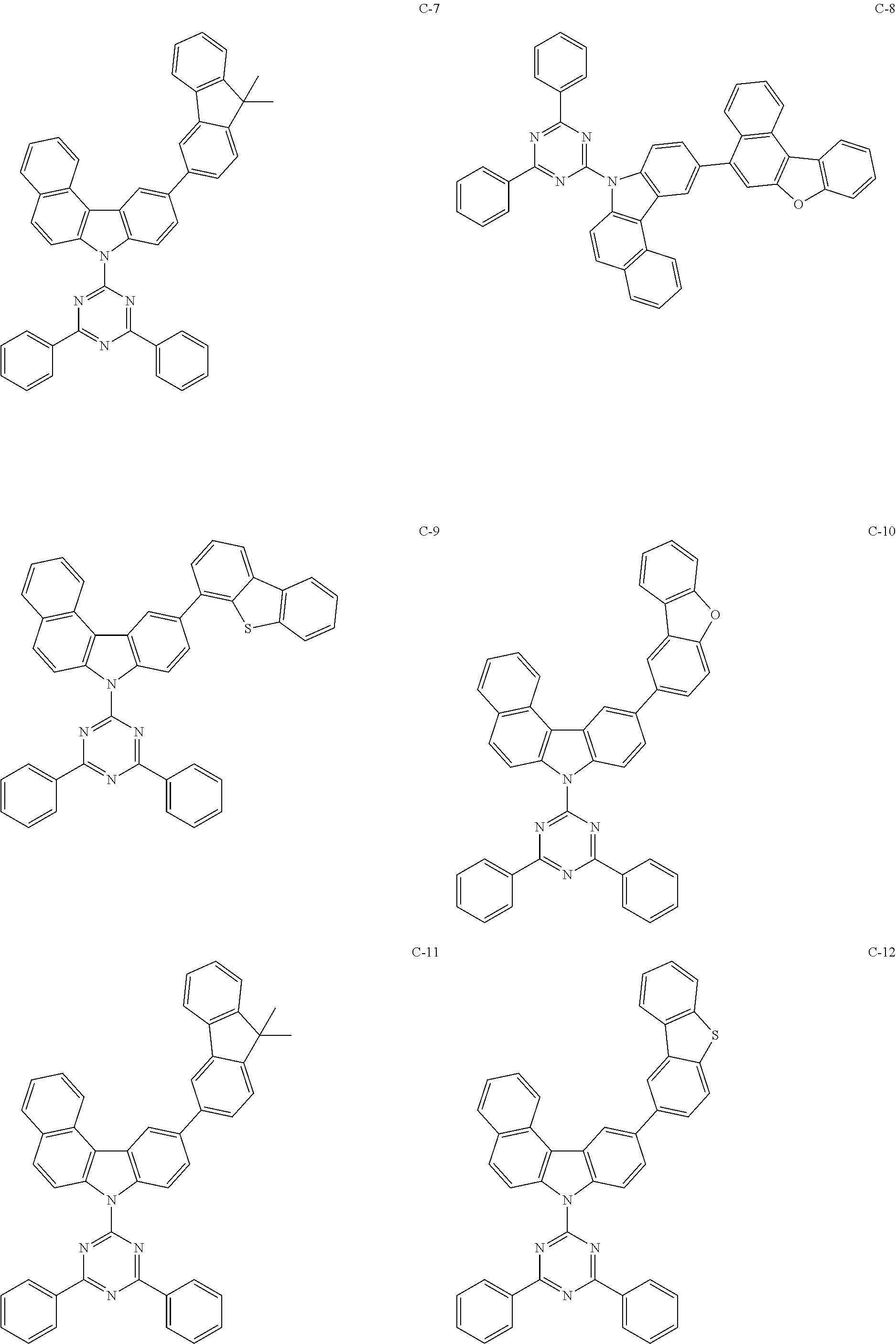

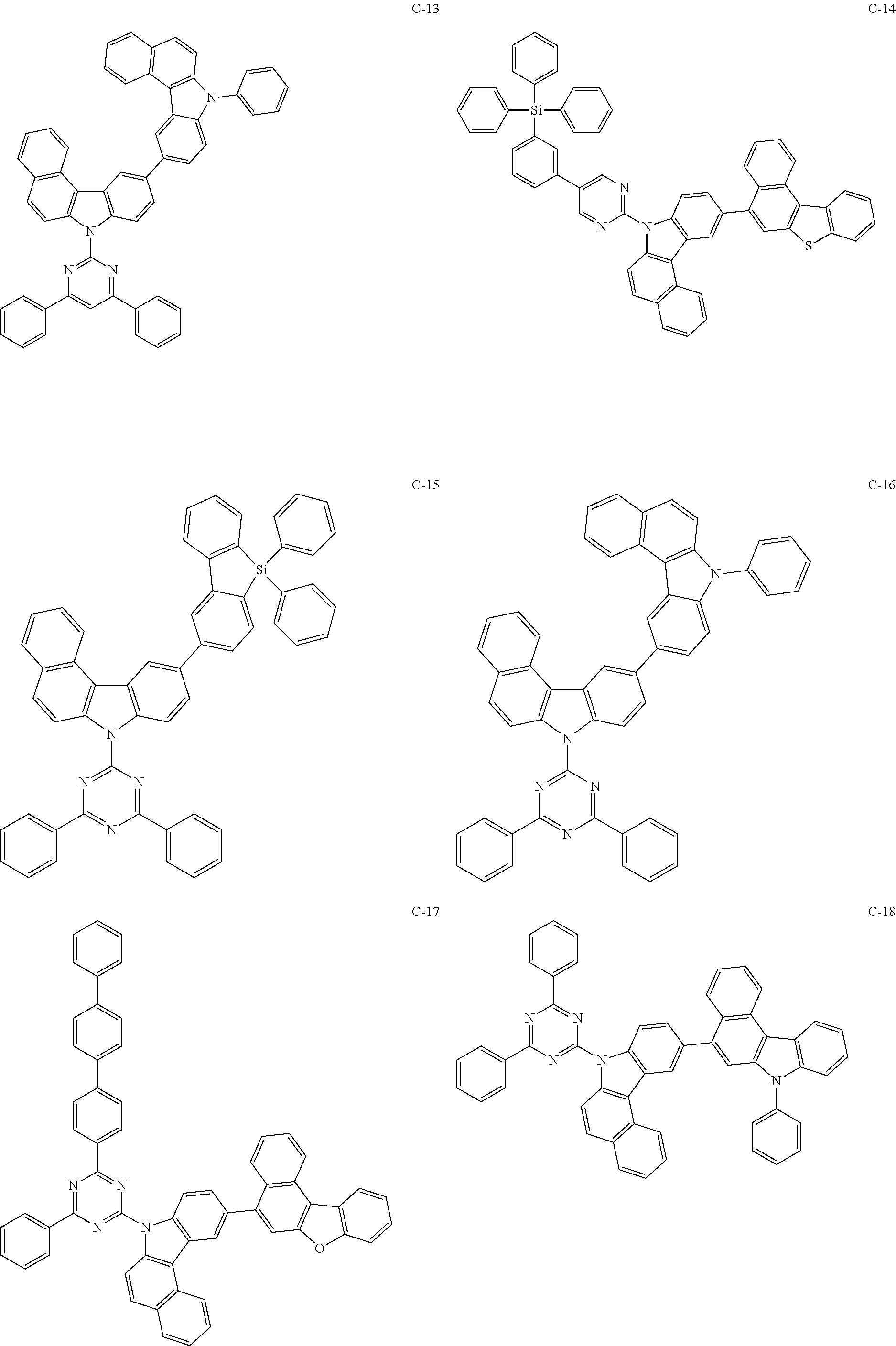

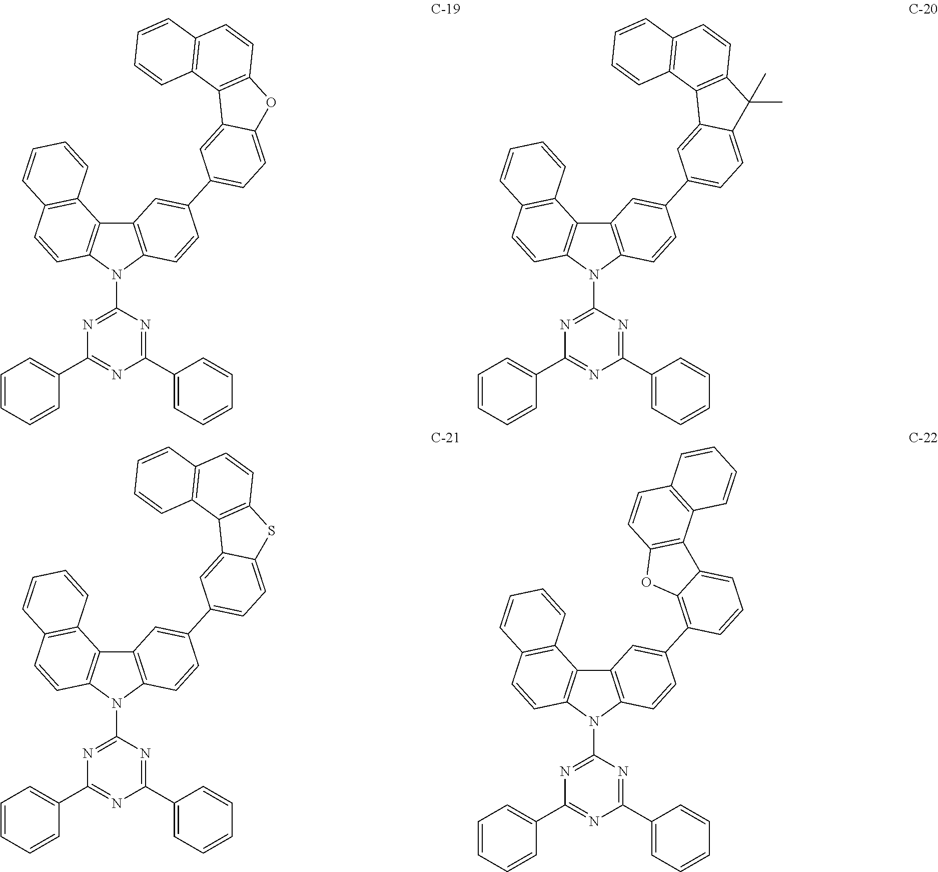

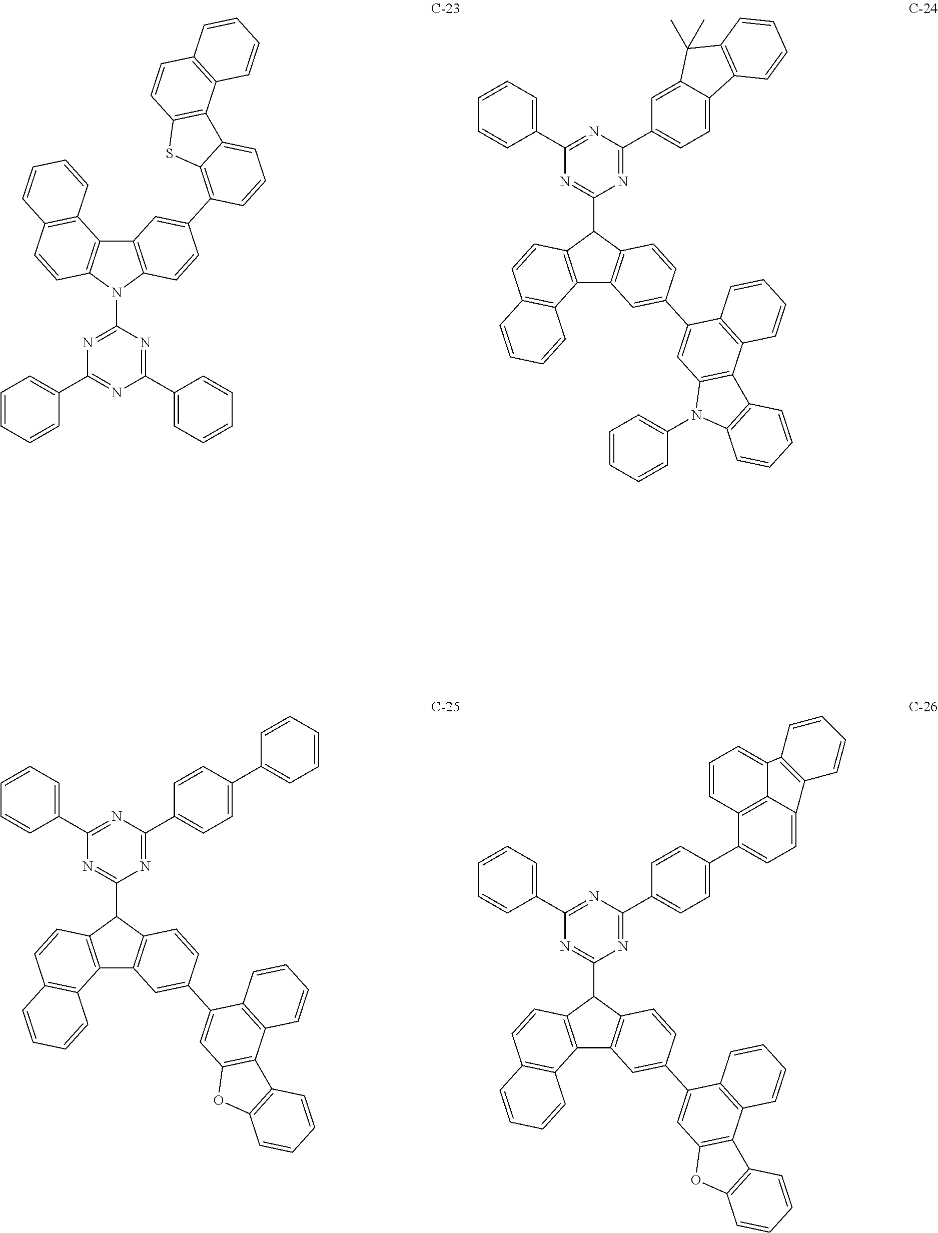 [SMILES: c1ccc(-c2nc(-c3ccccc3)nc(-n3c4ccc(-c5cccc6c5sc5ccc7ccccc7c56)cc4c4c5ccccc5ccc43)n2)cc1 ; CC1(C)c2ccccc2-c2ccc(-c3nc(-c4ccccc4)nc(C4c5ccc(-c6cc7c(c8ccccc68)c6ccccc6n7-c6ccccc6)cc5-c5c4ccc4ccccc54)n3)cc21 ; c1ccc(-c2ccc(-c3nc(-c4ccccc4)nc(C4c5ccc(-c6cc7oc8ccccc8c7c7ccccc67)cc5-c5c4ccc4ccccc54)n3)cc2)cc1 ; c1ccc(-c2nc(-c3ccc(-c4ccc5c6c(cccc46)-c4ccccc4-5)cc3)nc(C3c4ccc(-c5cc6oc7ccccc7c6c6ccccc56)cc4-c4c3ccc3ccccc43)n2)cc1]

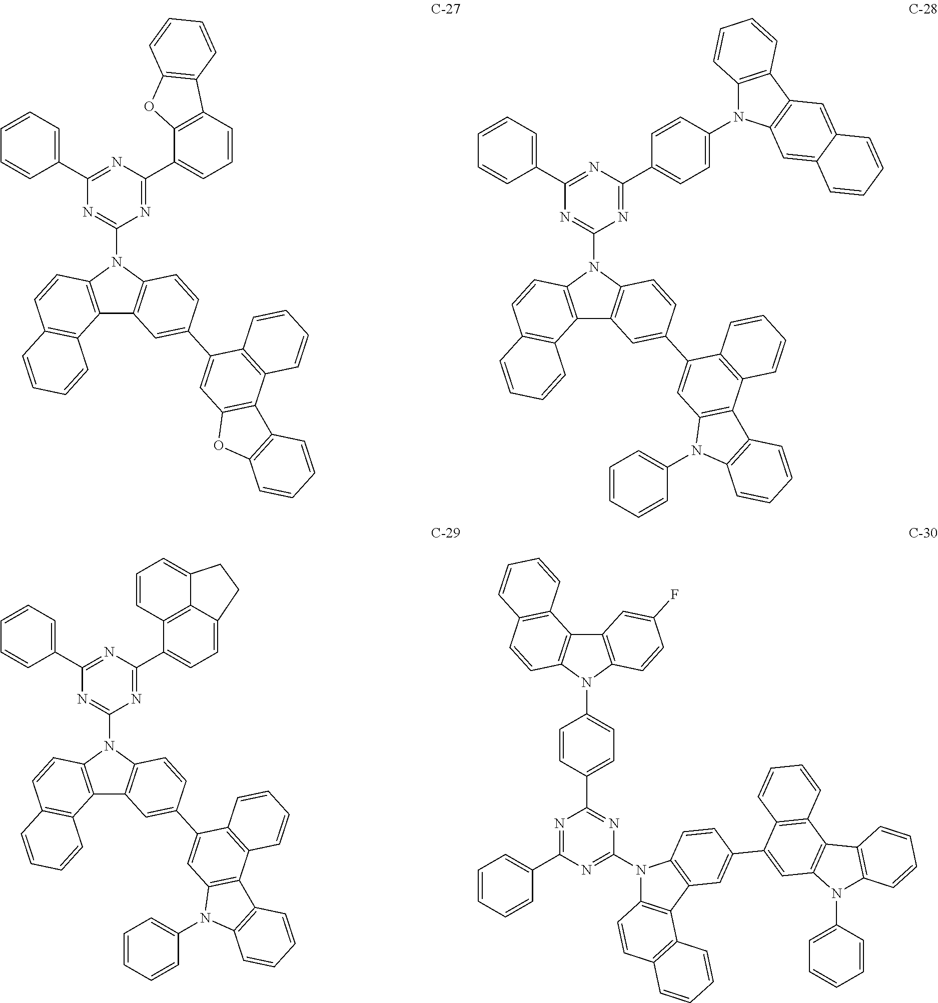 [SMILES: c1ccc(-c2nc(-c3cccc4c3oc3ccccc34)nc(-n3c4ccc(-c5cc6oc7ccccc7c6c6ccccc56)cc4c4c5ccccc5ccc43)n2)cc1 ; c1ccc(-c2nc(-c3ccc(-n4c5ccccc5c5cc6ccccc6cc54)cc3)nc(-n3c4ccc(-c5cc6c(c7ccccc57)c5ccccc5n6-c5ccccc5)cc4c4c5ccccc5ccc43)n2)cc1 ; c1ccc(-c2nc(-c3ccc4c5c(cccc35)CC4)nc(-n3c4ccc(-c5cc6c(c7ccccc57)c5ccccc5n6-c5ccccc5)cc4c4c5ccccc5ccc43)n2)cc1 ; Fc1ccc2c(c1)c1c3ccccc3ccc1n2-c1ccc(-c2nc(-c3ccccc3)nc(-n3c4ccc(-c5cc6c(c7ccccc57)c5ccccc5n6-c5ccccc5)cc4c4c5ccccc5ccc43)n2)cc1]

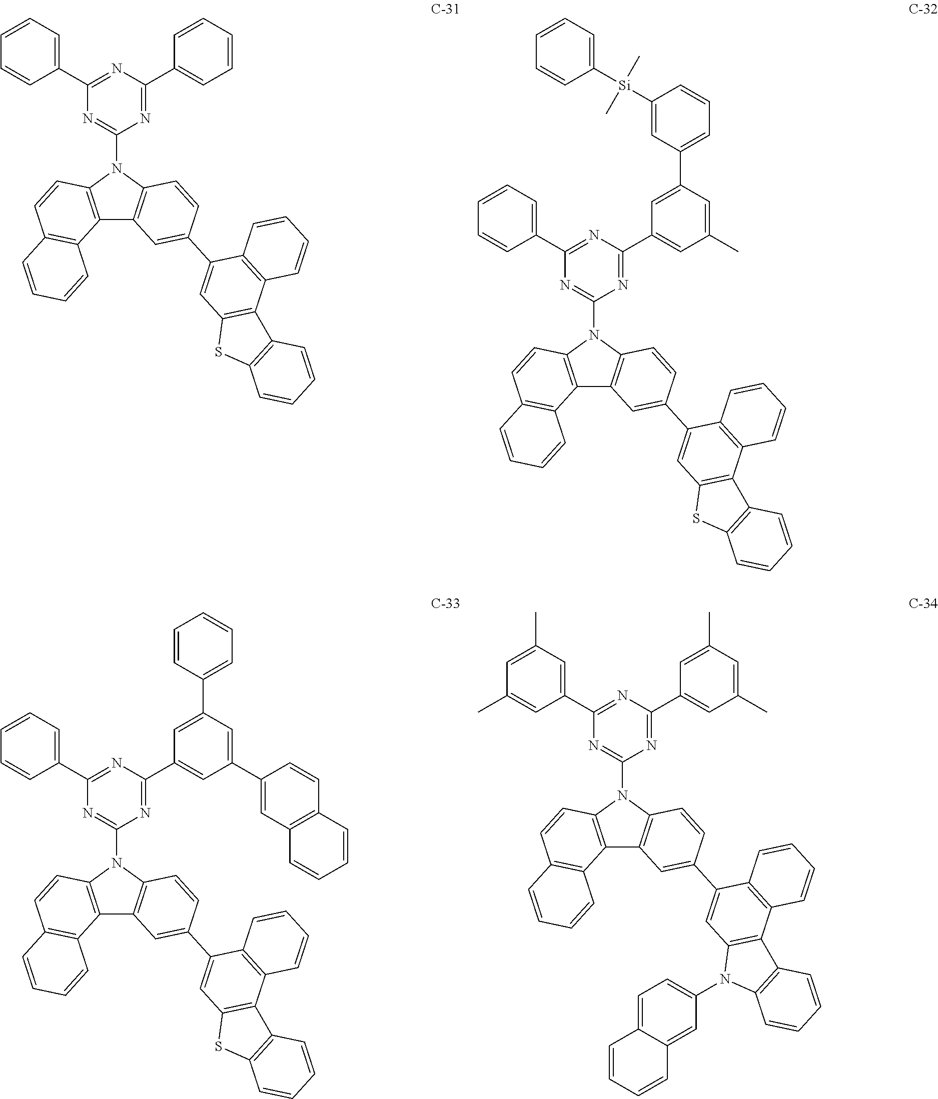 [SMILES: c1ccc(-c2nc(-c3ccccc3)nc(-n3c4ccc(-c5cc6sc7ccccc7c6c6ccccc56)cc4c4c5ccccc5ccc43)n2)cc1 ; Cc1cc(-c2cccc([Si](C)(C)c3ccccc3)c2)cc(-c2nc(-c3ccccc3)nc(-n3c4ccc(-c5cc6sc7ccccc7c6c6ccccc56)cc4c4c5ccccc5ccc43)n2)c1 ; c1ccc(-c2cc(-c3ccc4ccccc4c3)cc(-c3nc(-c4ccccc4)nc(-n4c5ccc(-c6cc7sc8ccccc8c7c7ccccc67)cc5c5c6ccccc6ccc54)n3)c2)cc1 ; Cc1cc(C)cc(-c2nc(-c3cc(C)cc(C)c3)nc(-n3c4ccc(-c5cc6c(c7ccccc57)c5ccccc5n6-c5ccc6ccccc6c5)cc4c4c5ccccc5ccc43)n2)c1]

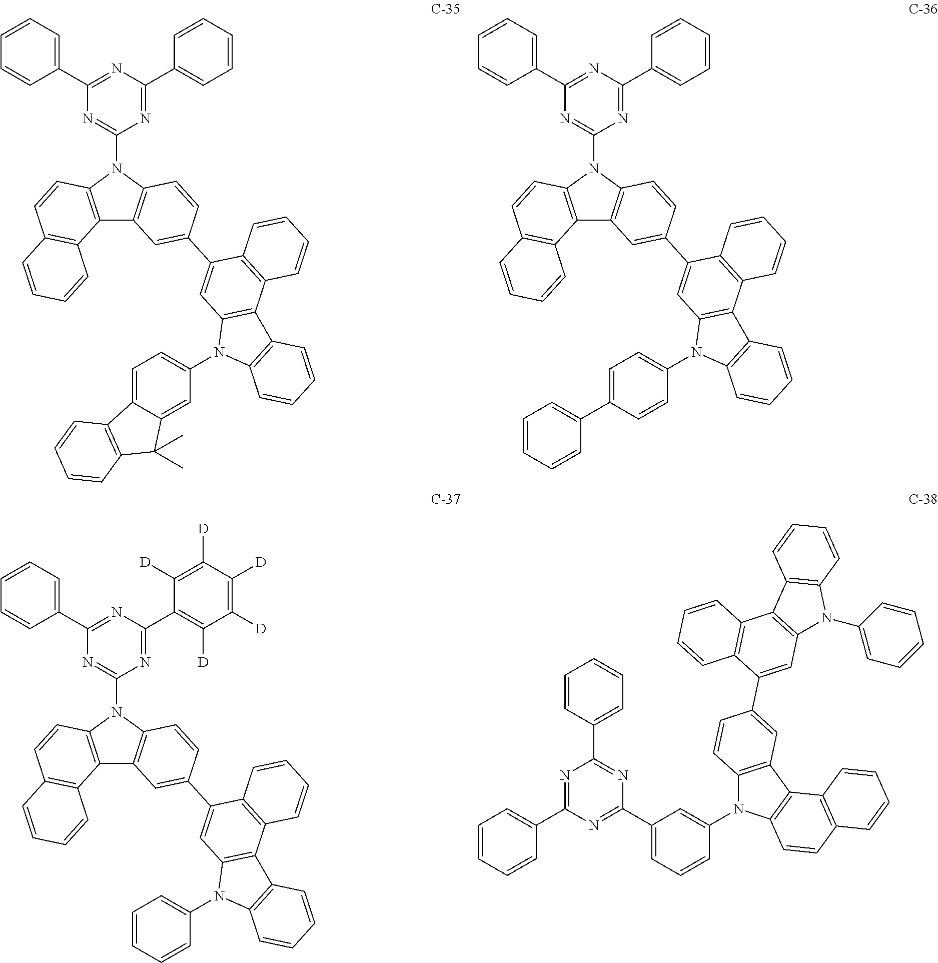 [SMILES: CC1(C)c2ccccc2-c2ccc(-n3c4ccccc4c4c5ccccc5c(-c5ccc6c(c5)c5c7ccccc7ccc5n6-c5nc(-c6ccccc6)nc(-c6ccccc6)n5)cc43)cc21 ; c1ccc(-c2ccc(-n3c4ccccc4c4c5ccccc5c(-c5ccc6c(c5)c5c7ccccc7ccc5n6-c5nc(-c6ccccc6)nc(-c6ccccc6)n5)cc43)cc2)cc1 ; [2H]c1c([2H])c([2H])c(-c2nc(-c3ccccc3)nc(-n3c4ccc(-c5cc6c(c7ccccc57)c5ccccc5n6-c5ccccc5)cc4c4c5ccccc5ccc43)n2)c([2H])c1[2H] ; c1ccc(-c2nc(-c3ccccc3)nc(-c3cccc(-n4c5ccc(-c6cc7c(c8ccccc68)c6ccccc6n7-c6ccccc6)cc5c5c6ccccc6ccc54)c3)n2)cc1]

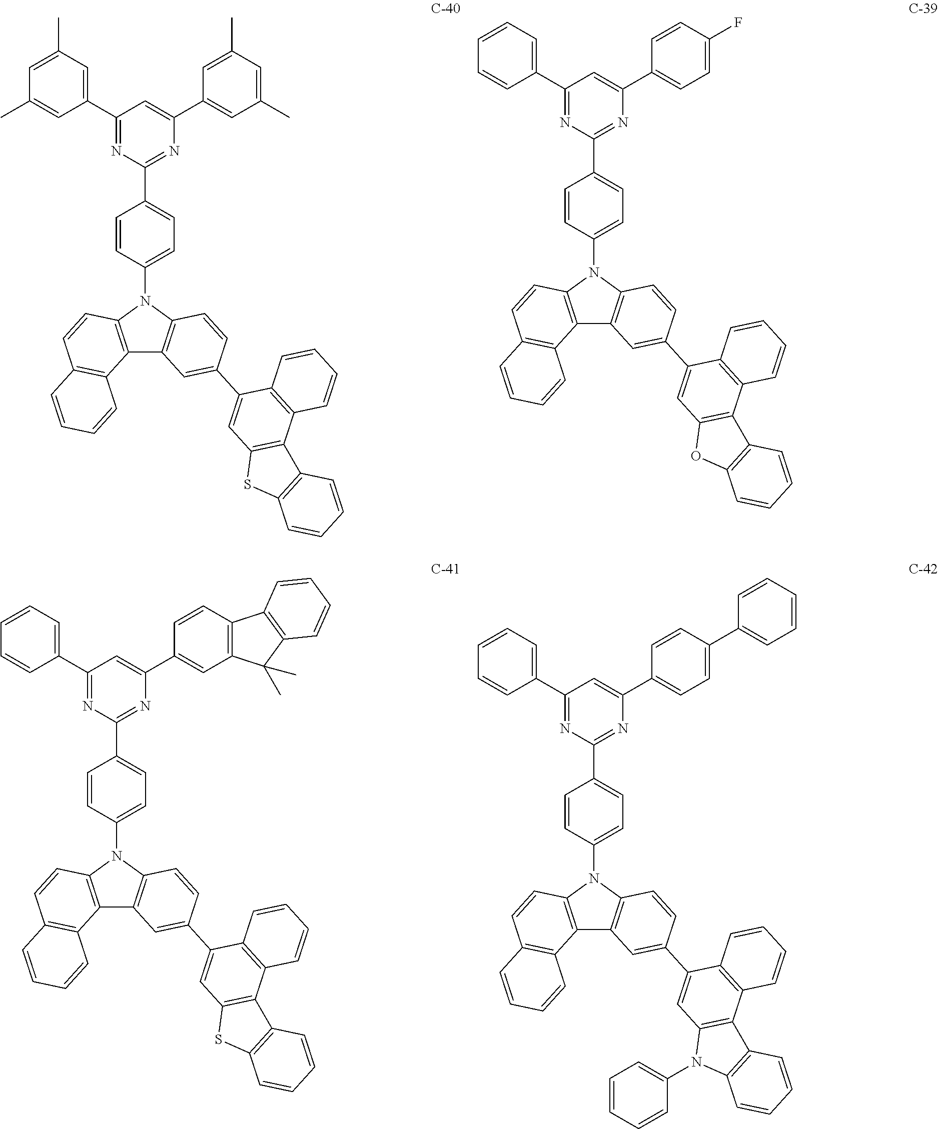

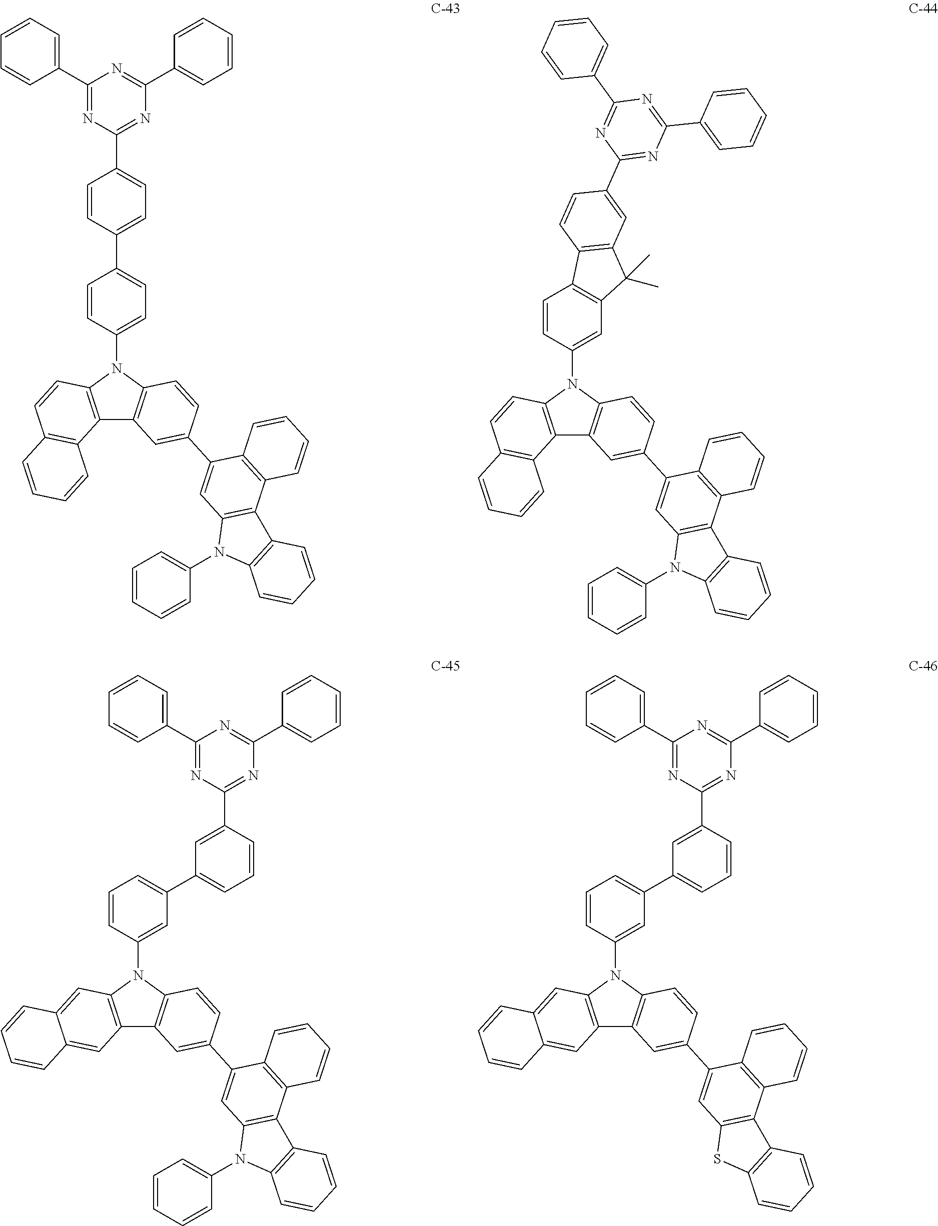

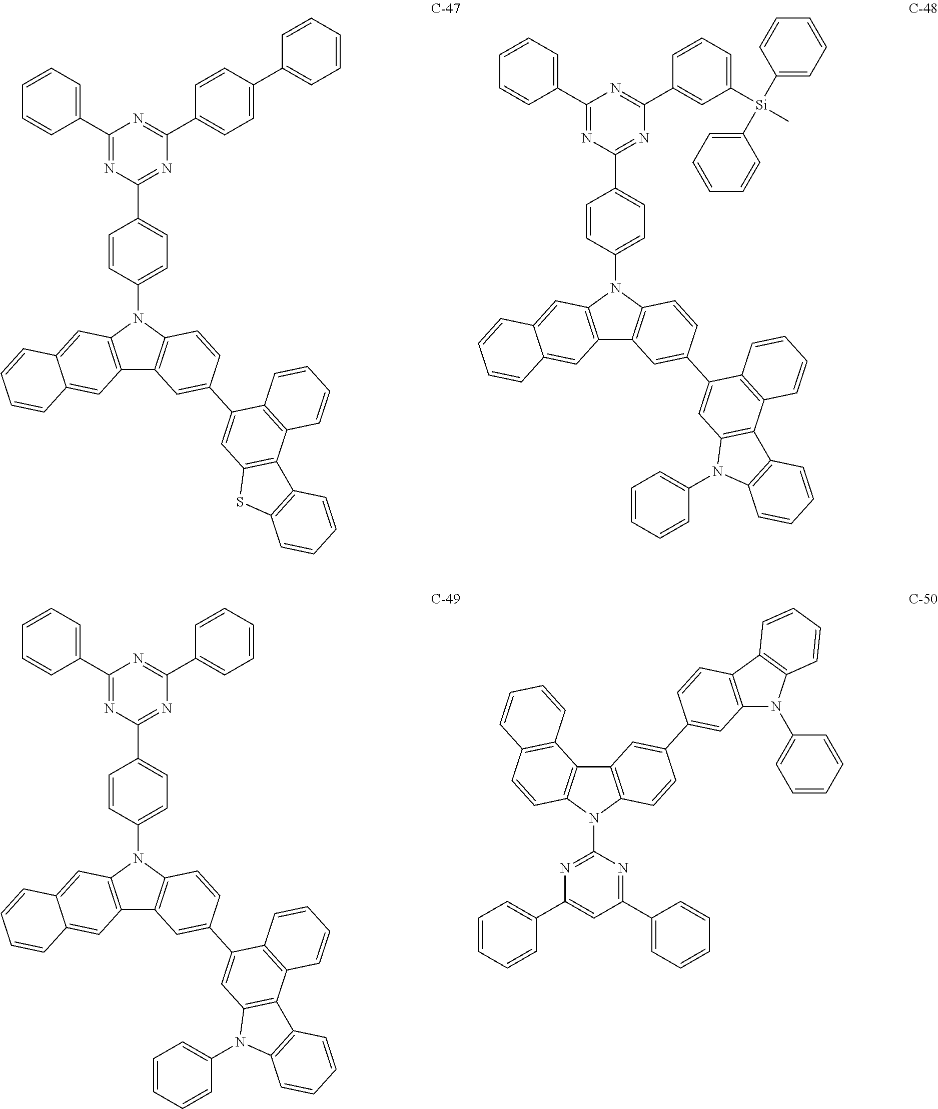 [SMILES: c1ccc(-c2ccc(-c3nc(-c4ccccc4)nc(-c4ccc(-n5c6ccc(-c7cc8sc9ccccc9c8c8ccccc78)cc6c6cc7ccccc7cc65)cc4)n3)cc2)cc1 ; C[Si](c1ccccc1)(c1ccccc1)c1cccc(-c2nc(-c3ccccc3)nc(-c3ccc(-n4c5ccc(-c6cc7c(c8ccccc68)c6ccccc6n7-c6ccccc6)cc5c5cc6ccccc6cc54)cc3)n2)c1 ; c1ccc(-c2nc(-c3ccccc3)nc(-c3ccc(-n4c5ccc(-c6cc7c(c8ccccc68)c6ccccc6n7-c6ccccc6)cc5c5cc6ccccc6cc54)cc3)n2)cc1 ; c1ccc(-c2cc(-c3ccccc3)nc(-n3c4ccc(-c5ccc6c7ccccc7n(-c7ccccc7)c6c5)cc4c4c5ccccc5ccc43)n2)cc1]

The organic electroluminescent compounds according to the present invention can be prepared according to the following reaction scheme.

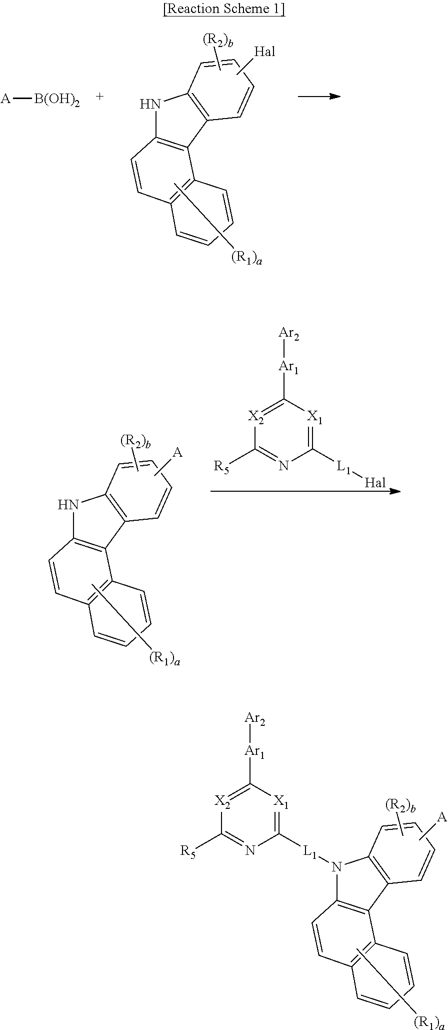

wherein A, X₁, X₂, Ar₁, Ar₂, L₁, R₁ to R₅, Y, a and b are as defined in formula 1 above, and Hal represents a halogen.

In addition, the present invention provides an organic electroluminescent material comprising the organic electroluminescent compound of formula 1, and an organic electroluminescent device comprising the material.

The above material can be comprised of the organic electroluminescent compound according to the present invention alone, or can further include conventional materials generally used in organic electroluminescent materials.

The organic electroluminescent device comprises a first electrode, a second electrode, and at least one organic layer between the first and second electrodes. The organic layer comprises at least one compound of formula 1 according to the present invention. Further, the organic layer comprises a light-emitting layer in which the compound of formula 1 is comprised as a host material.

One of the first electrode and the second electrode is an anode, and the other is a cathode. The organic layer comprises a light-emitting layer, and at least one layer selected from the group consisting of a hole injection layer, a hole transport layer, an electron transport layer, an electron injection layer, an interlayer, a hole blocking layer and an electron blocking layer.

The organic electroluminescent compound according to the present invention can be comprised of in the light-emitting layer. Where used in the light-emitting layer, the organic electroluminescent compound according to the present invention can be comprised as a host material.

The light-emitting layer can further comprise at least one dopant, and, if needed, another compound as a second host material in addition to the organic electroluminescent compound according to the present invention.

The second host material can be from any of the known phosphorescent dopants. Specifically, the phosphorescent dopant selected from the group consisting of the compounds of formula 2 to 6 below is preferable in view of luminous efficiency.

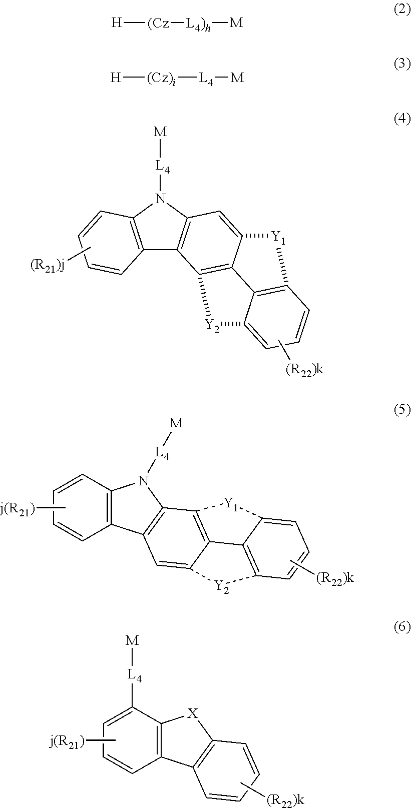

Wherein

Cz represents

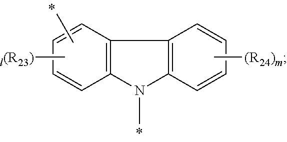

X represents O or S;

R₂₁ to R₂₄ each independently represent hydrogen, deuterium, a halogen, a substituted or unsubstituted (C1-C30)alkyl group, a substituted or unsubstituted (C6-C30)aryl group, a substituted or unsubstituted 5- to 30-membered heteroaryl group, or R₂₅R₂₆R₂₇Si—;

R₂₅ to R₂₇ each independently represent a substituted or unsubstituted (C1-C30)alkyl group, or a substituted or unsubstituted (C6-C30)aryl group;

L₄ represents a single bond, a substituted or unsubstituted (C6-C30)arylene group, or a substituted or unsubstituted 5- to 30-membered heteroarylene group;

M represents a substituted or unsubstituted (C6-C30)aryl group, or a substituted or unsubstituted 5- to 30-membered heteroaryl group;

Y₁ and Y₂ represent —O—, —S—, —N(R₃₁)— or —C(R₃₂)(R₃₃)—, and Y₁ and Y₂ cannot exist simultaneously;

R₃₁ to R₃₃ each independently represent a substituted or unsubstituted (C1-C30)alkyl group, a substituted or unsubstituted (C6-C30)aryl group, or a substituted or unsubstituted 5- to 30-membered heteroaryl group, and R₃₂ and R₃₃ are the same or different;

h and i each independently represent an integer of 1 to 3;

j, k, l, and m each independently represent an integer of 0 to 4; and

where h, i, j, k, l, or m is an integer of 2 or more, each of (Cz-L₄), each of (Cz), each of R₂₁, each of R₂₂, each of R₂₃ or each of R₂₄ is the same or different.

Specifically, preferable examples of the second host material are as follows:

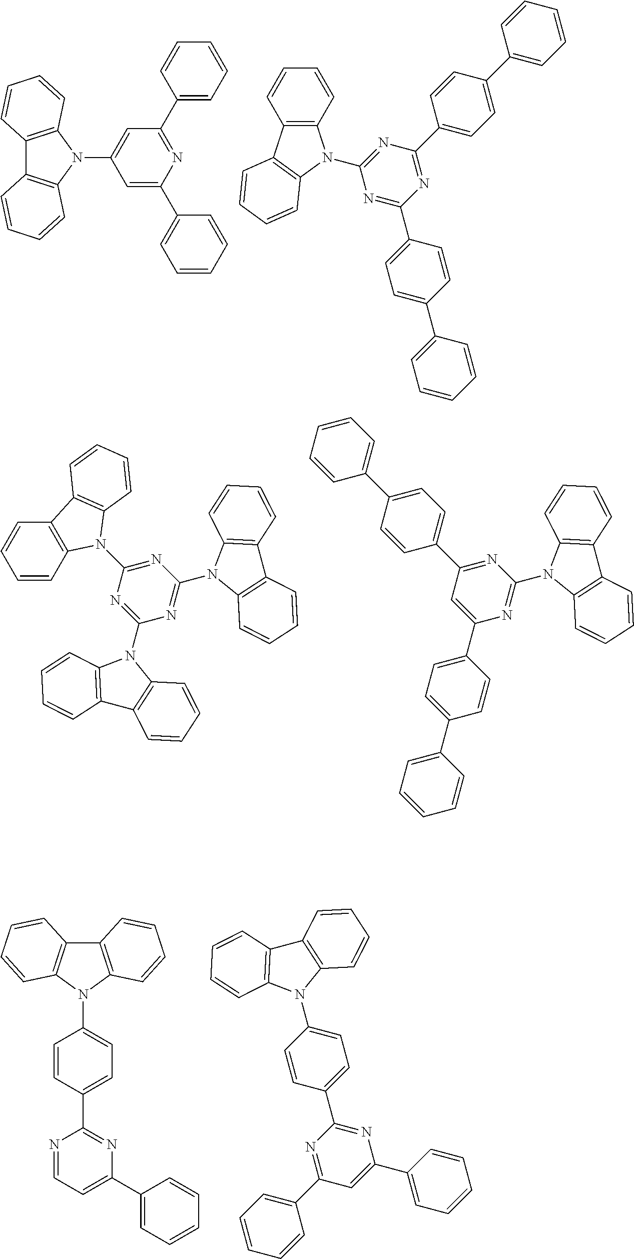

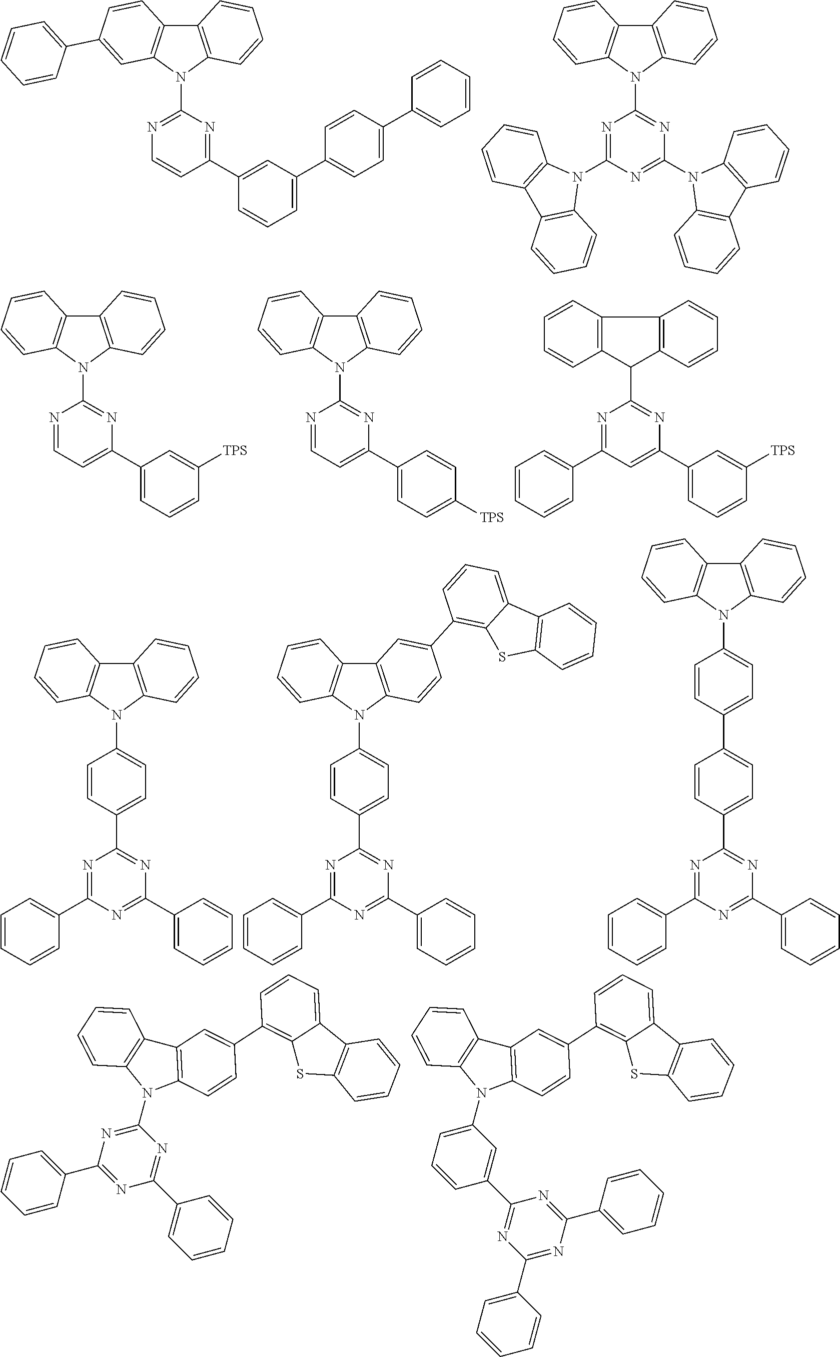

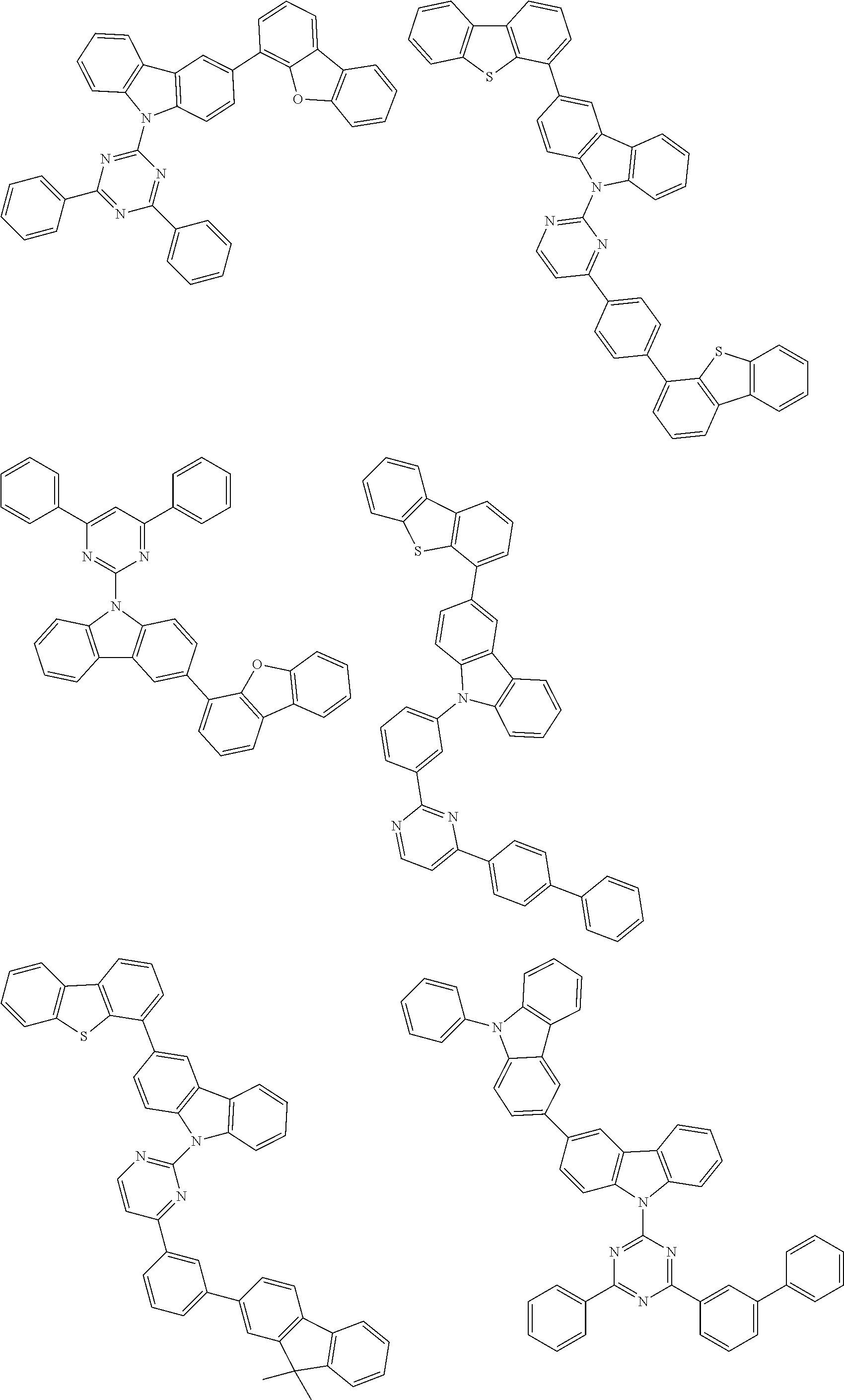

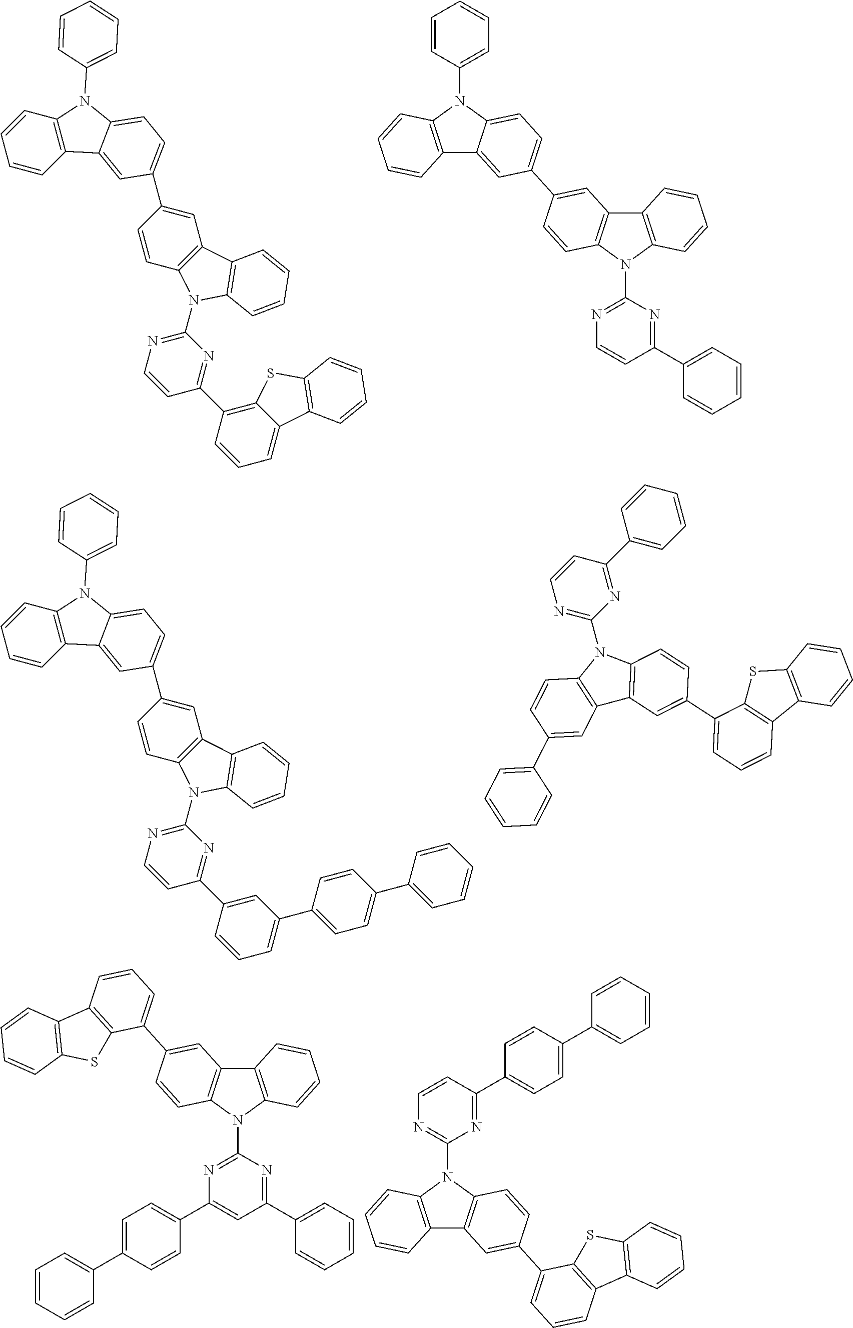

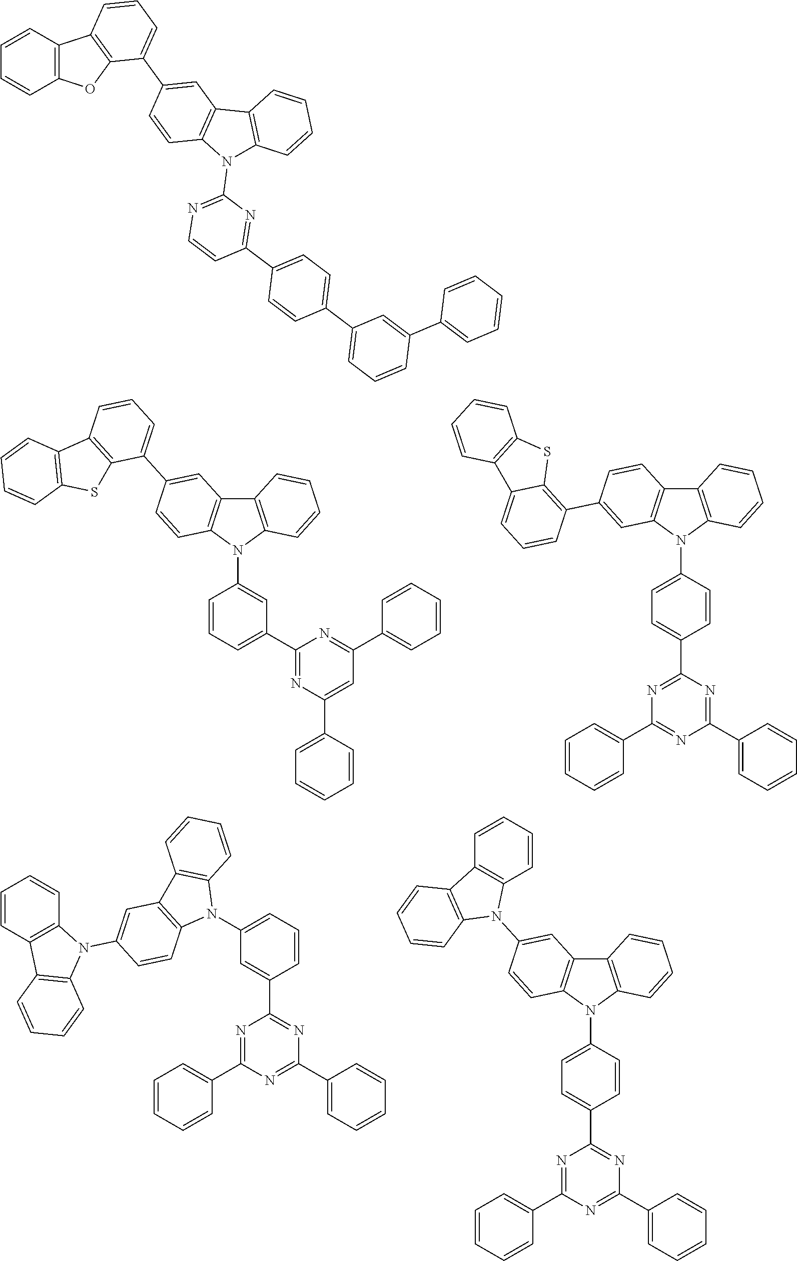 [SMILES: c1ccc(-c2cccc(-c3ccc(-c4ccnc(-n5c6ccccc6c6cc(-c7cccc8c7oc7ccccc78)ccc65)n4)cc3)c2)cc1 ; c1ccc(-c2cc(-c3ccccc3)nc(-c3cccc(-n4c5ccccc5c5cc(-c6cccc7c6sc6ccccc67)ccc54)c3)n2)cc1 ; c1ccc(-c2nc(-c3ccccc3)nc(-c3ccc(-n4c5ccccc5c5ccc(-c6cccc7c6sc6ccccc67)cc54)cc3)n2)cc1 ; c1ccc(-c2nc(-c3ccccc3)nc(-c3cccc(-n4c5ccccc5c5cc(-n6c7ccccc7c7ccccc76)ccc54)c3)n2)cc1 ; c1ccc(-c2nc(-c3ccccc3)nc(-c3ccc(-n4c5ccccc5c5cc(-n6c7ccccc7c7ccccc76)ccc54)cc3)n2)cc1]

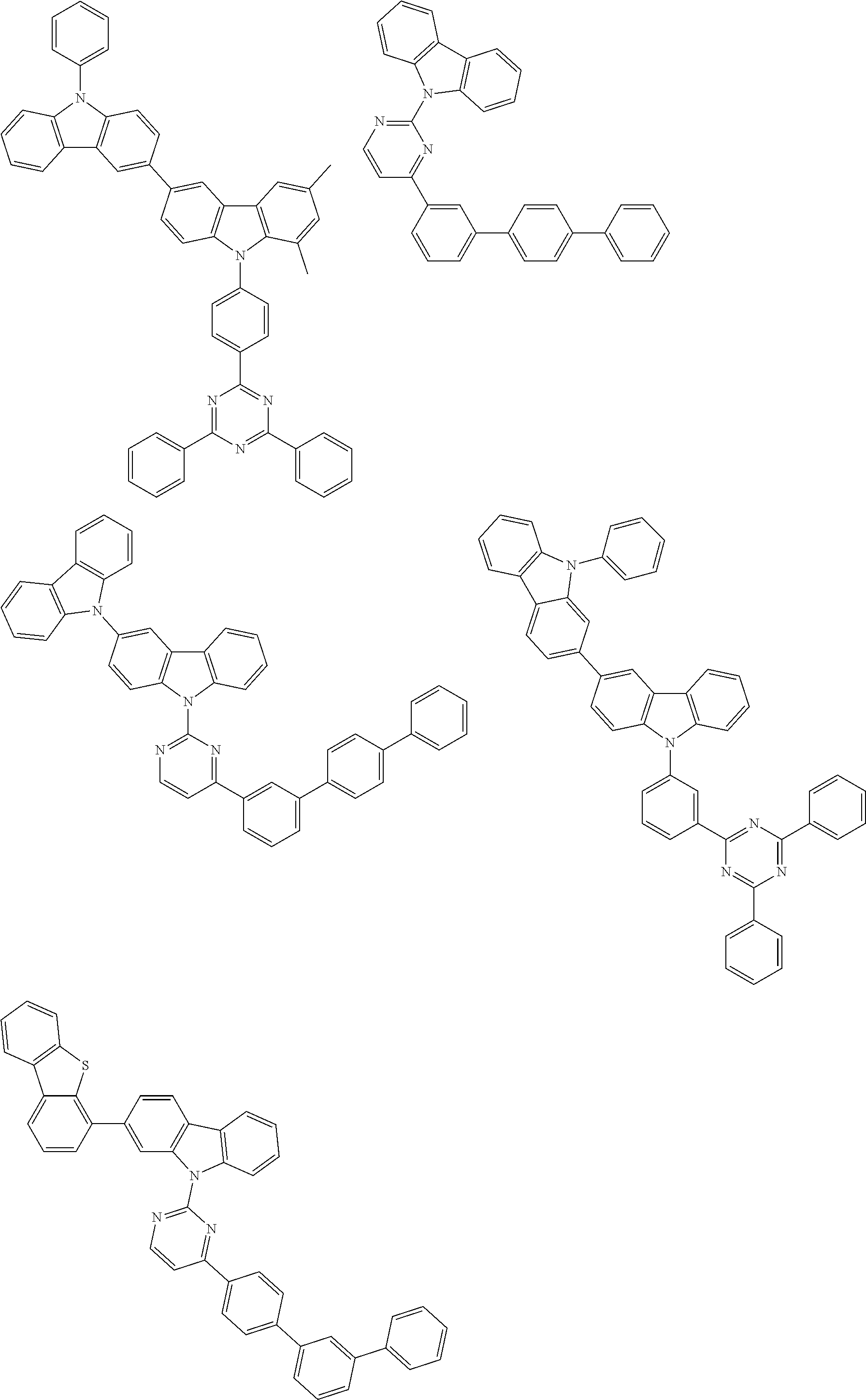

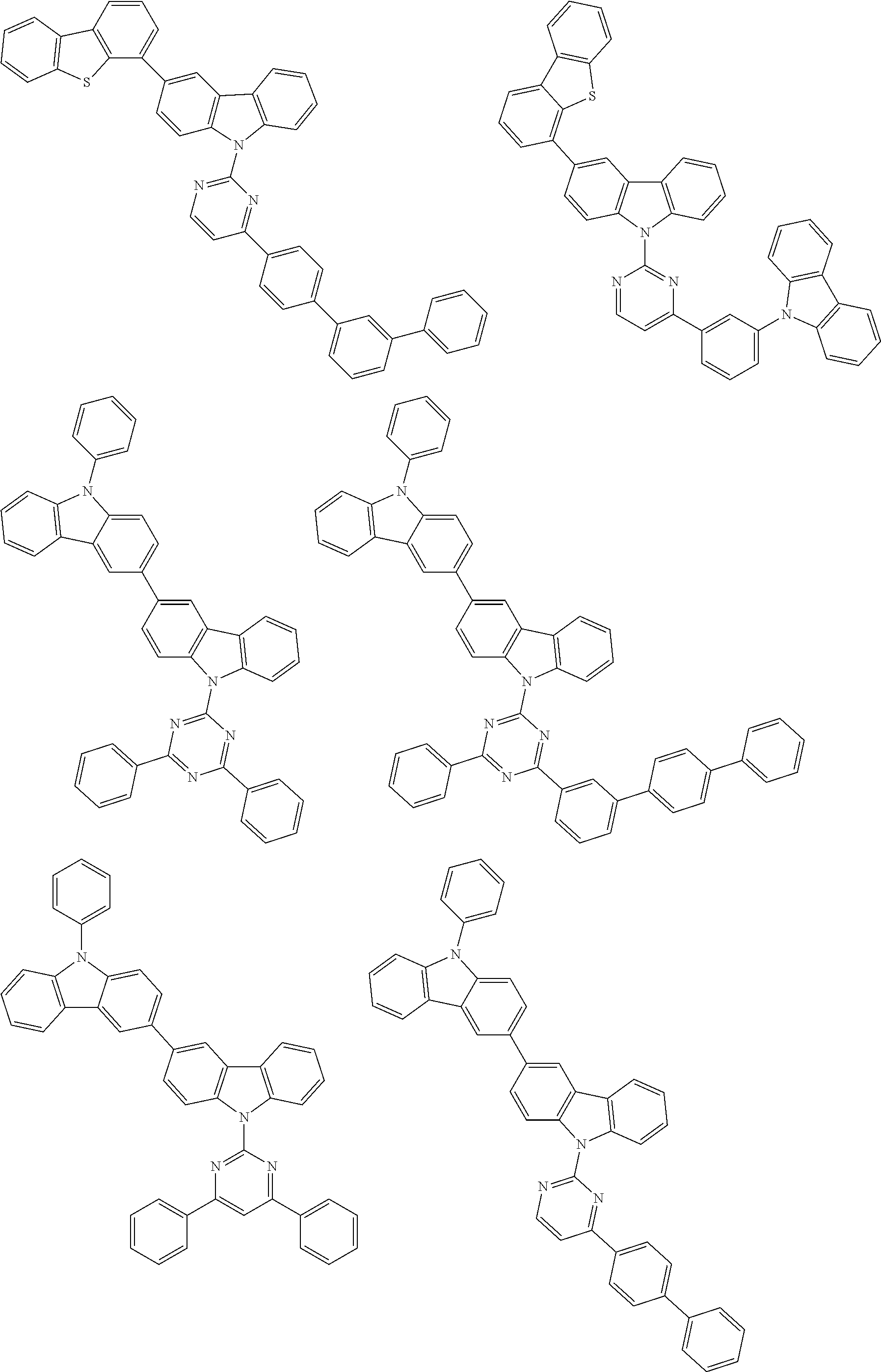

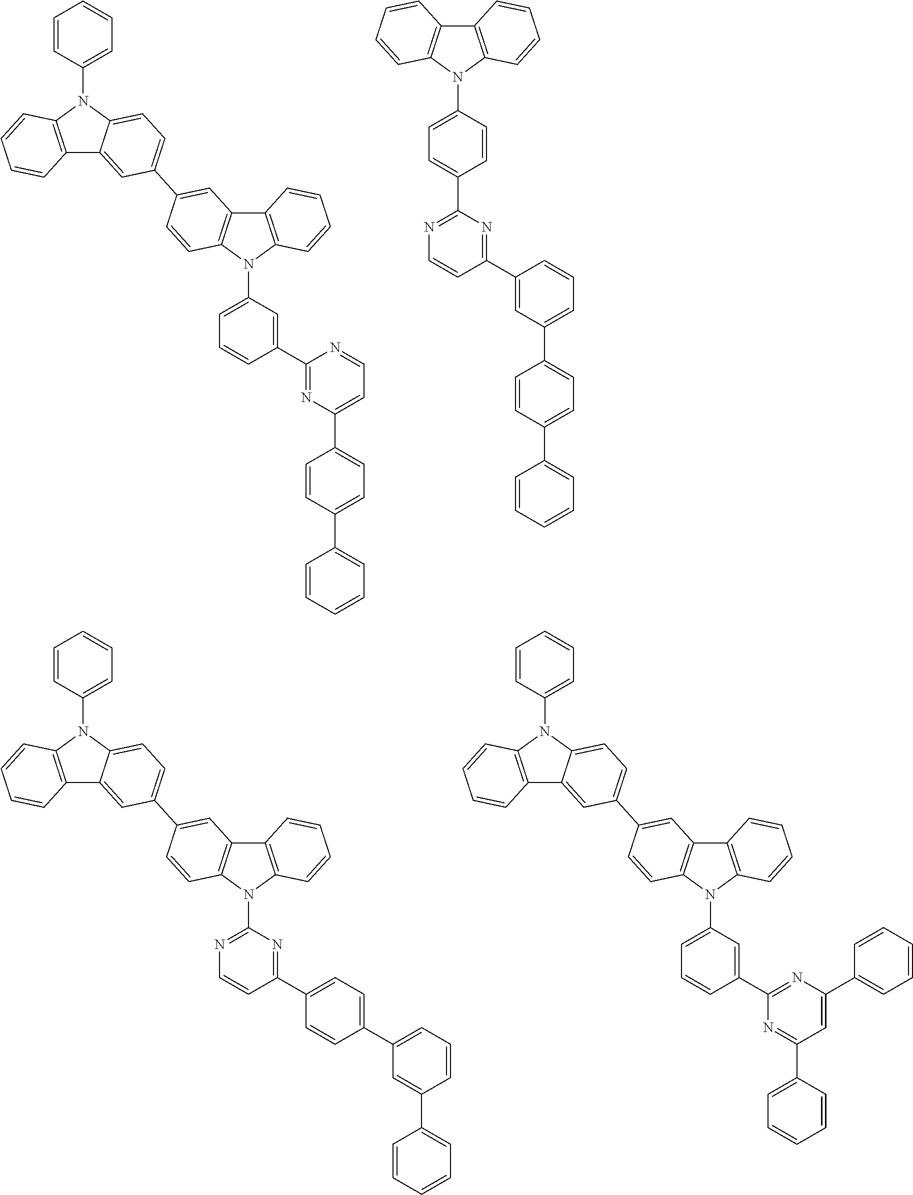 [SMILES: c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; c1ccc(-c2ccc(-c3cccc(-c4ccnc(-c5ccc(-n6c7ccccc7c7ccccc76)cc5)n4)c3)cc2)cc1 ; c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1]

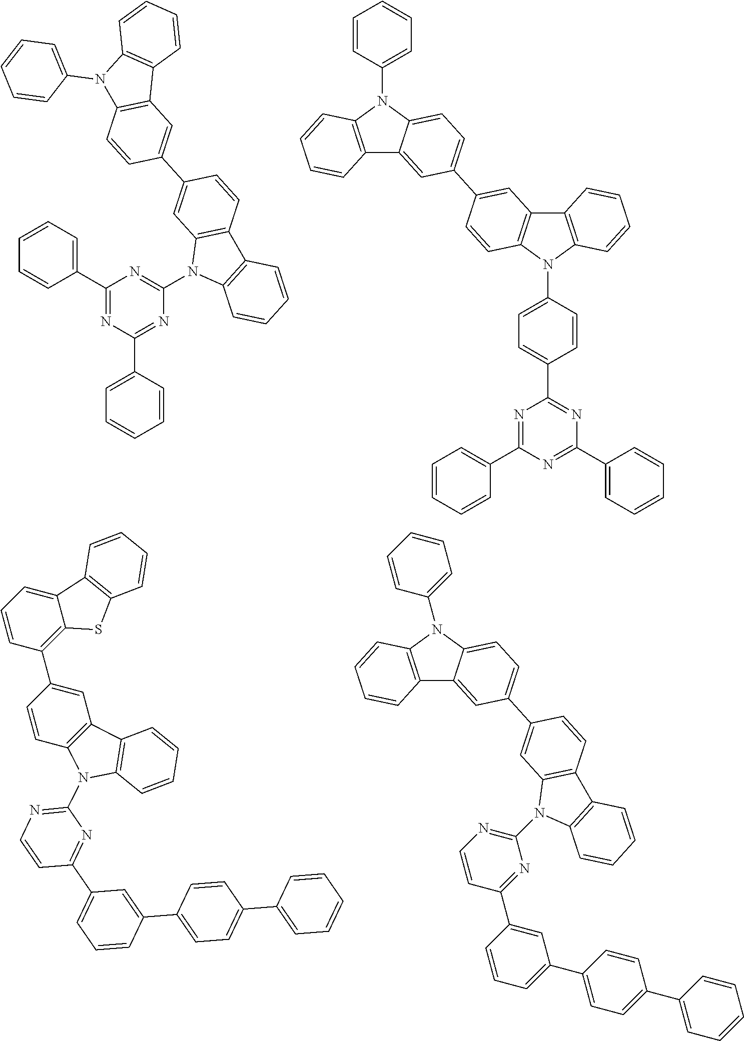

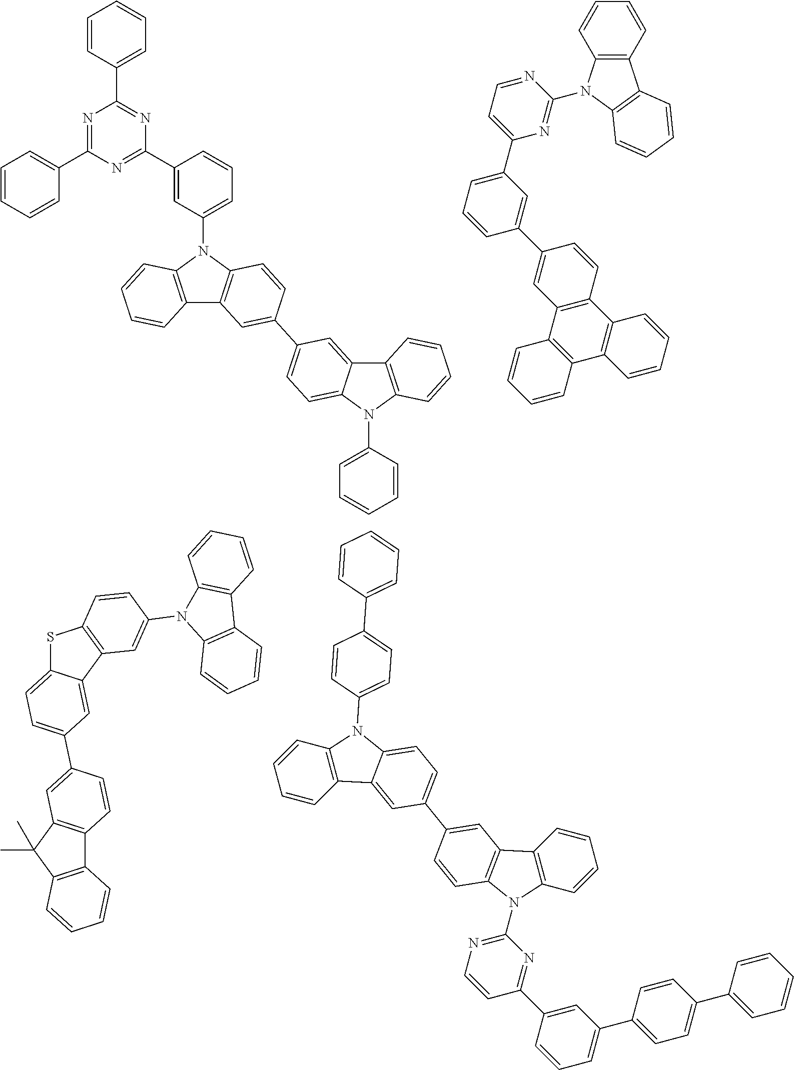

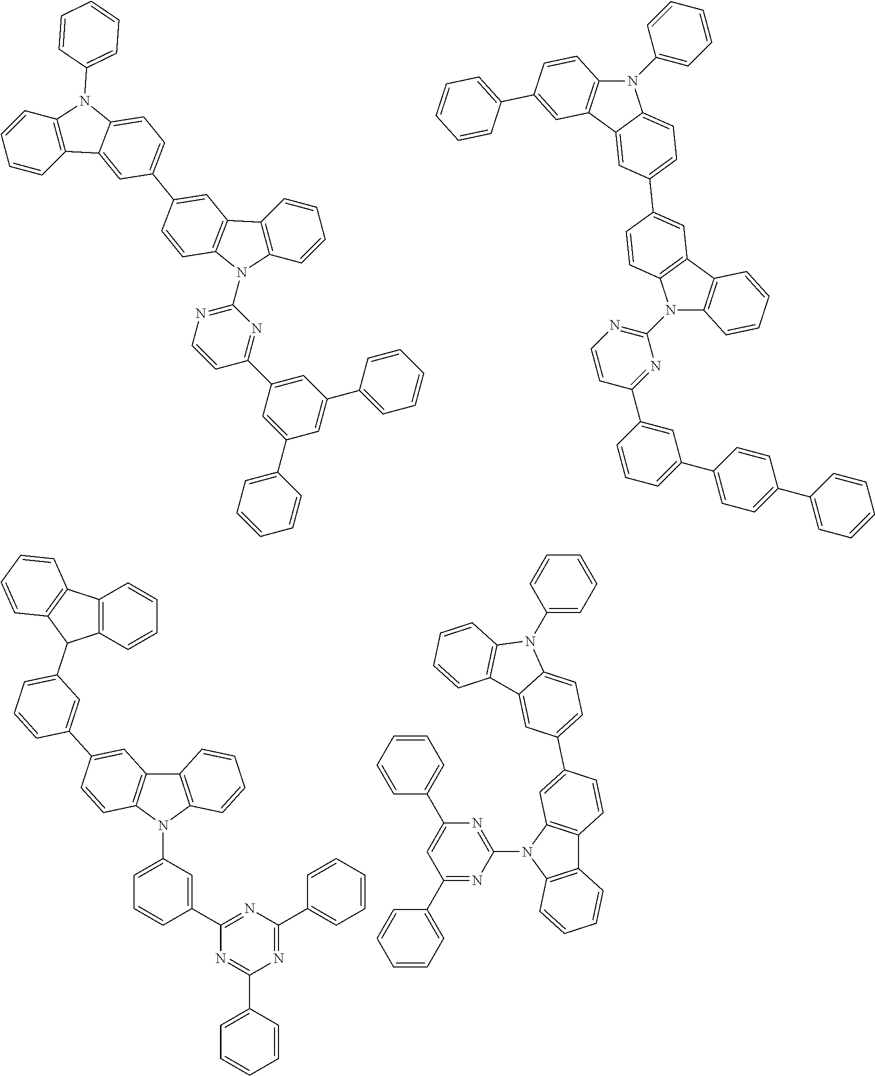

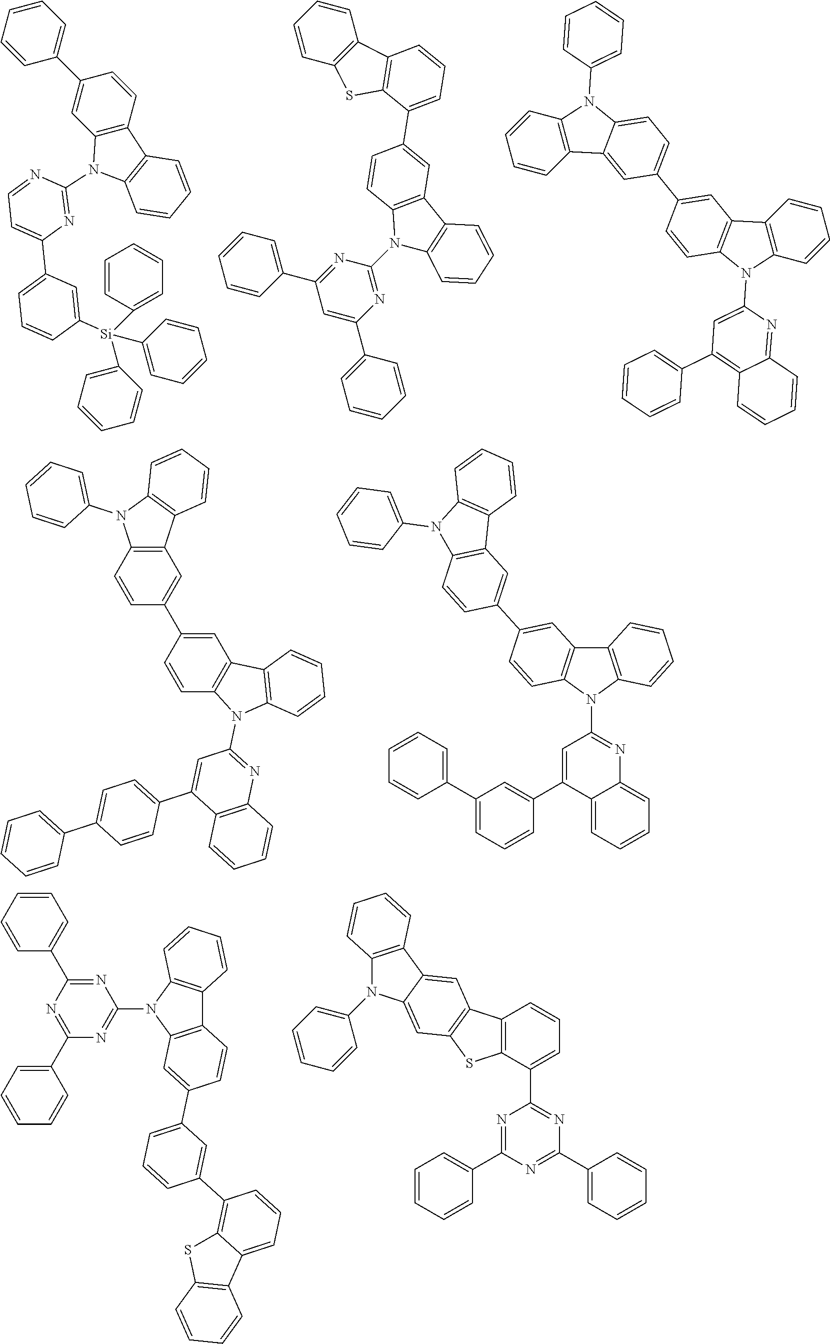

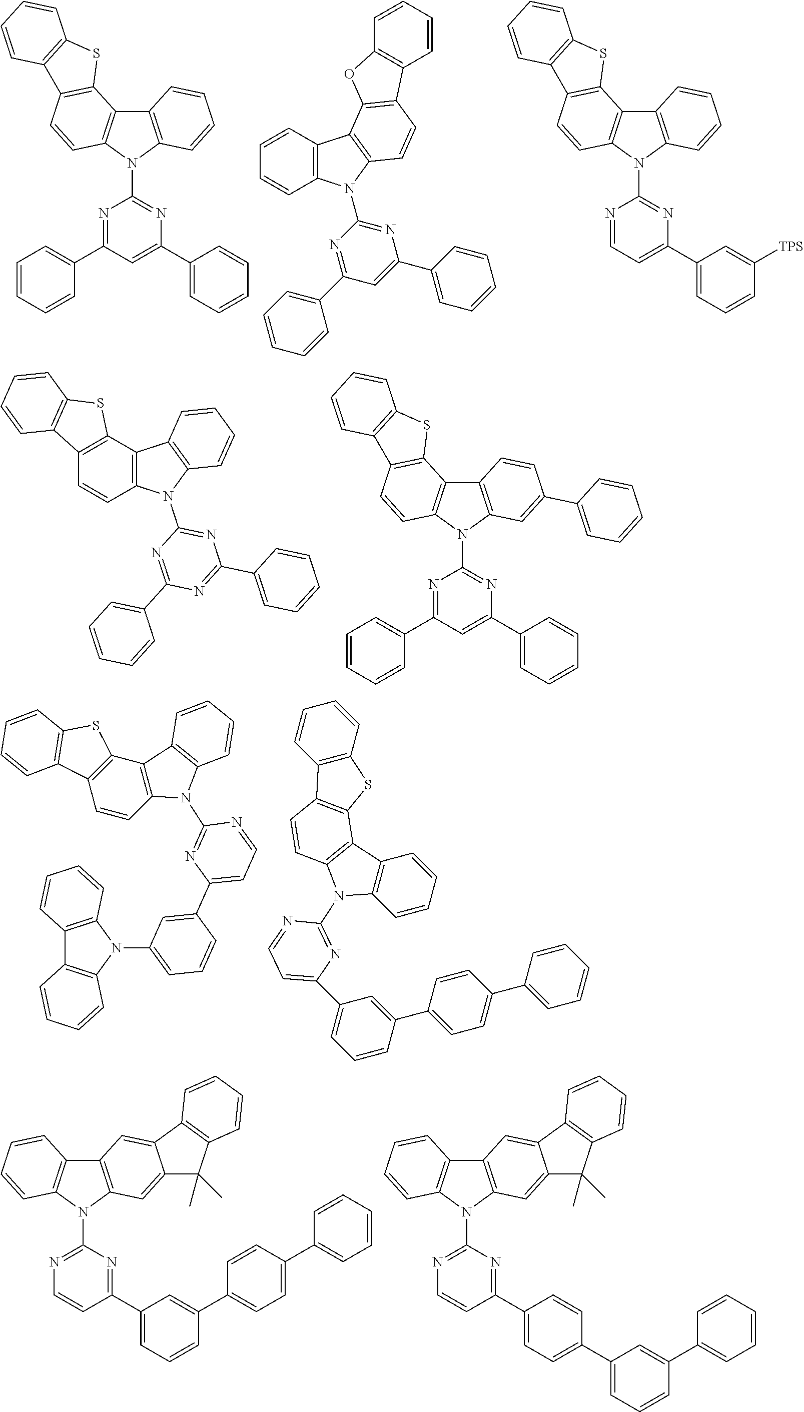

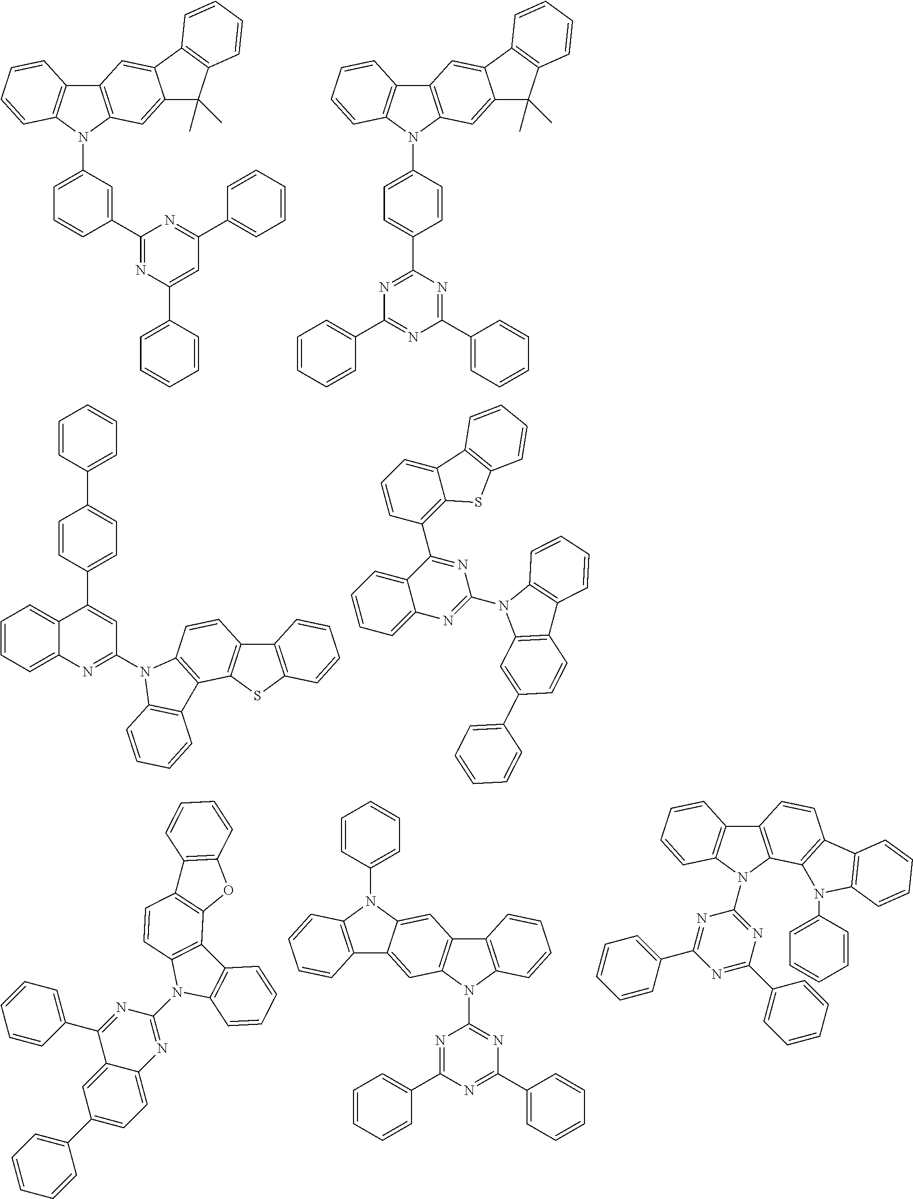

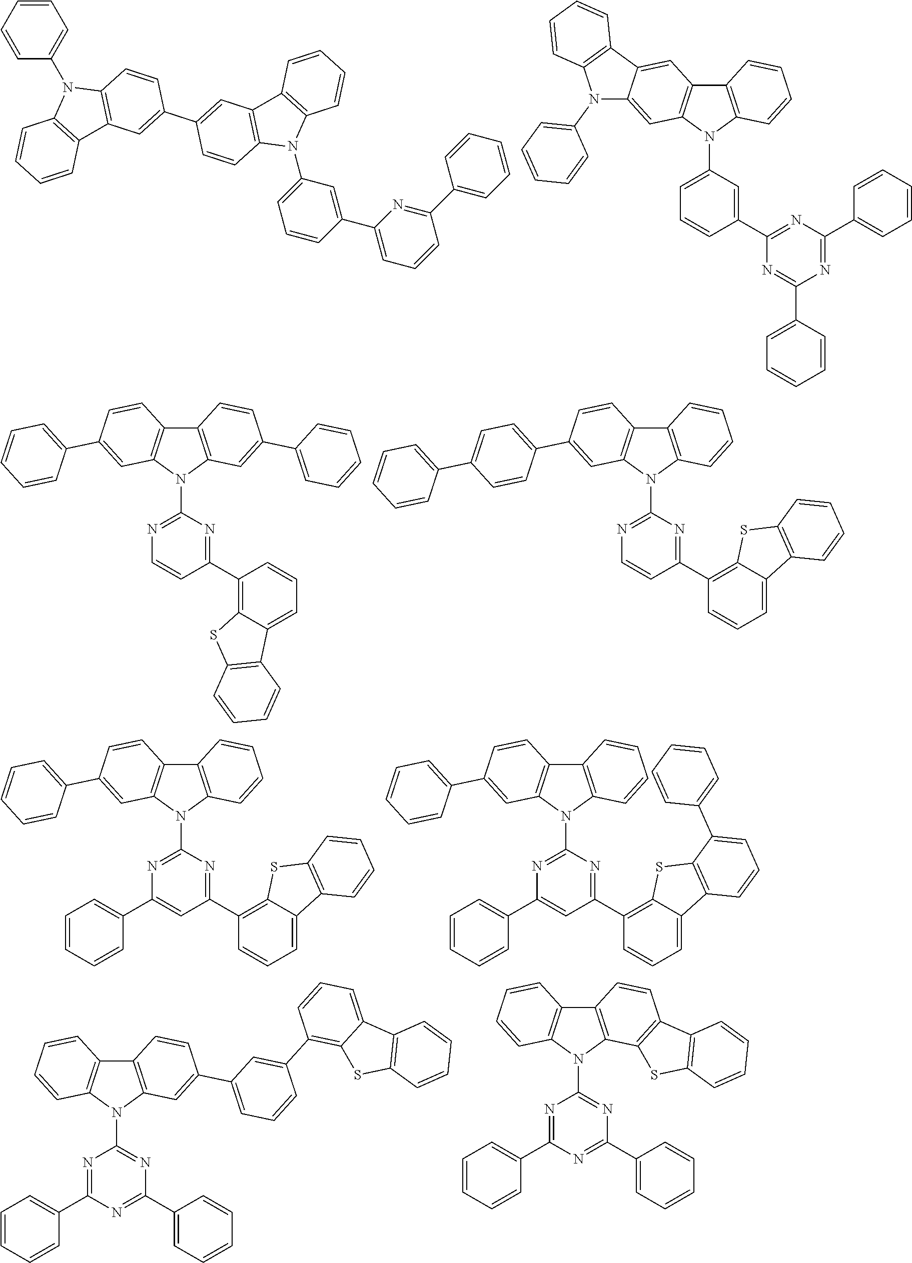

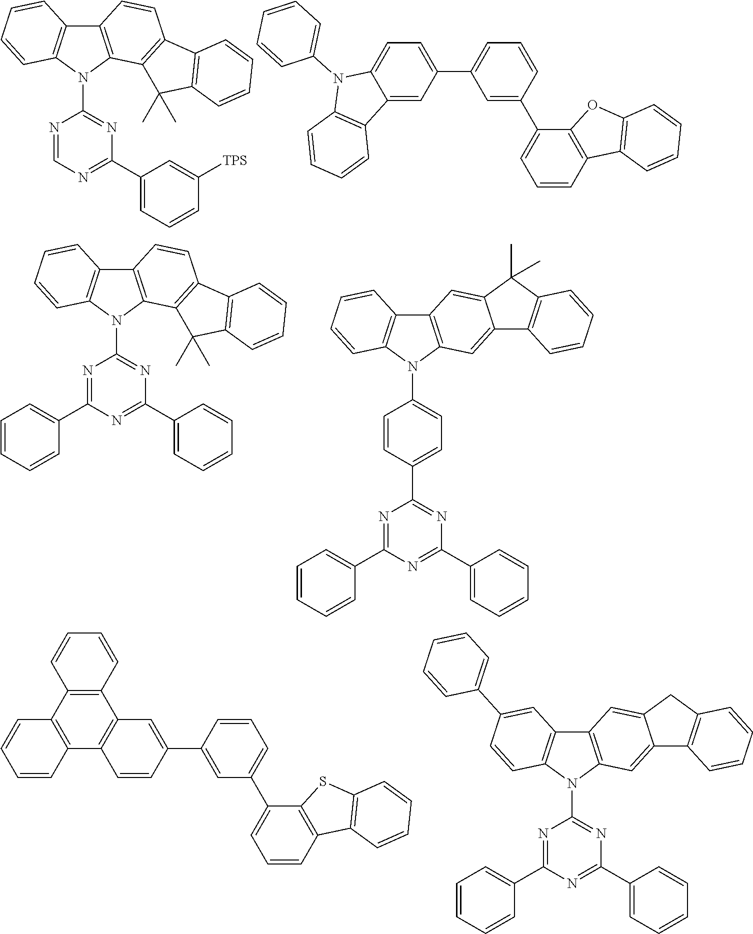

According to the present invention, the dopant used in the manufacture of the organic electroluminescent device is preferably one or more phosphorescent dopants. The phosphorescent dopant material applied to the electroluminescent device according to the present invention is not limited, but preferably may be selected from complex compounds of iridium, osmium, copper and platinum; more preferably ortho-metallated complex compounds of iridium, osmium, copper and platinum; and even more preferably ortho-metallated iridium complex compounds.

According to the present invention, the dopant comprised in the organic electroluminescent device may be selected from compounds represented by the following formulas 7 to 9.

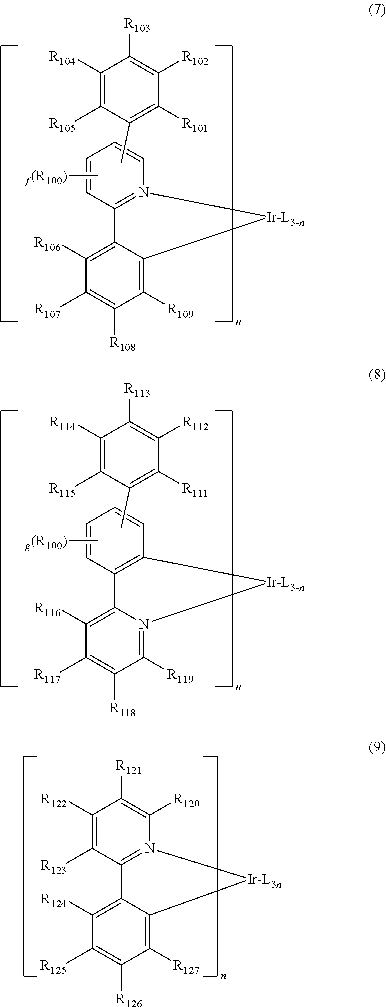

wherein L is selected from the following structures:

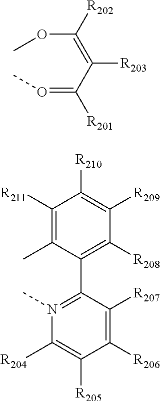

R₁₀₀ represents hydrogen, a substituted or unsubstituted (C1-C30)alkyl group, or a substituted or unsubstituted (C3-C30)cycloalkyl group; R₁₀₁ to R₁₀₉ and R₁₁₁ to R₁₂₃ each independently represent hydrogen, deuterium, a halogen, a (C1-C30)alkyl group unsubstituted or substituted with halogen(s), a substituted or unsubstituted (C3-C30)cycloalkyl group, a cyano group, or a substituted or unsubstituted (C1-C30)alkoxy group; R₁₂₀ to R₁₂₃ are linked to an adjacent substituent to form a fused ring, e.g. quinoline; R₁₂₄ to R₁₂₇ each independently represent hydrogen, deuterium, a halogen, a substituted or unsubstituted (C1-C30)alkyl group, or a substituted or unsubstituted (C6-C30)aryl group; where R₁₂₄ to R₁₂₇ are aryl groups, adjacent substituents may be linked to each other to form a fused ring, e.g. fluorene; R₂₀₁ to R₂₁₁ each independently represent hydrogen, deuterium, a halogen, a (C1-C30)alkyl group unsubstituted or substituted with halogen(s), or a substituted or unsubstituted (C3-C30)cycloalkyl group; f and g each independently represent an integer of 1 to 3; where f or g is an integer of 2 or more, each of R₁₀₀ is the same or different; and n is an integer of 1 to 3.

Specifically, the phosphorescent dopant may be selected from compounds represented by the following compounds:

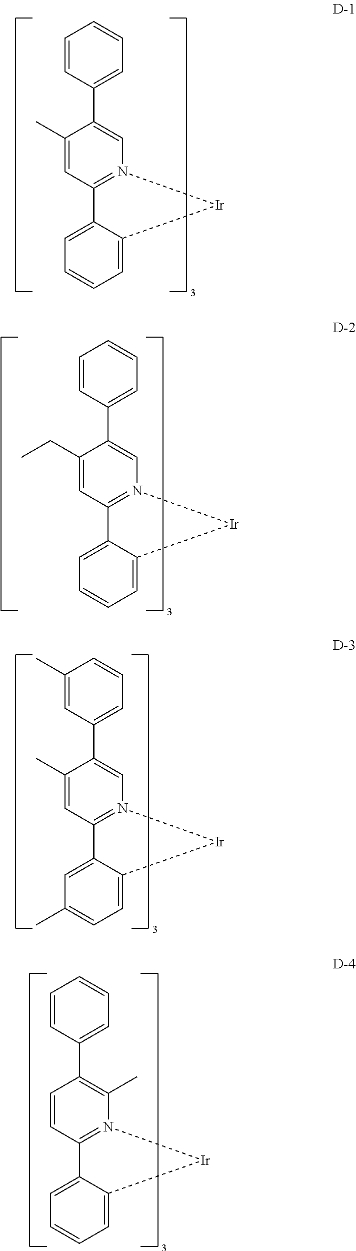

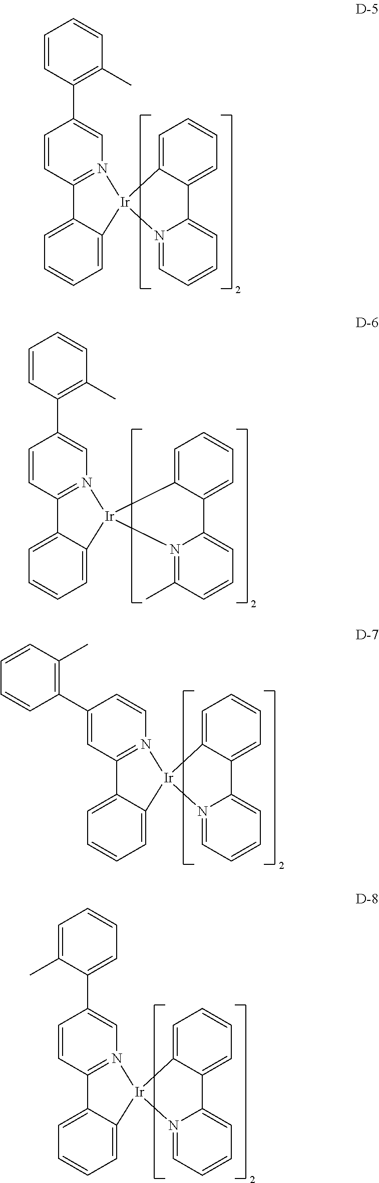

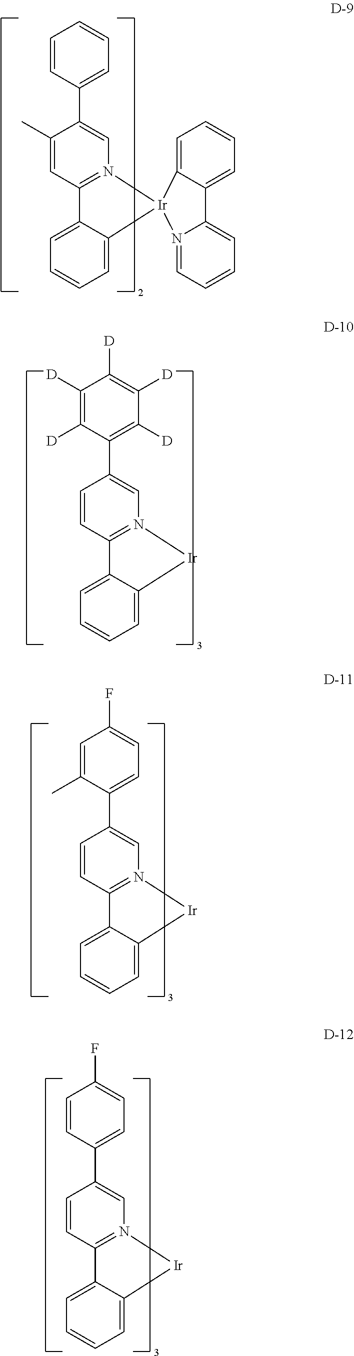

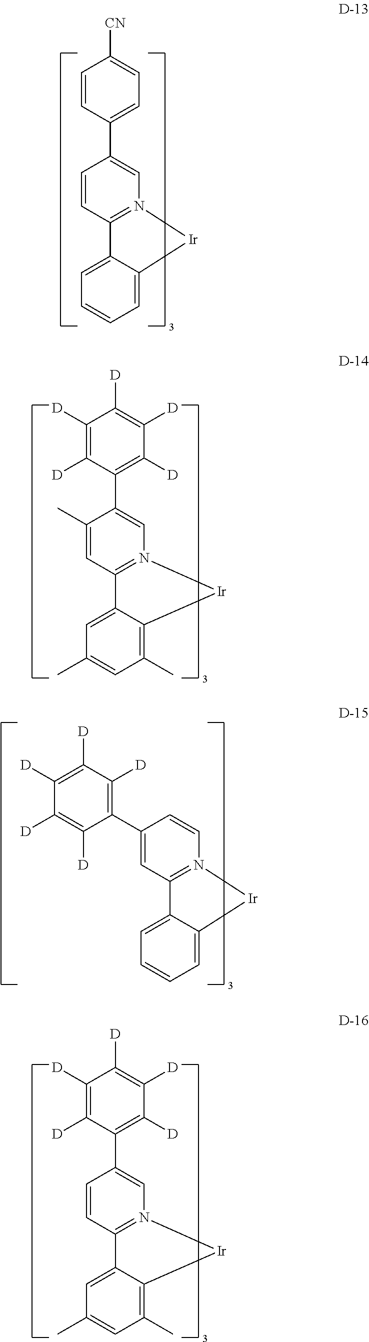

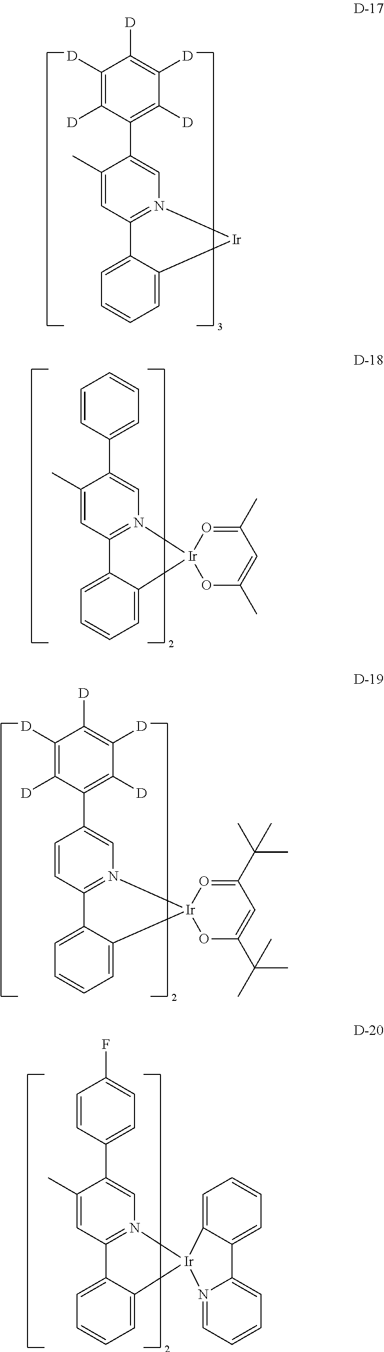

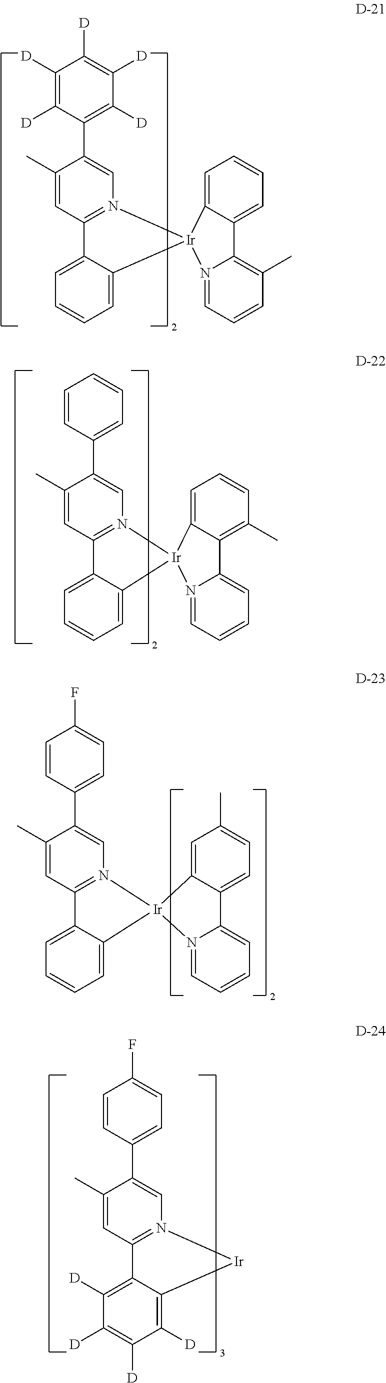

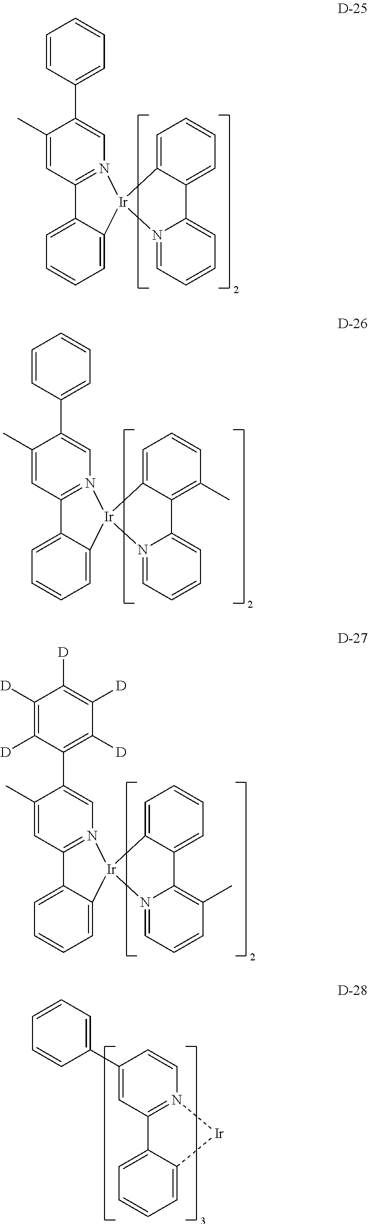

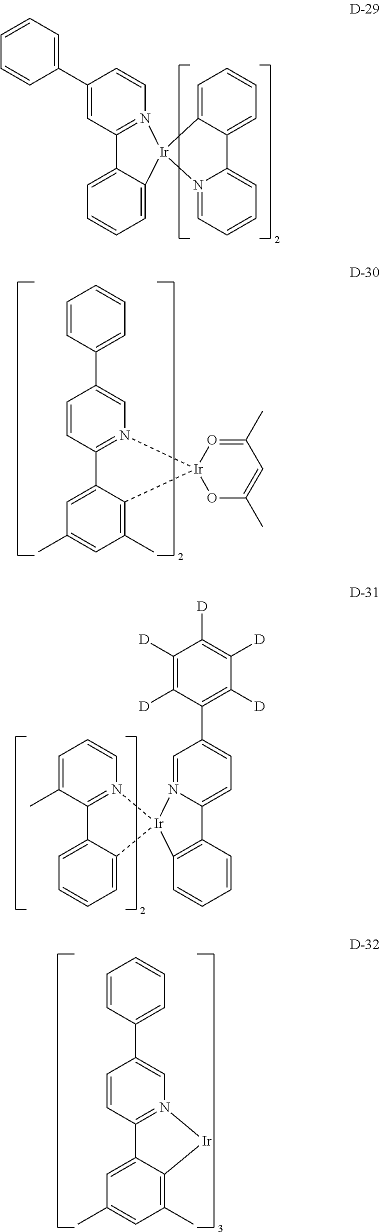

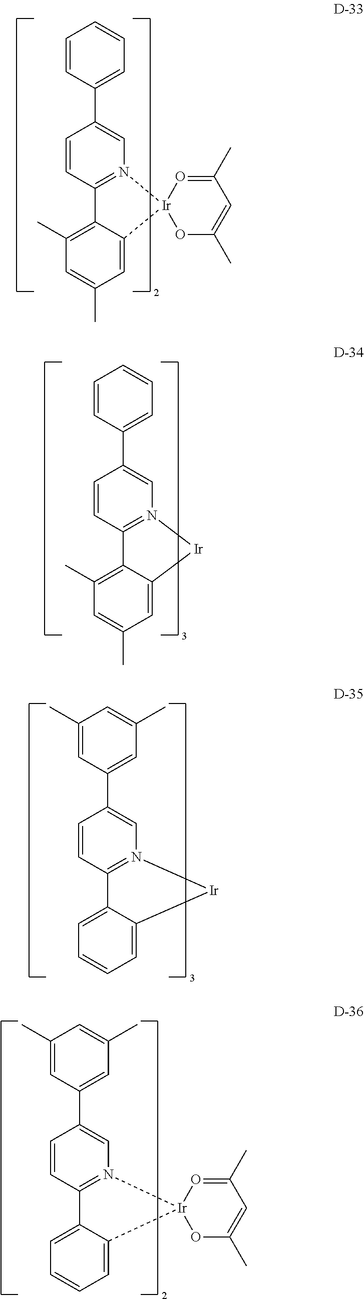

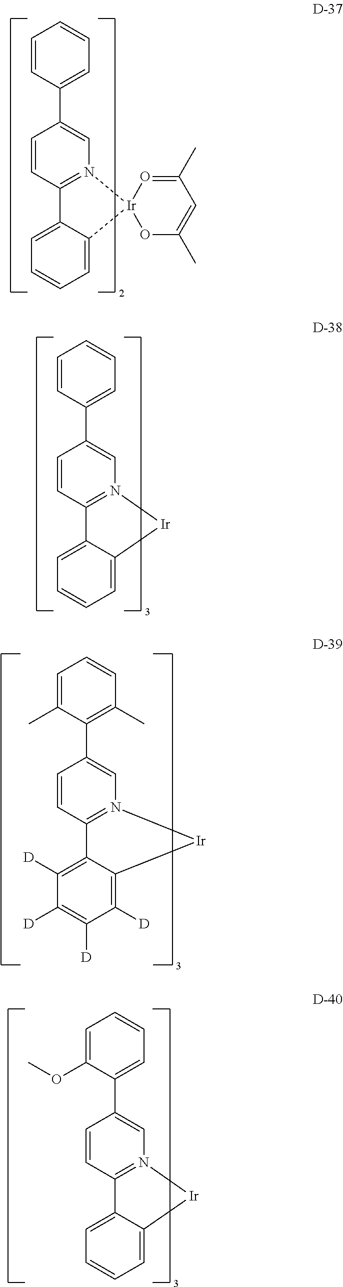

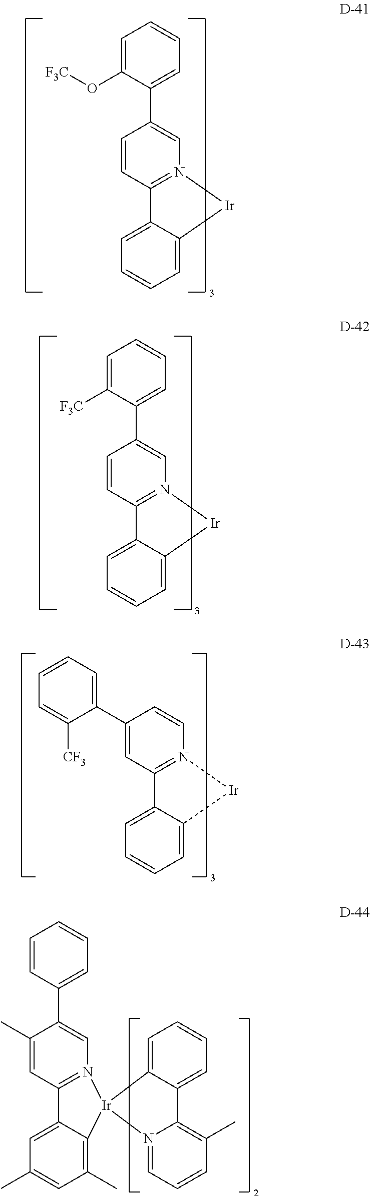

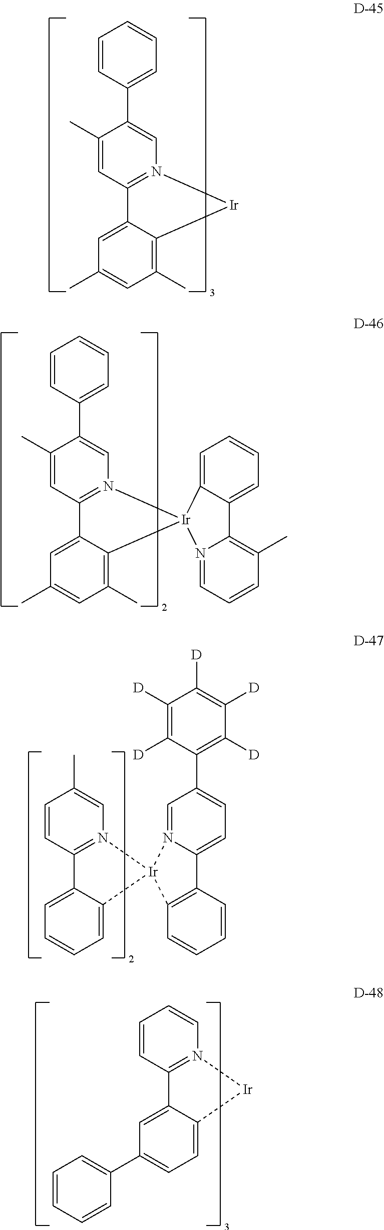

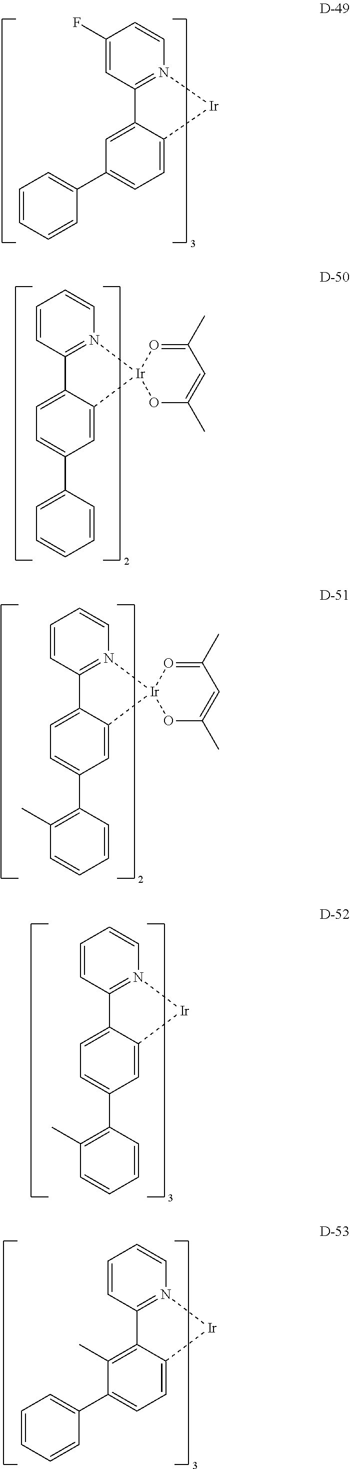

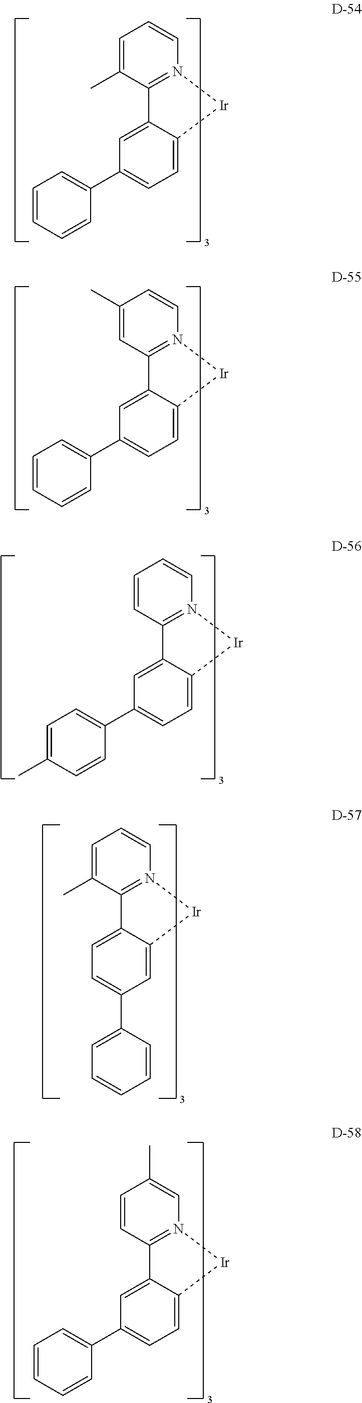

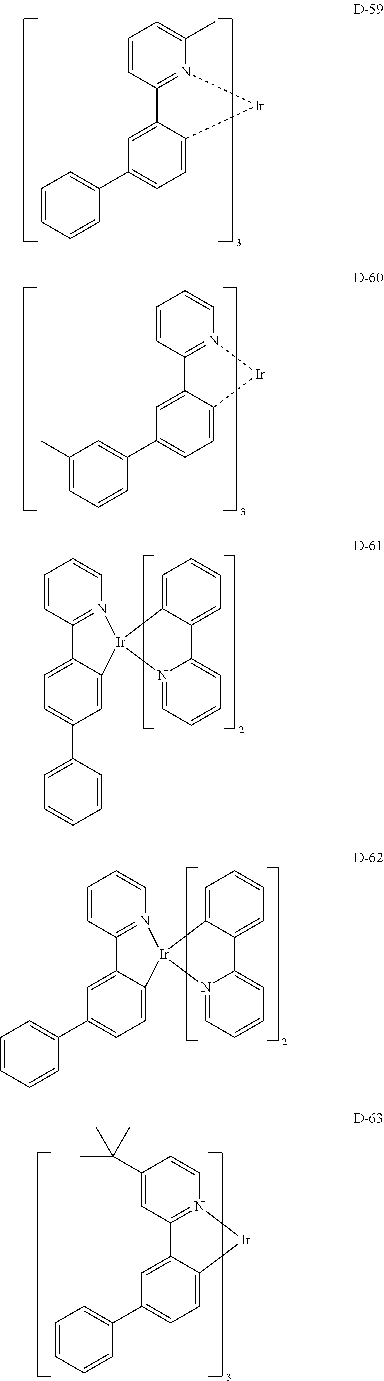

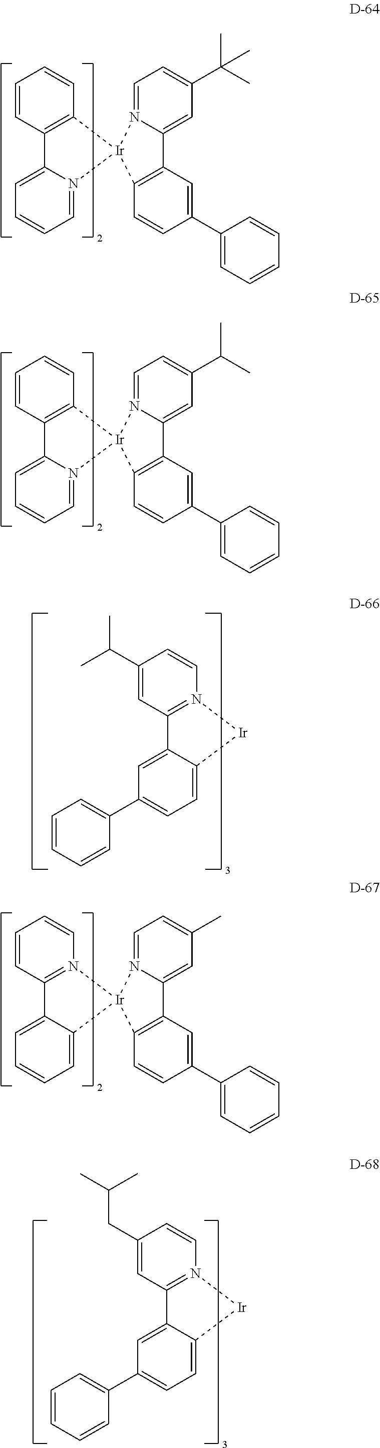

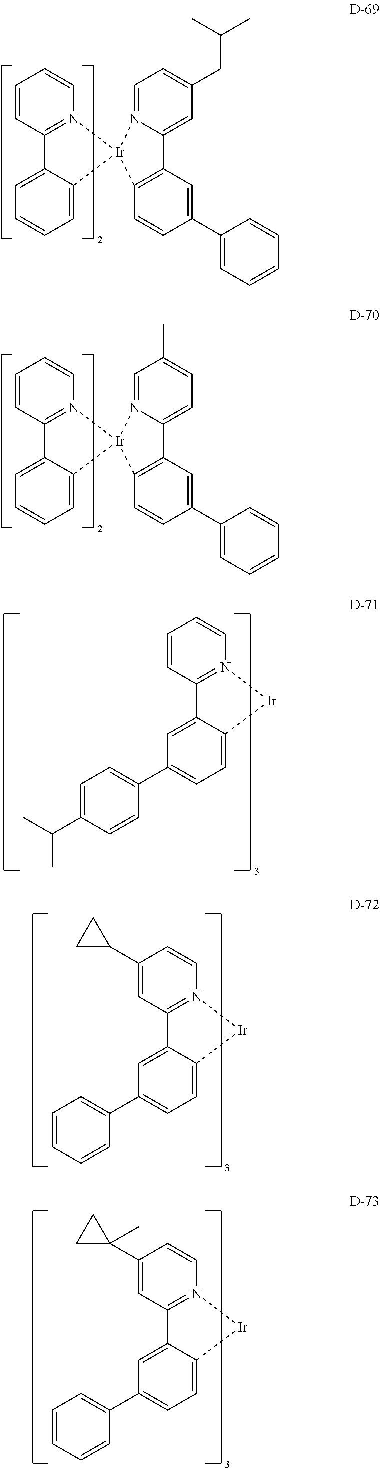

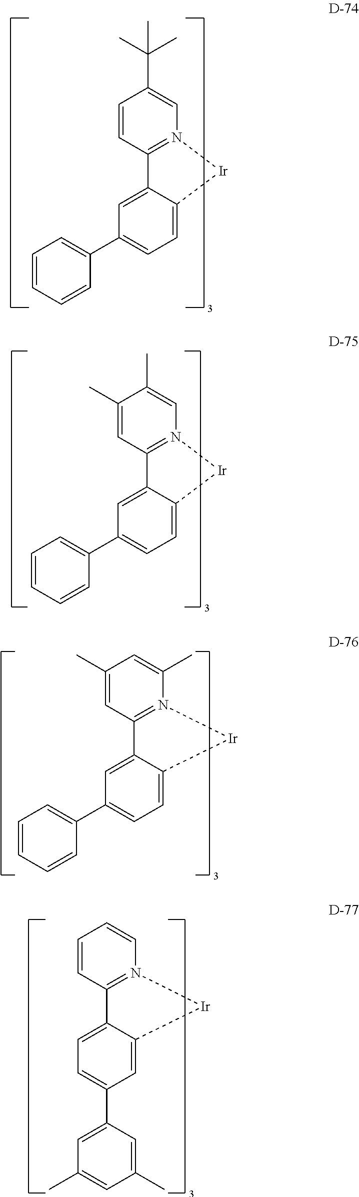

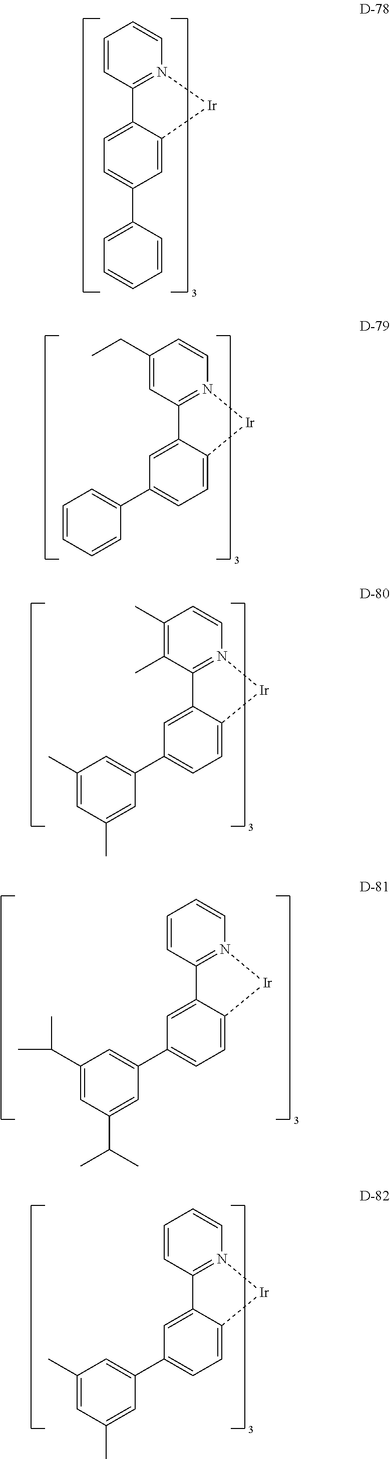

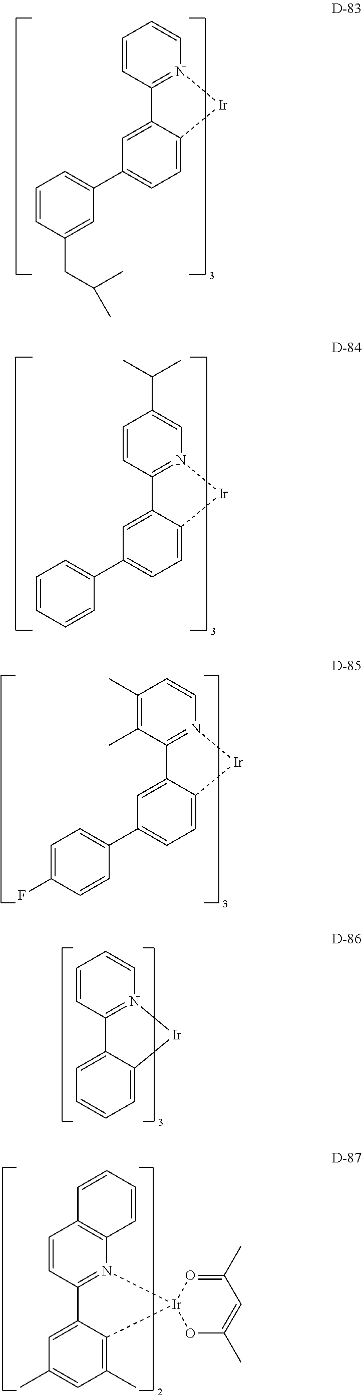

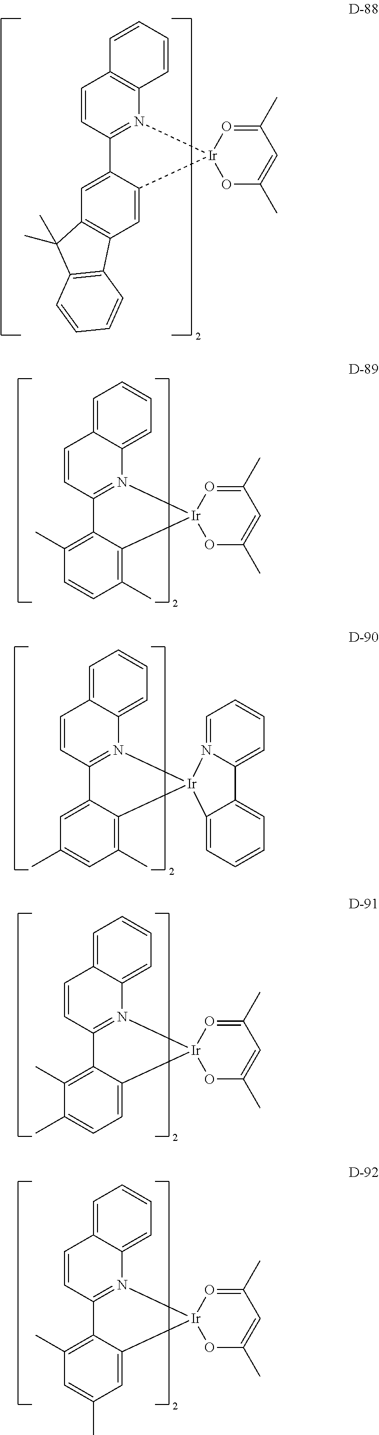

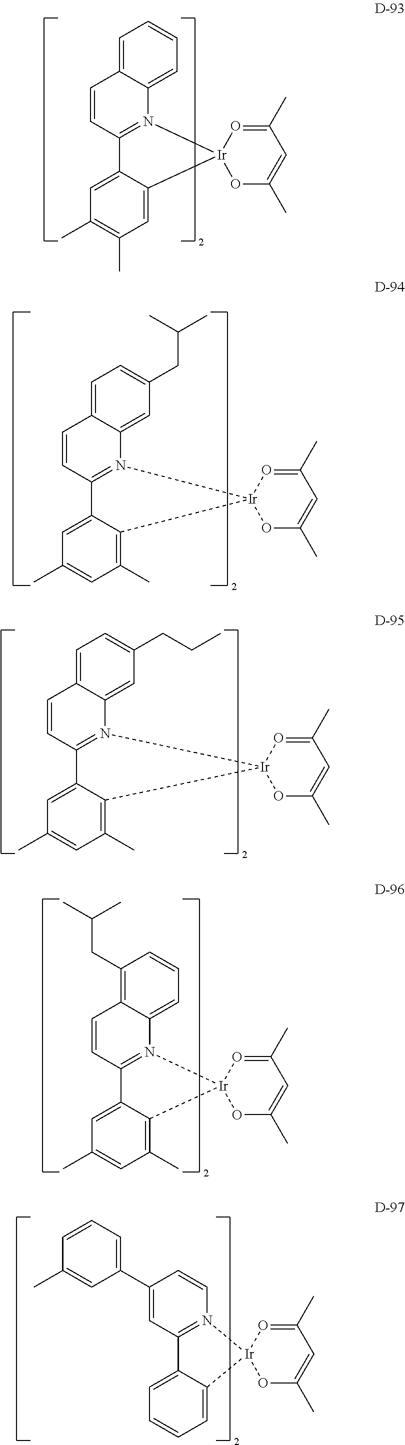

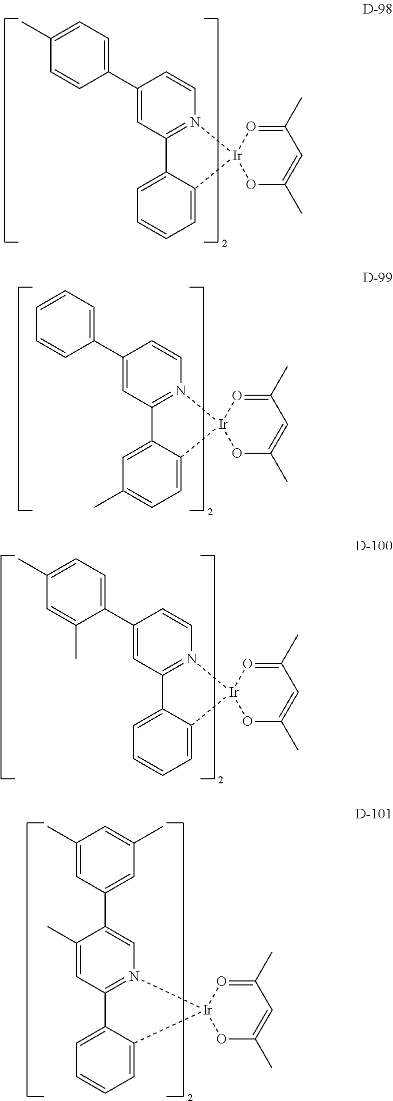

The present invention further provides a material for an organic electroluminescent device. The material comprises a first host material and a second host material, wherein the compound according to the present invention can be comprised as a first host material, wherein the ratio of the organic electroluminescent compound according to the present invention (a first host material) to the second host material can be in the range of 1:99 to 99:1.

Further, the organic electroluminescent device comprises a first electrode, a second electrode, and at least one organic layer between the first and second electrodes. The organic layer comprises a light-emitting layer, wherein the light-emitting layer comprises the material for the organic electroluminescent device according to the present invention and a phosphorescent dopant material, and the material for the organic electroluminescent device according to the present invention is used as a host material.

The organic electroluminescent device according to the present invention may further comprise, in addition to the compounds represented by formula 1, at least one compound selected from the group consisting of arylamine-based compounds and styrylarylamine-based compounds.

In the organic electroluminescent device according to the present invention, the organic layer may further comprise at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising the metal. The organic layer may comprise a light-emitting layer and a charge generating layer.

In addition, the organic electroluminescent device may emit white light by further comprising at least one light-emitting layer which comprises a blue electroluminescent compound, a red electroluminescent compound or a green electroluminescent compound, besides the compound according to the present invention. Additionally, if needed, it further comprises a yellow or orange light-emitting layer.

According to the present invention, at least one layer (hereinafter, “a surface layer”) of the organic electroluminescent device preferably selected from a chalcogenide layer, a metal halide layer and a metal oxide layer; may be placed on an inner surface(s) of one or both electrode(s). Specifically, a chalcogenide (includes oxides) layer of silicon or aluminum is preferably placed on an anode surface of an electroluminescent medium layer, and a metal halide layer or a metal oxide layer is placed on a cathode surface of an electroluminescent medium layer. Such a surface layer provides operation stability for the organic electroluminescent device. Preferably, the chalcogenide includes SiOₓ(1≦X≦2), AlOₓ(1≦X≦1.5), SiON, SiAlON, etc.; the metal halide includes LiF, MgF₂, CaF₂, a rare earth metal fluoride, etc.; and the metal oxide includes Cs₂O, Li₂O, MgO, SrO, BaO, CaO, etc.

Preferably, in the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

As for the formation of the layers of the organic electroluminescent device according to the present invention, dry film-forming methods such as vacuum evaporation, sputtering, plasma and ion plating methods, or wet film-forming methods such as spin coating, dipping and flow coating methods can be used.

When applying a wet film-forming method, a thin film is formed by dissolving or diffusing the material comprising each layer into any suitable solvent such as ethanol, chloroform, tetrahydrofuran, dioxane, etc.

Hereinafter, the organic electroluminescent compound, the preparation method of the compound, and the luminescent properties of the device comprising the compound of the present invention will be explained in detail with reference to the following examples:

### Example 1

### Preparation of Compound C-18

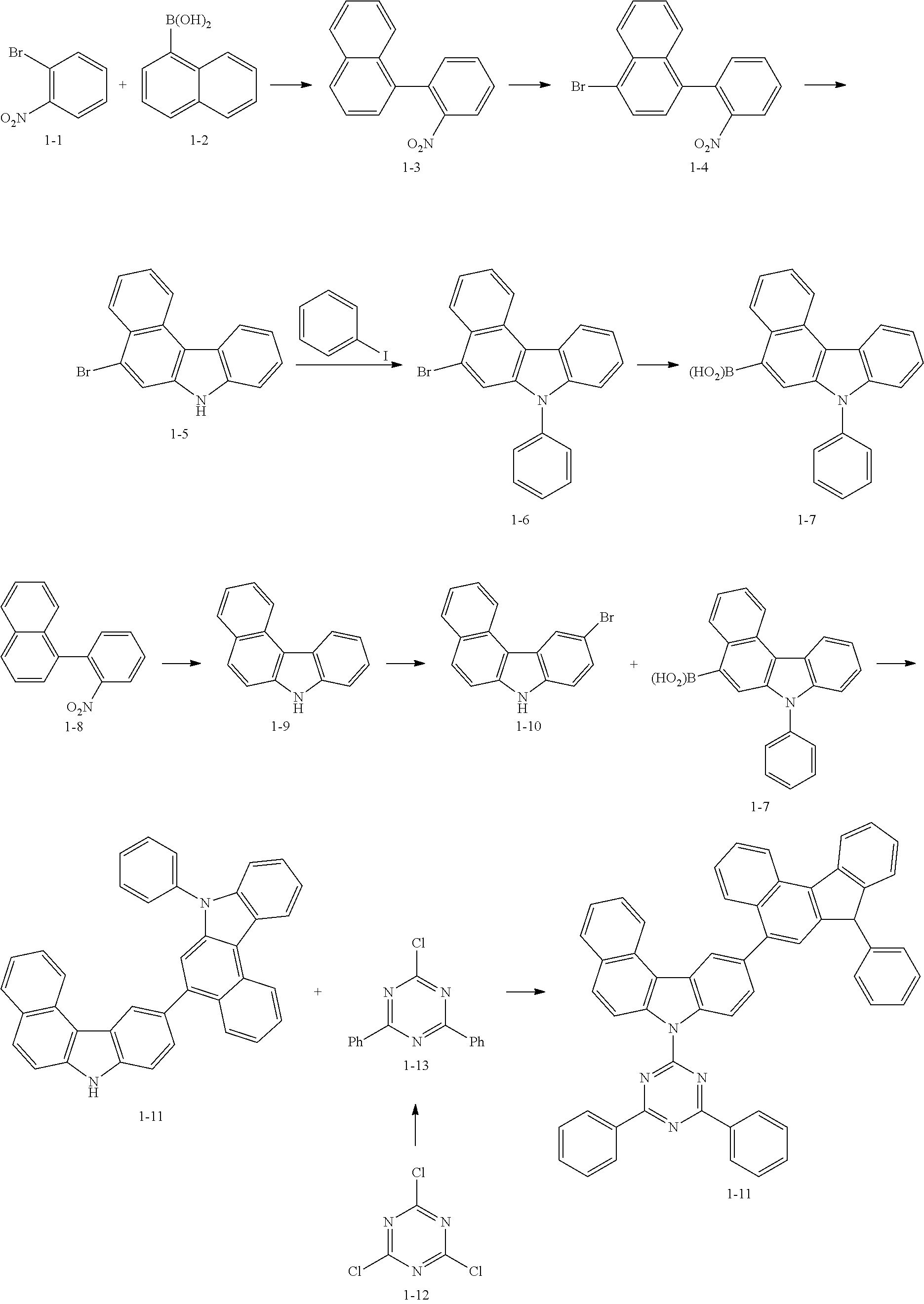

### Preparation of Compound 1-3

After dissolving compound 1-1 (50.7 g, 251 mmol), compound 1-2 (43.2 g, 251 mmol), Pd(PPh₃)₄ (11 g, 10 mmol) and K₂CO₃ (84.2 g, 609 mmol) in toluene (1 L)/EtOH (200 mL)/distilled water(200 mL), the reaction mixture was stirred for 2 hours at 90° C. The organic layer was distillated under reduced pressure, and then triturated with MeOH. The obtained solid was silica-filtered by dissolving in methylene chloride (MC), and then triturated with MC and hexane to obtain compound 1-3 (50 g, 80%).

### Preparation of Compound 1-4

Compound 1-3 (20 g, 80.24 mmol) was dissolved in CC (20 m). After putting Br₂ (4.1 g, 80.24 mmol), the reaction mixture was stirred for a day at room temperature. After terminating the reaction, the reaction mixture was extracted with ethyl acetate (EA), and the obtained organic layer was concentrated. The organic layer was purified by a silica column to obtain compound 1-4 (25.6 g, 9780%)).

### Preparation of Compound 1-5

After dissolving compound 1-4 (25.6 g, 78 mmol) in P(OEt)₃ (200 mL) and 1,2-dichlorobenzene (150 mL), the reaction mixture was stirred for a day at 150° C. After terminating the reaction, the reaction mixture was concentrated under reduced pressure, and extracted with EA. The obtained organic layer was concentrated, and purified by a silica column to obtain compound 1-5 (12 g, 52%).

### Preparation of Compound 1-6

After dissolving compound 1-5 (12 g, 41 mmol), iodobenzene (9.2 mL, 82 mmol), Cul (3.9 g, 20.5 mmol), ethylenediamine (EDA) (1.4 mL, 20.5 mmol) and Cs₂CO₃ (40 g, 123 mmol) in toluene (250 mL), the reaction mixture was stirred under reflux for a day. After extracting with EA, the reaction mixture was distilled under reduced pressure, and was purified by a column chromatography with MC/Hexane to obtain compound 1-6 (14 g, 93%).

### Preparation of Compound 1-7

After dissolving compound 1-6 (14 g, 37.6 mmol) in tetrahydrofuran (THF) (140 mL) and adding 2.5 M n-BuLi (18 mL, 45.1 mmol) in hexane at −78° C., the reaction mixture was stirred for one hour. The reaction mixture was then stirred for 2 hours while slowly adding B(OMe)₃ (13 mL, 56.4 mmol). After quenching by adding 2 M HCl, the reaction mixture was extracted with distilled water and EA. After recrystallizing using MC and hexane, compound 1-7 (6 g, 47%) was obtained.

### Preparation of Compound 1-9

After dissolving compound 1-8 (20 g, 80.2 mmol) in P(OEt)₃ (200 mL) and 1,2-dichlorobenzene (200 mL), the reaction mixture was stirred for one hour at 150° C. After terminating the reaction, the reaction mixture was concentrated under reduced pressure, and extracted with EA. The obtained organic layer was concentrated, and purified by a silica column to obtain compound 1-9 (8.7 g, 50%).

### Preparation of Compound 1-10

After dissolving compound 1-9 (8.7 g, 40.1 mmol) in dimethytformamide (DMF) (50 mL), and adding N-bromosuccinimide (NBS) (4.7 g, 40.1 mmol), the reaction mixture was stirred for a day at room temperature. After terminating the reaction, the reaction mixture was extracted with EA, and the organic layer was concentrated. The resulting product was purified by a silica column to give compound 1-10 (9.5 g, 80%).

### Preparation of Compound 1-11

After dissolving compound 1-7 (6 g, 17.8 mmol), compound 1-10 (4.4 g, 14.9 mmol), K₂CO₃ (6.2 g, 44.7 mmol) and Pd(PPh₃)₄ (860 mg, 0.75 mmol) in toluene (100 mL)/EtOH(20 mL)/purified water (20 mL), the reaction mixture was stirred for 3 hours at 95° C. After terminating the reaction, the reaction mixture was cooled to room temperature, and left standing to remove the water layer. After concentrating, the oil layer was triturated with MC and filtered to obtain compound 1-11 (7 g, 92%).

### Preparation of Compound 1-13

After dissolving compound 1-12 (36 g, 195 mmol) in THF (360 mL), the reaction mixture was cooled to 0° C., and PhMgBr (160 mL) was added slowly. While increasing the temperature to room temperature, the reaction mixture was stirred for 2 hours. After terminating the reaction by adding distilled water, the organic layer was extracted with EA, dried using magnesium sulfate, and recrystallized with MC/MeOH to obtain compound 1-13 (12 g, 72%).

### Preparation of Compound C-18

After suspending compound 1-11 (800 mg, 1.6 mmol) and compound 1-13 (508 mg, 1.9 mmol) in DMF (1 mL), 60% NaH (83 g, 2 mmol) was added at room temperature. The reaction mixture was stirred for 12 hours. After adding purified water, the reaction mixture was filtered under reduced pressure. The obtained solid was triturated with MeOH/EA, dissolved in MC, silica-filtered, and triturated with MC/n-hexane to obtain compound C-18 (1 g, 83.3%).

MS/FAB found 739.86. calculated 739.27

### Example 2

### Preparation of Compound C-16

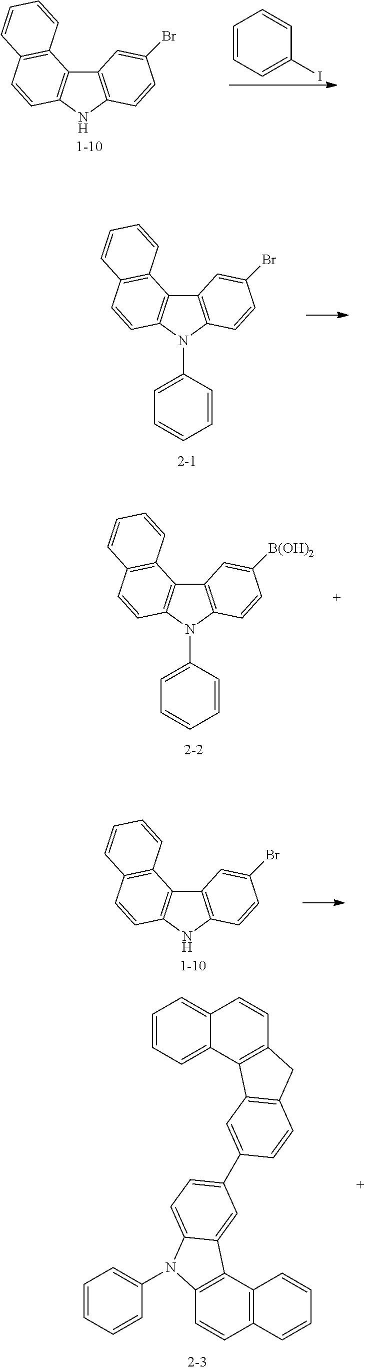 [SMILES: Brc1ccc2[nH]c3ccc4ccccc4c3c2c1 ; Ic1ccccc1 ; Brc1ccc2c(c1)c1c3ccccc3ccc1n2-c1ccccc1 ; OB(O)c1ccc2c(c1)c1c3ccccc3ccc1n2-c1ccccc1 ; Brc1ccc2[nH]c3ccc4ccccc4c3c2c1 ; c1ccc(-n2c3ccc(-c4ccc5c(c4)-c4c(ccc6ccccc46)C5)cc3c3c4ccccc4ccc32)cc1]

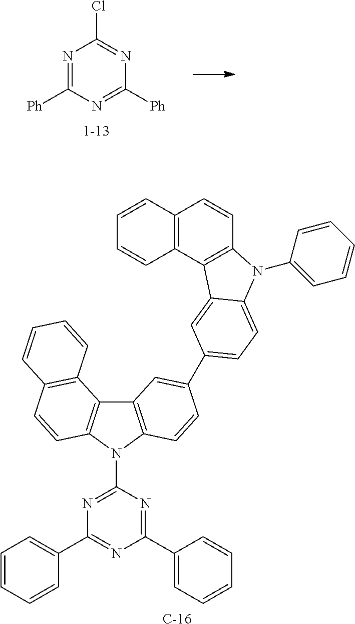

### Preparation of Compound 2-1

Using compound 1-10 (7.5 g, 25.3 mmol) and iodobenzene (7.5 mL, 51 mmol), compound 2-1 (7.9 g, 84%) was obtained in the same manner as compound 1-6 of Example 1.

### Preparation of Compound 2-2

Using compound 2-1 (7.5 g, 79 mmol) and B(Oi-Pr)₃ (6.8 mL, 119 mmol), compound 2-2 (5 g, 75%) was obtained in the same manner as compound 1-7 of Example 1.

### Preparation of Compound 2-3

Using compound 2-1 (8 g, 27 mmol) and compound 2-2 (10.9 g, 32.4 mmol), compound 2-3 (11.5 g, 87%) was obtained in the same manner as compound 1-11 of Example 1.

### Preparation of Compound C-16

Using compound 2-3 (2.9 g, 5.7 mmol) and compound 1-13 (1.7 g, 6.3 mmol), compound C-16 (11.5 g, 87%) was obtained in the same manner as compound C-18 of Example 1.

MS/FAB found 739.86. calculated 739.27

### Example 3

### Preparation of Compound C-4

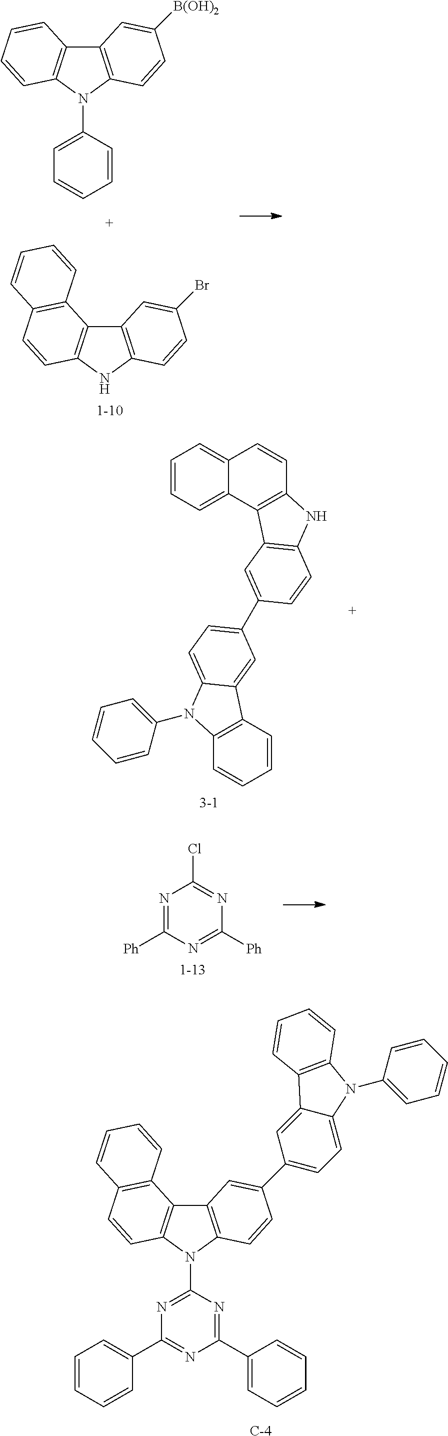

### Preparation of Compound 3-1

Using 9-phenylcarbazolyl-3-boronic acid (9.3 g, 32.4 mmol) and compound 1-10 (4.3 g, 27 mmol), compound 3-1 (9.7 g, 78%) was obtained in the same manner as compound 1-11 of Example 1.

### Preparation of Compound C-4

Using compound 3-1 (2.3 g, 5 mmol) and compound 1-13 (1.5 g, 5.5 mmol), compound C-4 (2.5 g, 72%) was obtained in the same manner as compound C-18 of Example 1.

MS/FAB found 689.80. calculated 689.26

### Device Example 1

### Production of an OLED Device Using the Compound According to the Present Invention

An OLED device was produced using the compound according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N¹,N^{1′}-([1,1′-biphenyl]-4,4′-diyl)bis(N¹-(naphthalen-1-yl)-N⁴,N⁴-diphenylbenzene-1,4-diamine) was introduced into a cell of the vacuum vapor depositing apparatus, and then the pressure in the chamber of the apparatus was controlled to 10⁻⁶ torr. Thereafter, an electric current was applied to the cell to evaporate the above introduced material, thereby forming a hole injection layer having a thickness of 60 nm on the ITO substrate. Then, N,N′-di(4-biphenyl)-N,N′-di(4-biphenyl)-4,4′-diaminobiphenyl was introduced into another cell of the vacuum vapor depositing apparatus, and was evaporated by applying a electric current to the cell, thereby forming a hole transport layer having a thickness of 20 nm on the hole injection layer. Thereafter, compound C-18 was introduced into one cell of the vacuum vapor depositing apparatus, as a host material, and compound D-88 was introduced into another cell as a dopant. The two materials were evaporated at different rates and deposited in a doping amount of 4 wt % based on the total amount of the host and dopant to form a light-emitting layer having a thickness of 30 nm on the hole transport layer. Then, 2-(4-(9,10-di(naphthalen-2-yl)anthracen-2-yl)phenyl)-1-phenyl-1H-benzo[d]imidazole was introduced into one cell and lithium quinolate was introduced into another cell. The two materials were evaporated at the same rate and deposited in a doping amount of 50 wt % to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the material used for producing the OLED device were purified by vacuum sublimation at 10⁻⁶ torr prior to use.

The produced OLED device showed a red emission having a luminance of 1,040 cd/m² and a current density of 15.7 mA/cm² at a driving voltage of 3.5 V. Further, it took a minimum of 35 hours to reduce luminance by 90% at a luminance of 5,000 nit.

### Device Example 2

### Production of an OLED Device Using the Compound According to the Present Invention

An OLED device was produced in the same manner as that of Device Example 1, except that compound C-4 was used in a host and compound D-87 was used in a dopant as the light-emitting material.

As a result, the produced OLED device showed a red emission having a luminance of 1,020 cd/m² and a current density of 7.8 mA/cm² at a driving voltage of 3.8 V. Further, it took a minimum of 40 hours to reduce luminance by 90% at a luminance of 5,000 nit.

### Device Example 3

### Production of an OLED Device Using the Compound According to the Present Invention

An OLED device was produced in the same manner as that of Device Example 1, except that compound C-16 was used in a host and compound D-88 was used in a dopant as the light-emitting material.

As a result, the produced OLED device showed a red emission having a luminance of 1,010 cd/m² and a current density of 12.5 mA/cm² at a driving voltage of 4.0 V. Further, it took a minimum of 40 hours to reduce luminance by 90% at a luminance of 5,000 nit.

### Comparative Example 1

### Production of an OLED Device Using Conventional Electroluminescent Compounds

An OLED device was produced in the same manner as that of Device Example 1, except that as a light-emitting material 4,4′-N,N′-dicarbazol-biphenyl was used as a host material and compound D-88 was used as a dopant; a light-emitting layer having a thickness of 30 nm was deposited on a hole transport layer; and a hole blocking layer having a thickness of 10 nm was deposited by using aluminum(III) bis(2-methyl-8-quinolinato)4-phenylphenolate.

As a result, the produced OLED device showed a red emission having a luminance of 1,000 cd/m² and a current density of 20.0 mA/cm² at a driving voltage of 8.2 V. Further, it took a minimum of 10 hours to reduce luminance by 90% at a luminance of 5,000 nit.

The present invention makes it possible to manufacture a device free from crystallization since the compounds used in the organic electronic material are highly efficient in transporting electrons. Further, the organic electroluminescent compound according to the present invention has good layer formability and an advantage of manufacturing an OLED device having long operating lifespan due to its excellent lifespan characteristics, lower driving voltages, high luminous efficiency, and reduced power consumption induced by improved power efficiency.

1. An organic electroluminescent compound represented by the following formula 1: 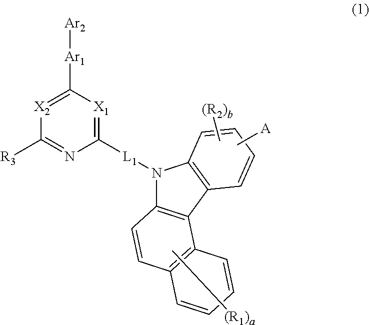
wherein
A represents 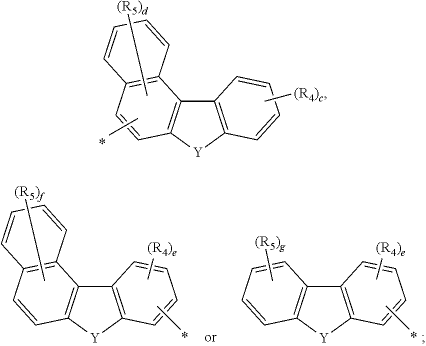
L₁ represents a single bond, a substituted or unsubstituted 3- to 30-membered heteroarylene group, a substituted or unsubstituted (C6-C30)arylene group, or a substituted or unsubstituted (C3-C30)cycloalkylene group;
X₁ and X₂ each independently represent CR₆ or N;
Y represents —O—, —S—, —CR₁₁R₁₂—, —SiR₁₁R₁₂—, or —NR₁₃—;
Ar₁ represents a single bond, a substituted or unsubstituted 3- to 30-membered heteroarylene group, a substituted or unsubstituted (C6-C30)arylene group, or a substituted or unsubstituted (C1-C30)alkylene group;
Ar₂ represents hydrogen, deuterium, a substituted or unsubstituted (C1-C30)alkyl group, a substituted or unsubstituted (C6-C30)aryl group, or a substituted or unsubstituted 3- to 30-membered heteroaryl group;
R₁ to R₆ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, a substituted or unsubstituted (C6-C30)aryl(C1-C30)alkyl group, a substituted or unsubstituted (C6-C30)aryl group fused with at least one substituted or unsubstituted (C3-C30)cycloalkyl, a substituted or unsubstituted 5- to 7-membered heterocycloalkyl group fused with at least one substituted or unsubstituted aromatic ring, a substituted or unsubstituted (C3-C30)cycloalkyl group fused with at least one substituted or unsubstituted aromatic ring, —NR₁₄R₁₅, —SiR₁₆R₁₇R₁₈, —SR₁₉, —OR₂₀, a (C2-C30)alkenyl group, a (C2-C30)alkynyl group, a cyano group or a nitro group;
R₁₁ to R₁₃ each independently represent a substituted or unsubstituted (C1-C30)alkyl group, a substituted or unsubstituted (C6-C30)aryl group, or a substituted or unsubstituted 3- to 30-membered heteroaryl group;
R₁₄ to R₂₀ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; or are linked to an adjacent substituent(s) to form a 3- to 30-membered mono- or polycyclic, alicyclic or aromatic ring whose carbon atom(s) may be replaced with at least one hetero atom selected from nitrogen, oxygen and sulfur;
a and f each independently represent an integer of 1 to 6; where a or f is an integer of 2 or more, each of R₁, or each of R₅ is the same or different;
b and e each independently represent an integer of 1 to 3; where b or e is an integer of 2 or more, each of R₂, or each of R₄ is the same or different;
c and g each independently represent an integer of 1 to 4; where c or g is an integer of 2 or more, each of R₄, or each of R₅ is the same or different;
d represents an integer of 1 to 5; where d is an integer of 2 or more, each of R₅ is the same or different; and
the heterocycloalkyl group and the heteroaryl(ene) group contain at least one hetero atom selected from B, N, O, S, P(═O), Si and P.

2. The organic eletroluinescence compound according to claim 1, wherein the substituents of the substituted groups in L₁, Ar₁, Ar₂, R₁ to R₆ and R₁₁ to R₂₀ groups each independently are at least one selected from the group consisting of deuterium; a halogen; a (C1-C30)alkyl group substituted or unsubstituted with a halogen; a (C6-C30)aryl group; a 3- to 30-membered heteroaryl group substituted or unsubstituted with a (C6-C30)aryl; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; an N-carbazolyl group; a di(C1-C30)alkylamino group; a di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group.

3. The organic electroluminescent compound according to claim 1, wherein
L₁ represents a single bond, a 3- to 30-membered heteroarylene group or a (C6-C30)arylene group;
X₁ and X₂ each independently represent CR₆ or N;
Y represents —O—, —S—, —CR₁₁R₁₂—, —SiR₁₁R₁₂—, or —NR₁₃—;
Ar₁ represents a single bond or a (C6-C30)arylene group;
Ar₂ represents hydrogen, deuterium, a substituted or unsubstituted (C1-C30)alkyl group, a substituted or unsubstituted (C6-C30)aryl group, or a substituted or unsubstituted 3- to 30-membered heteroaryl group, 1,2-dihydroacenaphtyl group, a substituted or unsubstituted N-carbazolyl group, a substituted or unsubstituted N-benzocarbazolyl group, or a substituted or unsubstituted N-dibenzocarbazolyl group;
R₁ to R₆ each independently represent hydrogen, deuterium, a halogen, a (C1-C30)alkyl group, a (C6-C30)aryl group, a 3- to 30-membered heteroaryl group, or an N-carbazolyl group;
R₁₁ to R₁₃ each independently represent a (C1-C30)alkyl group, a (C6-C30)aryl group, or a 3- to 30-membered heteroaryl group; and
the heteroarylene and arylene groups in L₁, the arylene group in Ar₁, the alkyl, aryl, heteroaryl, N-carbazolyl, N-benzocarbazolyl and N-dibenzocarbazolyl groups in Ar₂, the alkyl, aryl, heteroaryl and N-carbazolyl groups in R₁ to R₆, and the alkyl, aryl and heteroaryl groups in R₁₁ to R₁₃ each independently can be substituted with at least one selected from the group consisting of deuterium; a halogen; a (C1-C30)alkyl group substituted or unsubstituted with a halogen; a (C6-C30)aryl group; a 3- to 30-membered heteroaryl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a cyano group; an N-carbazolyl group; a (C6-C30)aryl(C1-C30)alkyl group; a (C1-C30)alkyl(C6-C30)aryl group; a carboxyl group; a nitro group; and a hydroxyl group.

4. The organic electroluminescent compound according to claim 1, wherein
the moiety, Ar₂—Ar₁—* in formula 1 is selected from the following structures:

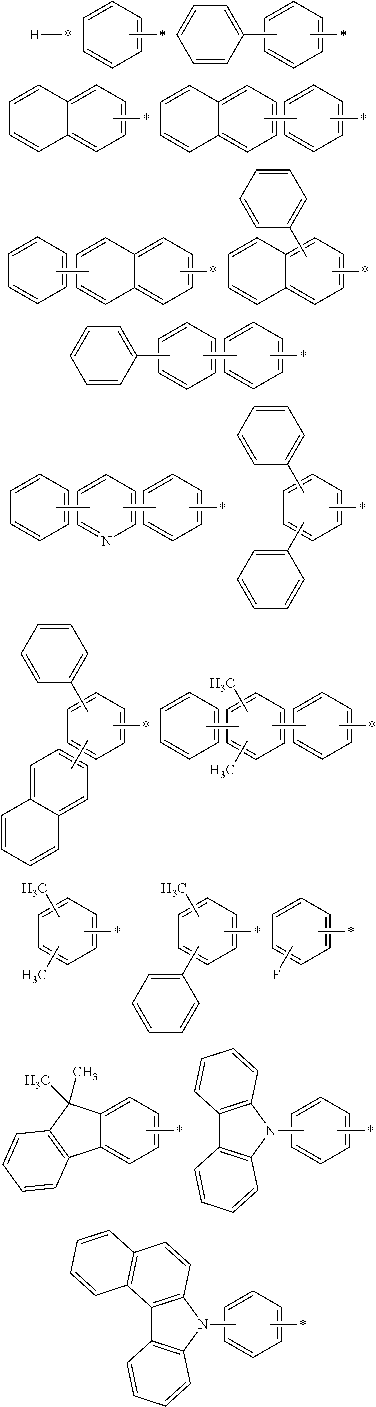

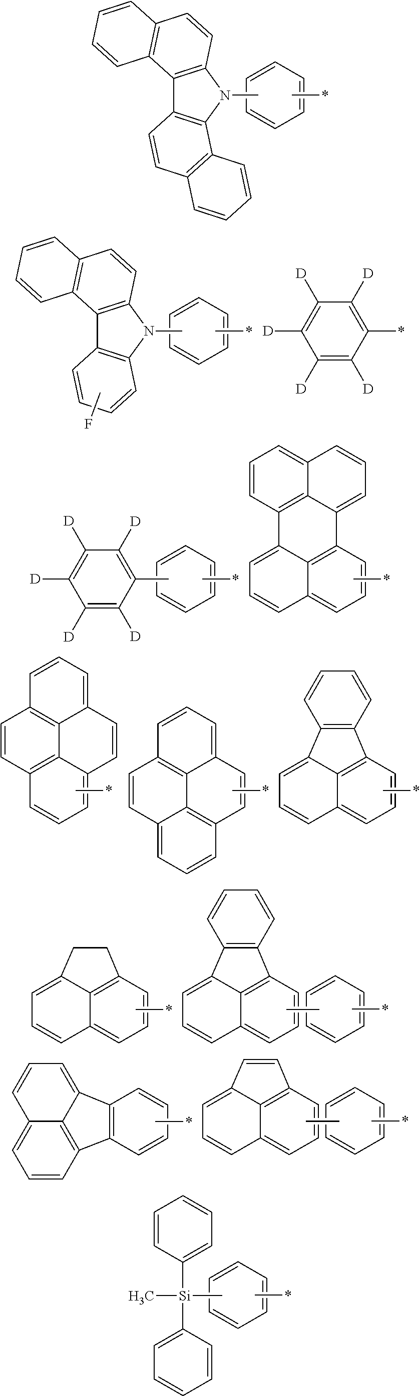

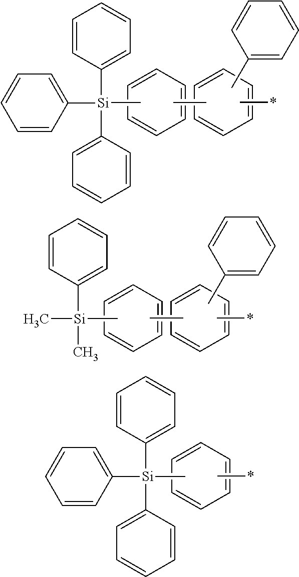

5. The organic electroluminescent compound according to claim 1, wherein the compound represented by formula 1 is selected from the group consisting of:

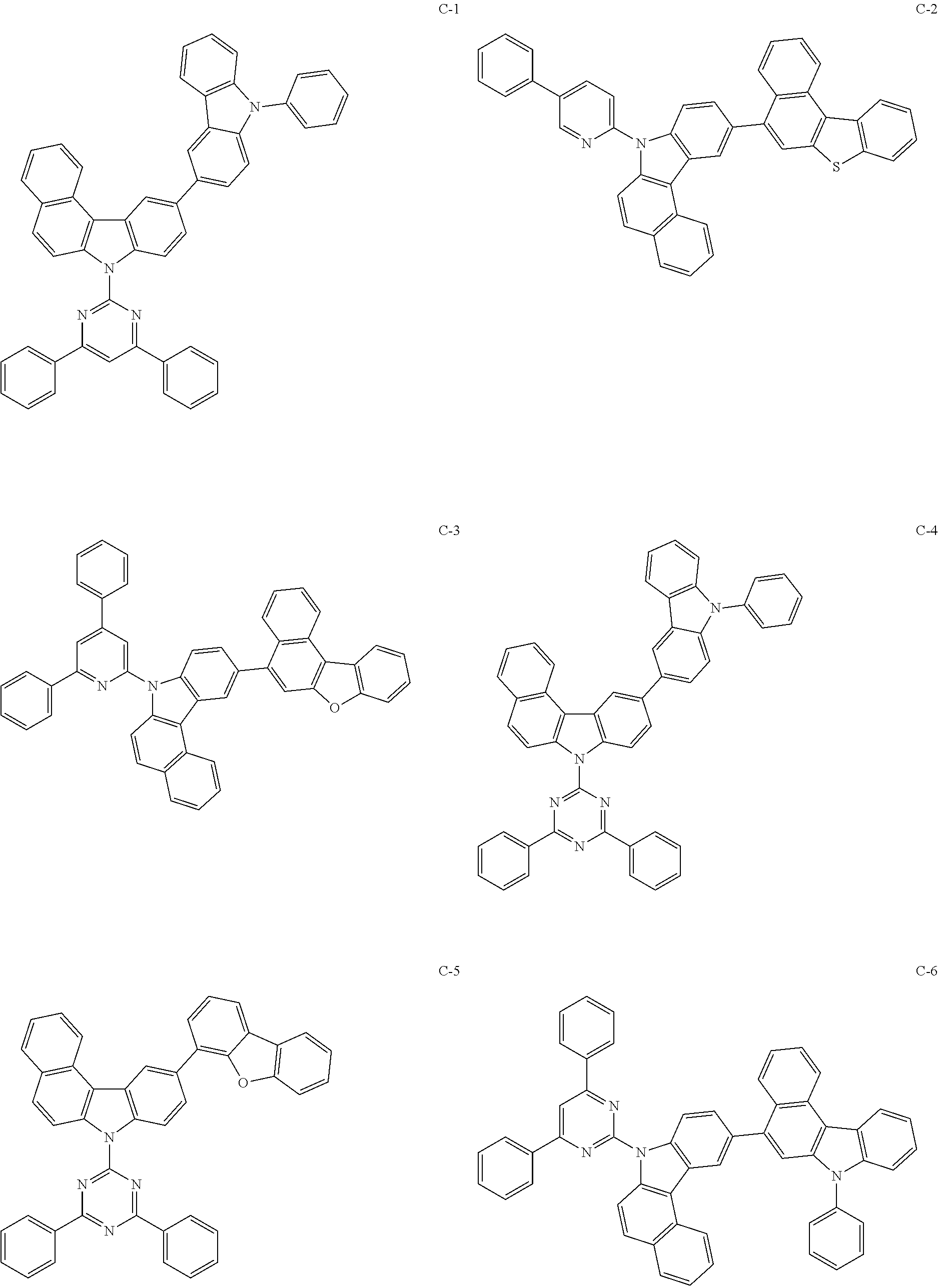

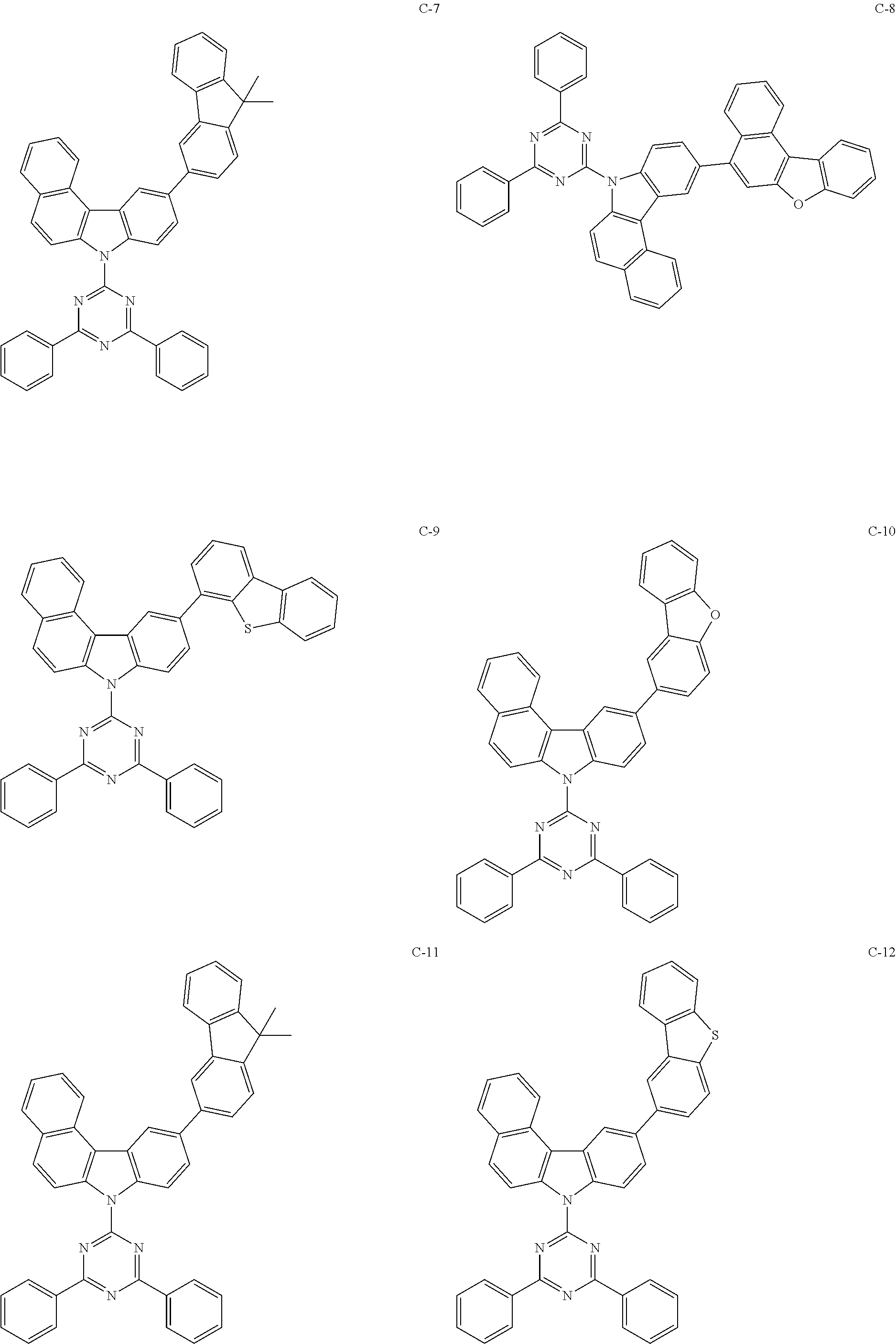

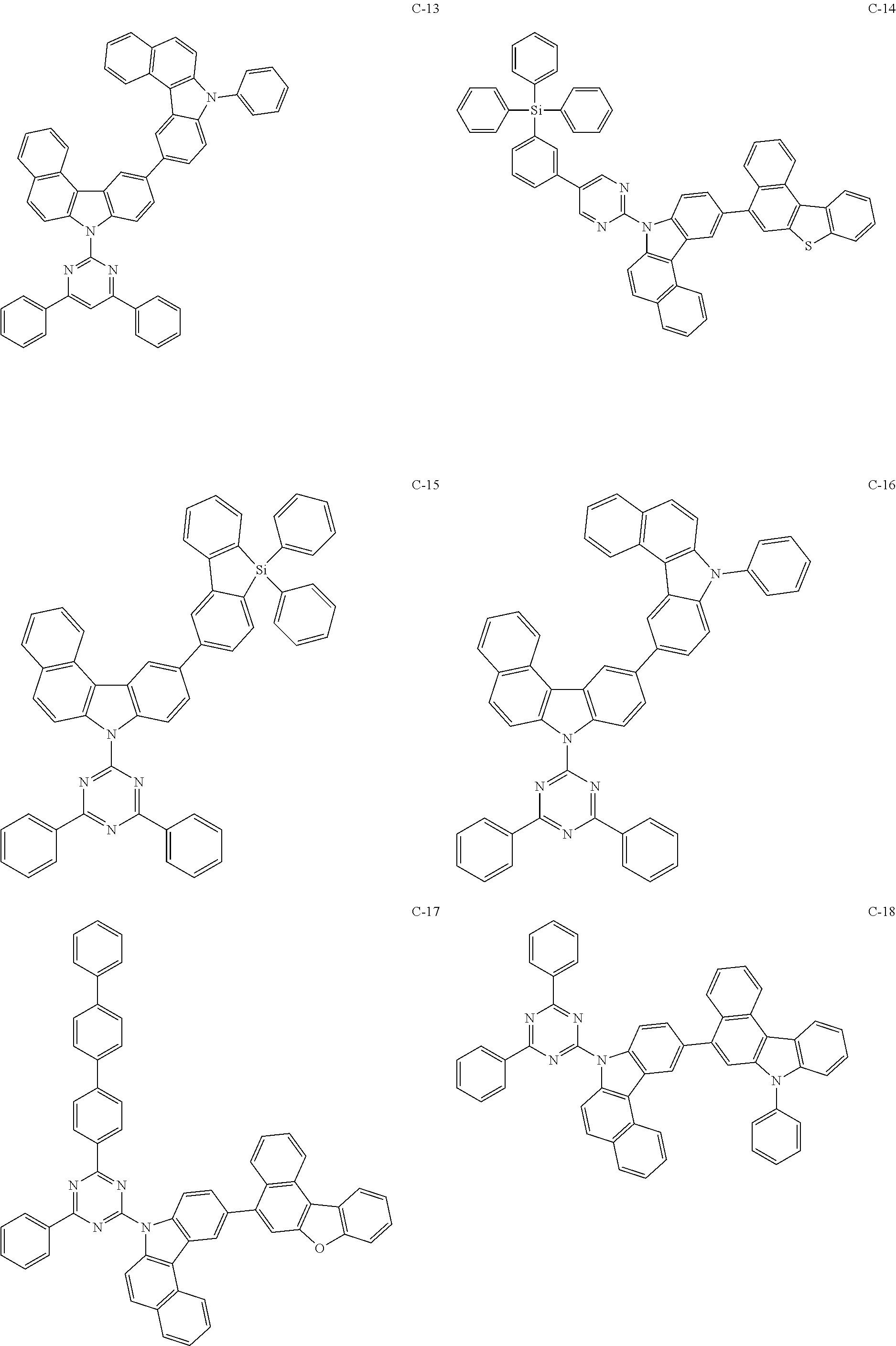

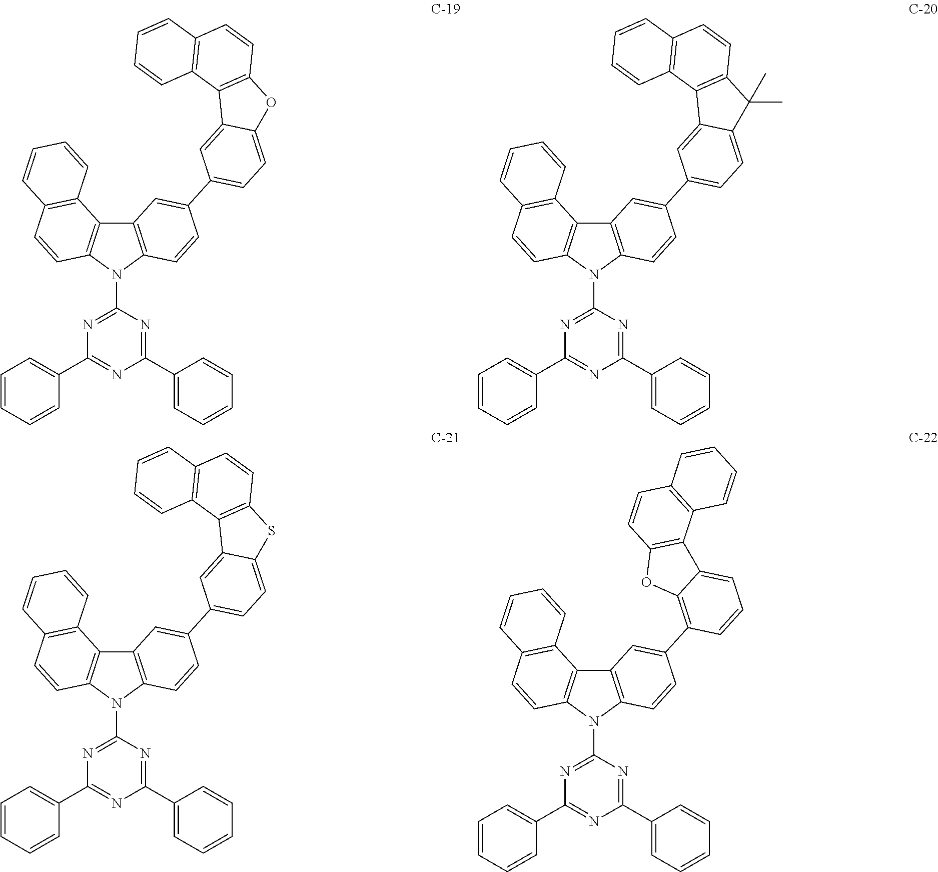

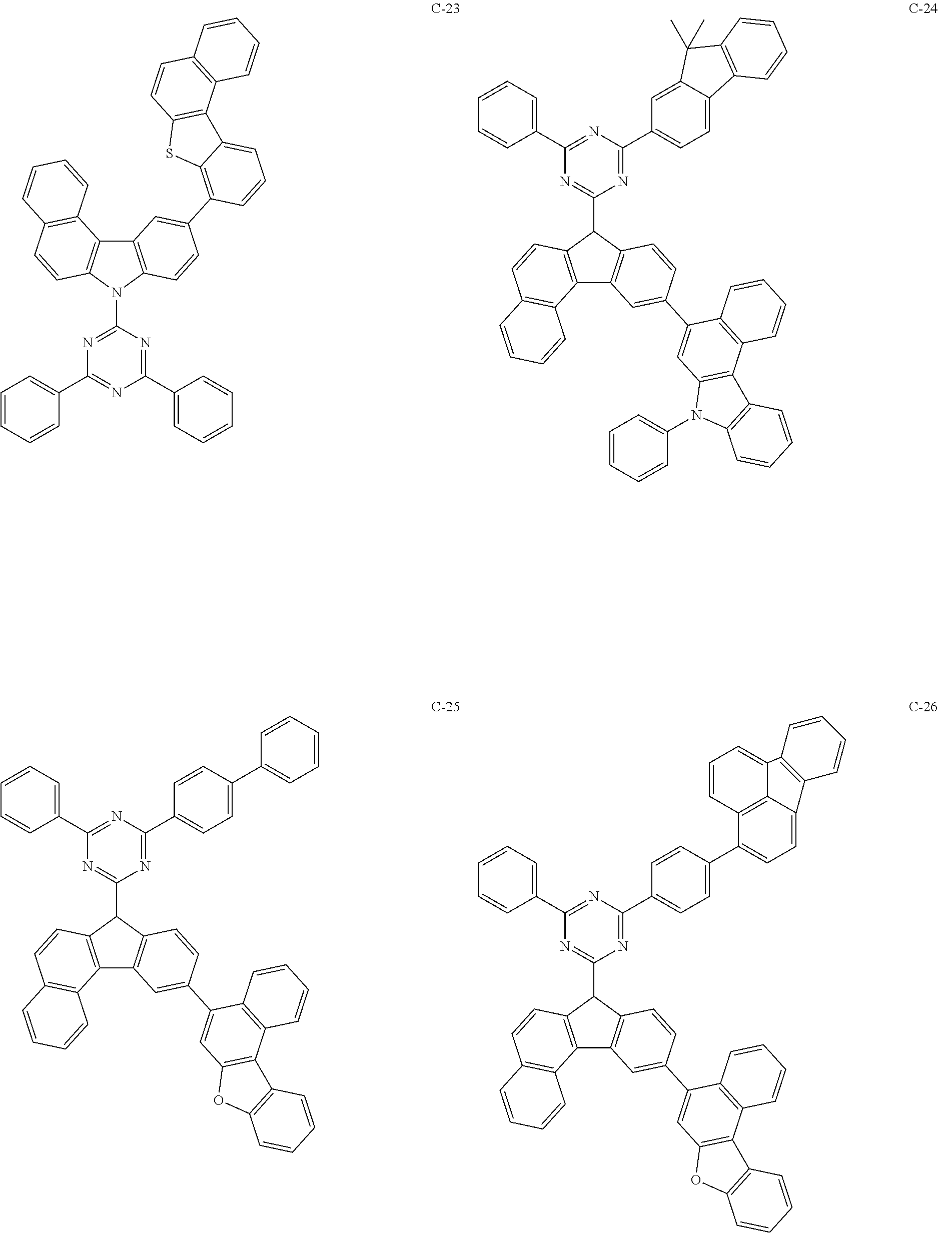 [SMILES: c1ccc(-c2nc(-c3ccccc3)nc(-n3c4ccc(-c5cccc6c5sc5ccc7ccccc7c56)cc4c4c5ccccc5ccc43)n2)cc1 ; CC1(C)c2ccccc2-c2ccc(-c3nc(-c4ccccc4)nc(C4c5ccc(-c6cc7c(c8ccccc68)c6ccccc6n7-c6ccccc6)cc5-c5c4ccc4ccccc54)n3)cc21 ; c1ccc(-c2ccc(-c3nc(-c4ccccc4)nc(C4c5ccc(-c6cc7oc8ccccc8c7c7ccccc67)cc5-c5c4ccc4ccccc54)n3)cc2)cc1 ; c1ccc(-c2nc(-c3ccc(-c4ccc5c6c(cccc46)-c4ccccc4-5)cc3)nc(C3c4ccc(-c5cc6oc7ccccc7c6c6ccccc56)cc4-c4c3ccc3ccccc43)n2)cc1]

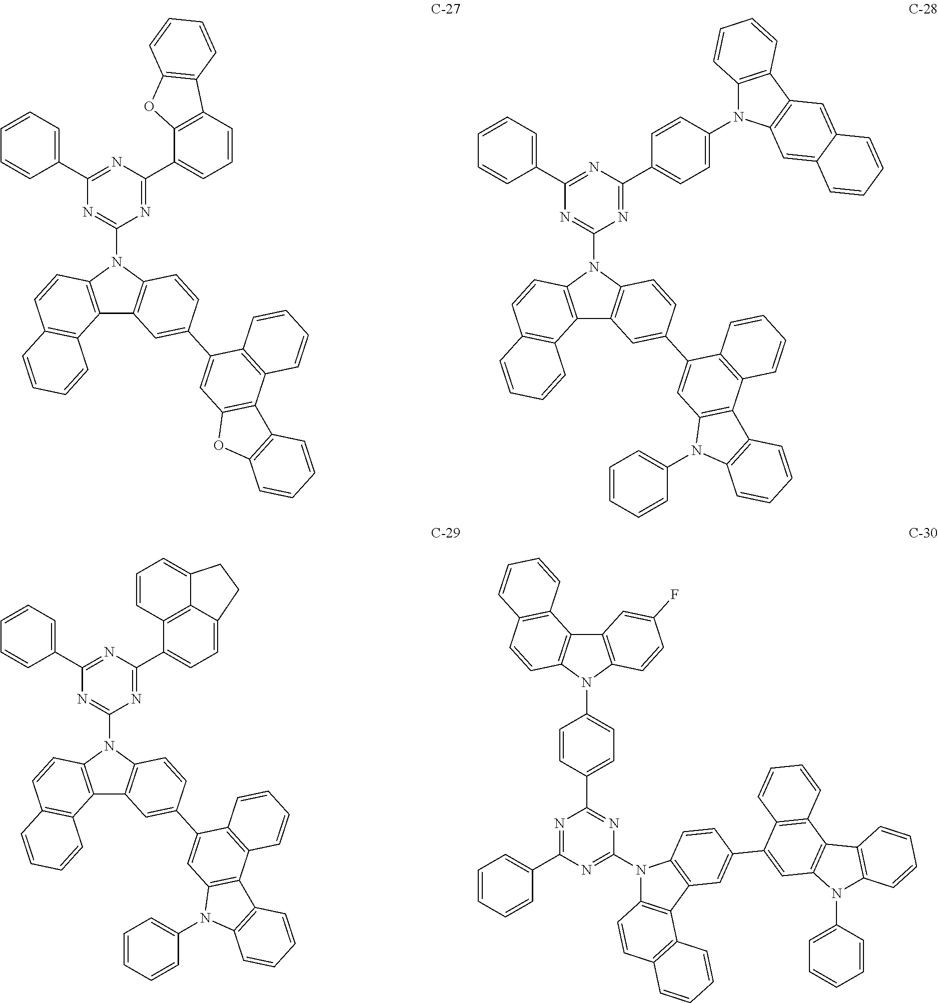 [SMILES: c1ccc(-c2nc(-c3cccc4c3oc3ccccc34)nc(-n3c4ccc(-c5cc6oc7ccccc7c6c6ccccc56)cc4c4c5ccccc5ccc43)n2)cc1 ; c1ccc(-c2nc(-c3ccc(-n4c5ccccc5c5cc6ccccc6cc54)cc3)nc(-n3c4ccc(-c5cc6c(c7ccccc57)c5ccccc5n6-c5ccccc5)cc4c4c5ccccc5ccc43)n2)cc1 ; c1ccc(-c2nc(-c3ccc4c5c(cccc35)CC4)nc(-n3c4ccc(-c5cc6c(c7ccccc57)c5ccccc5n6-c5ccccc5)cc4c4c5ccccc5ccc43)n2)cc1 ; Fc1ccc2c(c1)c1c3ccccc3ccc1n2-c1ccc(-c2nc(-c3ccccc3)nc(-n3c4ccc(-c5cc6c(c7ccccc57)c5ccccc5n6-c5ccccc5)cc4c4c5ccccc5ccc43)n2)cc1]

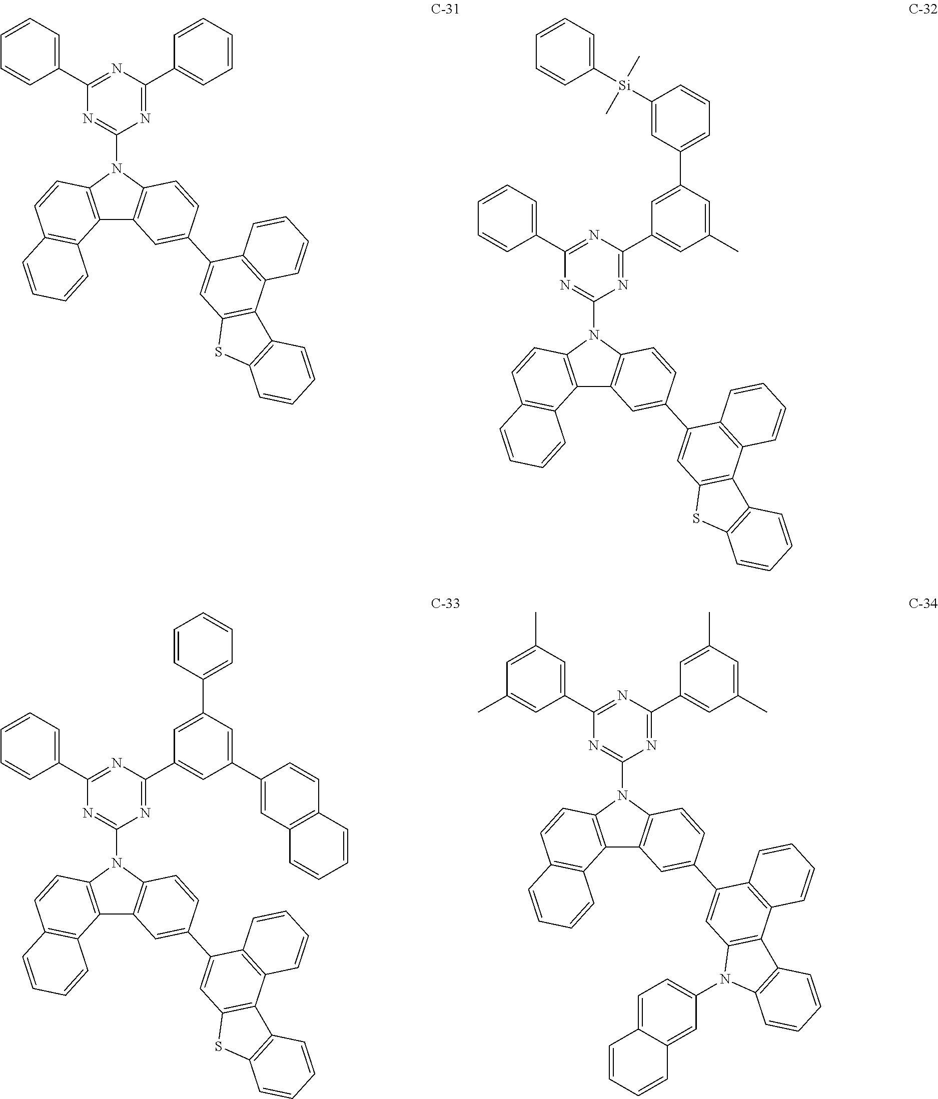 [SMILES: c1ccc(-c2nc(-c3ccccc3)nc(-n3c4ccc(-c5cc6sc7ccccc7c6c6ccccc56)cc4c4c5ccccc5ccc43)n2)cc1 ; Cc1cc(-c2cccc([Si](C)(C)c3ccccc3)c2)cc(-c2nc(-c3ccccc3)nc(-n3c4ccc(-c5cc6sc7ccccc7c6c6ccccc56)cc4c4c5ccccc5ccc43)n2)c1 ; c1ccc(-c2cc(-c3ccc4ccccc4c3)cc(-c3nc(-c4ccccc4)nc(-n4c5ccc(-c6cc7sc8ccccc8c7c7ccccc67)cc5c5c6ccccc6ccc54)n3)c2)cc1 ; Cc1cc(C)cc(-c2nc(-c3cc(C)cc(C)c3)nc(-n3c4ccc(-c5cc6c(c7ccccc57)c5ccccc5n6-c5ccc6ccccc6c5)cc4c4c5ccccc5ccc43)n2)c1]

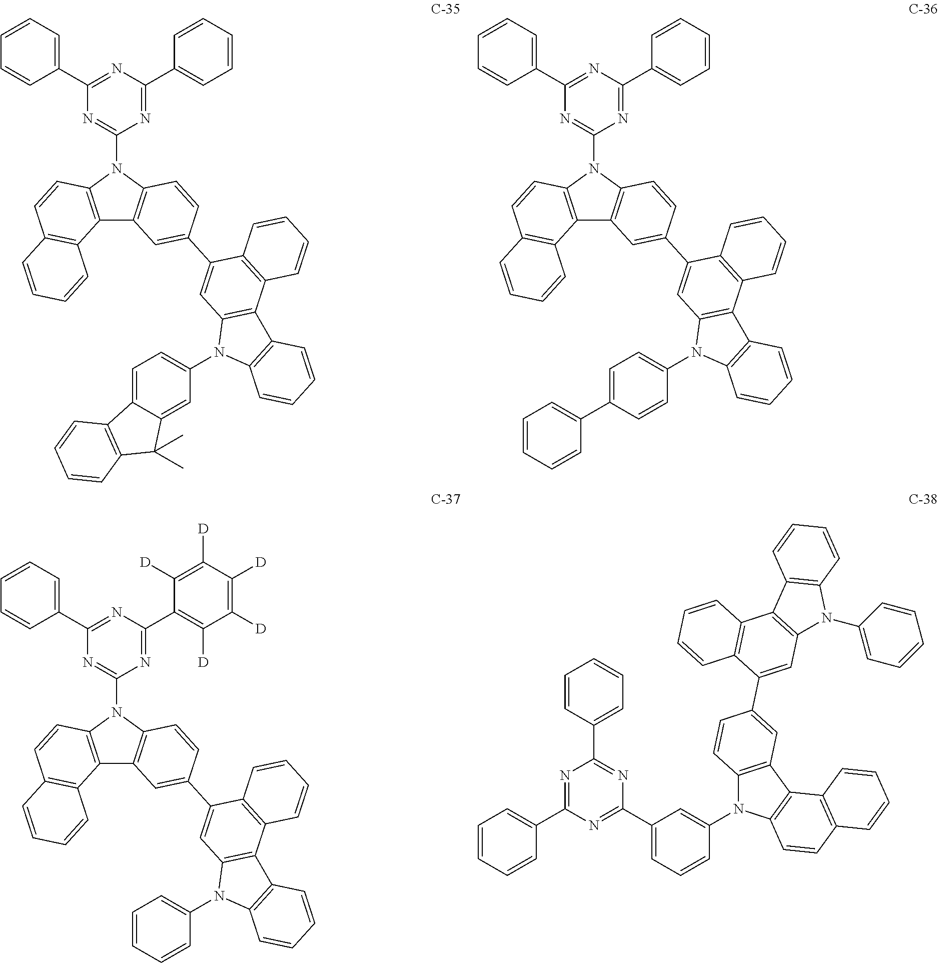 [SMILES: CC1(C)c2ccccc2-c2ccc(-n3c4ccccc4c4c5ccccc5c(-c5ccc6c(c5)c5c7ccccc7ccc5n6-c5nc(-c6ccccc6)nc(-c6ccccc6)n5)cc43)cc21 ; c1ccc(-c2ccc(-n3c4ccccc4c4c5ccccc5c(-c5ccc6c(c5)c5c7ccccc7ccc5n6-c5nc(-c6ccccc6)nc(-c6ccccc6)n5)cc43)cc2)cc1 ; [2H]c1c([2H])c([2H])c(-c2nc(-c3ccccc3)nc(-n3c4ccc(-c5cc6c(c7ccccc57)c5ccccc5n6-c5ccccc5)cc4c4c5ccccc5ccc43)n2)c([2H])c1[2H] ; c1ccc(-c2nc(-c3ccccc3)nc(-c3cccc(-n4c5ccc(-c6cc7c(c8ccccc68)c6ccccc6n7-c6ccccc6)cc5c5c6ccccc6ccc54)c3)n2)cc1]

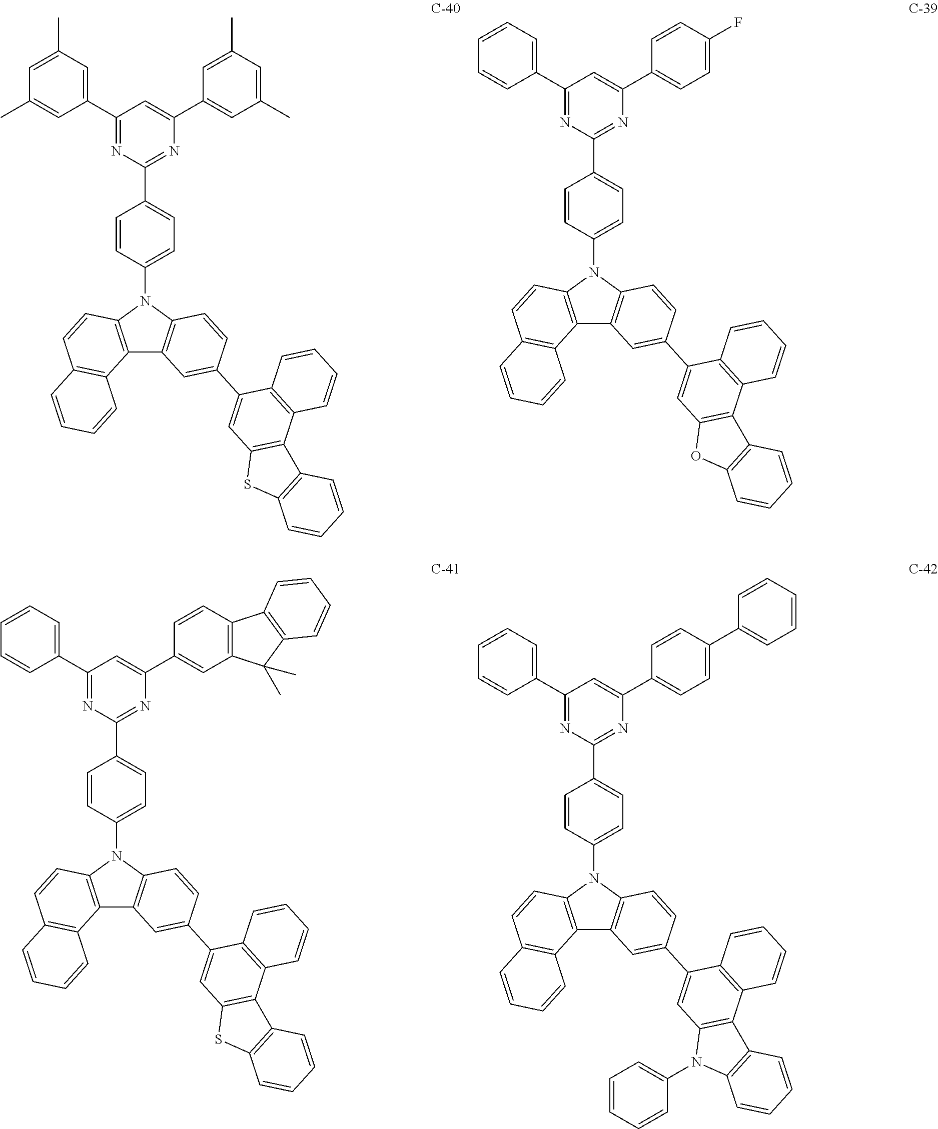

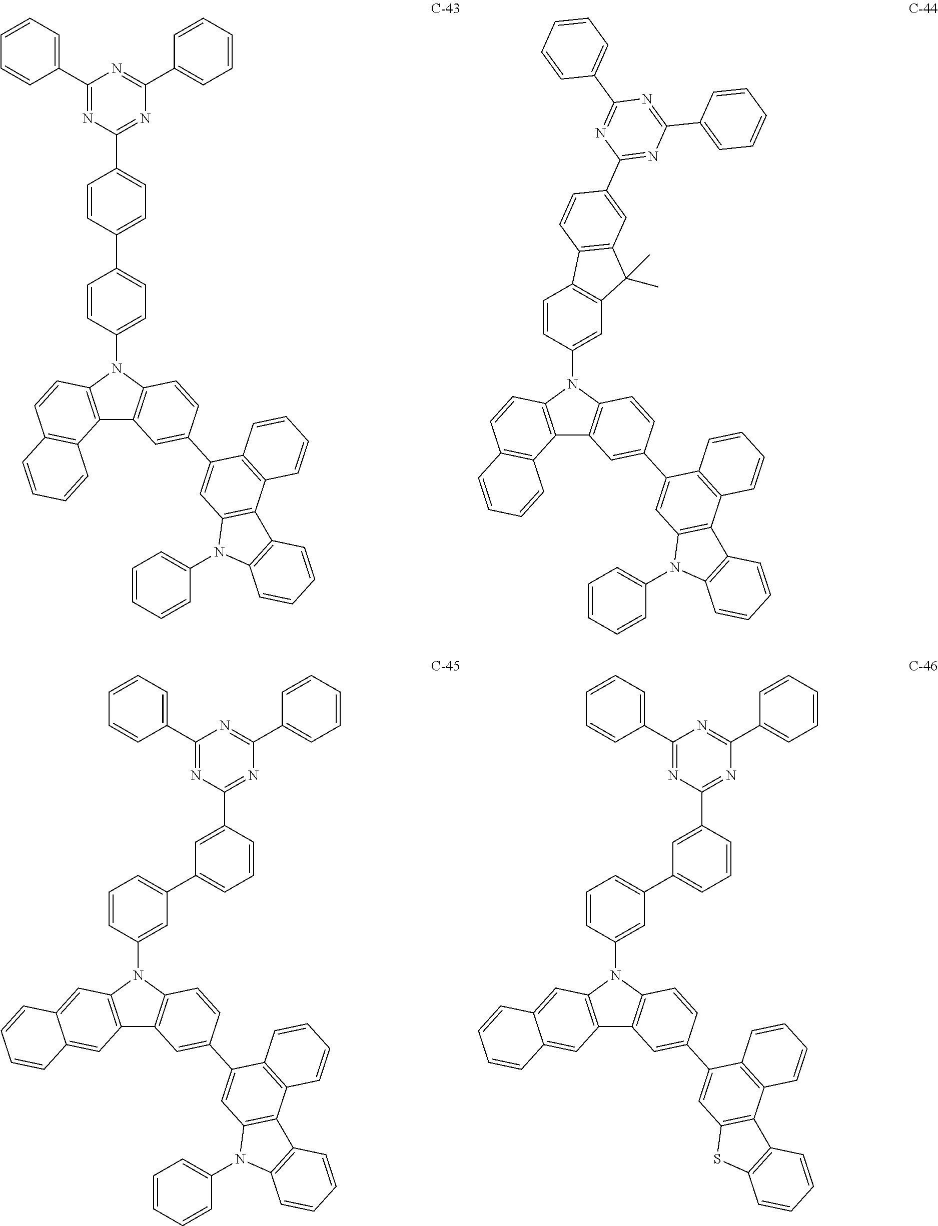

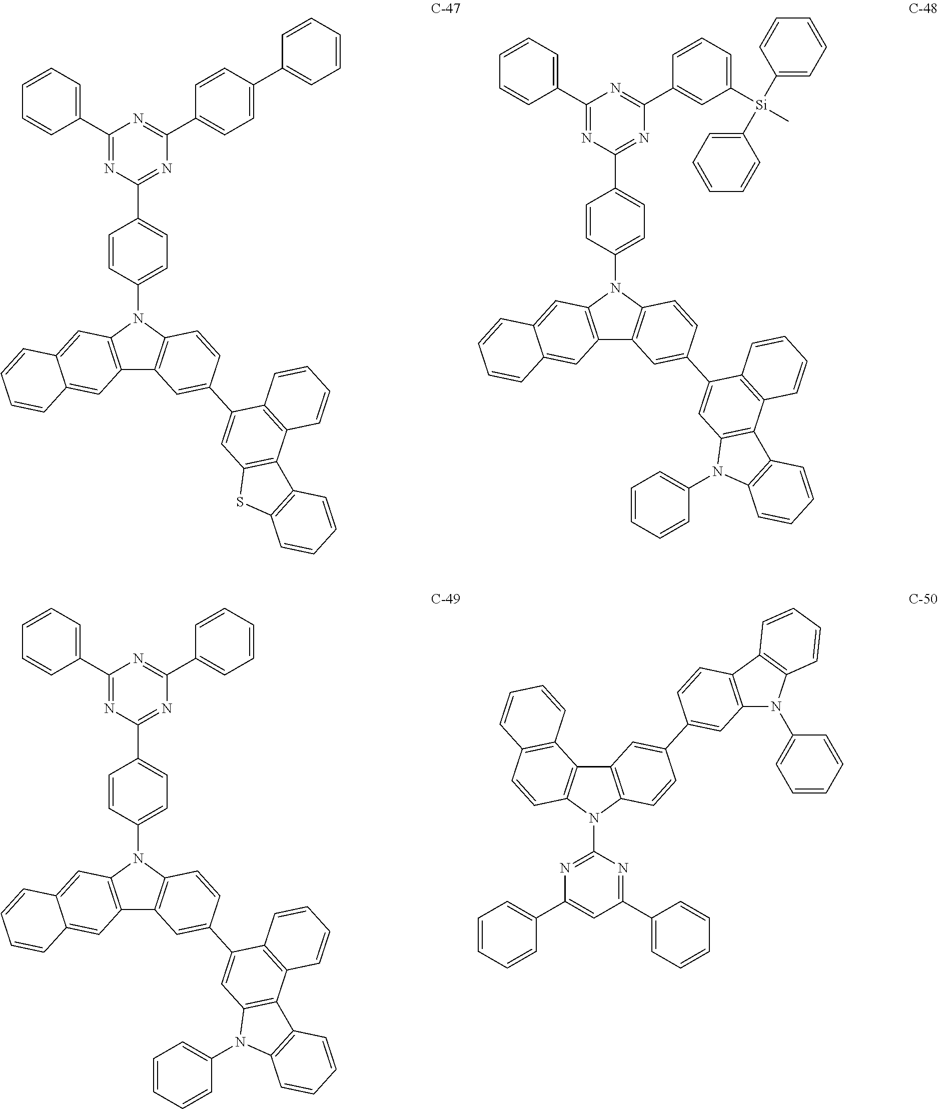 [SMILES: c1ccc(-c2ccc(-c3nc(-c4ccccc4)nc(-c4ccc(-n5c6ccc(-c7cc8sc9ccccc9c8c8ccccc78)cc6c6cc7ccccc7cc65)cc4)n3)cc2)cc1 ; C[Si](c1ccccc1)(c1ccccc1)c1cccc(-c2nc(-c3ccccc3)nc(-c3ccc(-n4c5ccc(-c6cc7c(c8ccccc68)c6ccccc6n7-c6ccccc6)cc5c5cc6ccccc6cc54)cc3)n2)c1 ; c1ccc(-c2nc(-c3ccccc3)nc(-c3ccc(-n4c5ccc(-c6cc7c(c8ccccc68)c6ccccc6n7-c6ccccc6)cc5c5cc6ccccc6cc54)cc3)n2)cc1 ; c1ccc(-c2cc(-c3ccccc3)nc(-n3c4ccc(-c5ccc6c7ccccc7n(-c7ccccc7)c6c5)cc4c4c5ccccc5ccc43)n2)cc1]

6. An organic electroluminescent device comprising the organic electroluminescent compound according to claim 1.
